(19) United States
(12) Patent Application Publication
(10) Pub. No.: US 2025/0318183 A1
(43) Pub. Date: Oct. 9, 2025

(54) SIC SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/243,740

(22) Filed: Jun. 20, 2025

Related U.S. Application Data
(63) Continuation of application No. PCT/JP2023/046702, filed on Dec. 26, 2023.

(30) Foreign Application Priority Data
Dec. 28, 2022 (JP) 2022-212613

(51) Int. Cl. H10D 30/66; H10D 62/10; H10D 62/60; H10D 62/832; H10D 64/23

(52) U.S. Cl. CPC H10D 30/665; H10D 30/668; H10D 62/102; H10D 62/124; H10D 62/60; H10D 62/8325; H10D 64/2527

(57) ABSTRACT

An SiC semiconductor device includes an SiC layer that includes a main surface, a trench structure that is formed in the main surface and extends in a first extension direction in plan view, and a gate structure of a planar electrode type that is arranged on the main surface and extends in a second extension direction other than the first extension direction in plan view.

### CROSS REFERENCE TO RELATED APPLICATIONS

The present application is a bypass continuation of International Patent Application No. PCT/JP2023/046702, filed on Dec. 26, 2023, which claims priority to Japanese Patent Application No. 2022-212613 filed on Dec. 28, 2022 in the Japan Patent Office, and the entire contents of these applications are hereby incorporated herein by reference.

### BACKGROUND

### 1. Field of the Disclosure

The present disclosure relates to an SiC semiconductor device.

### 2. Description of the Related Art

US2015/0028351A1 discloses an electronic device having an impurity region introduced into a silicon carbide layer by a channeling implantation method.

### BRIEF DESCRIPTION OF THE DRAWINGS

FIG. 1 is a plan view showing an SiC semiconductor device according to a specific embodiment.

FIG. 2 is a cross-sectional view taken along line II-II shown in FIG. 1.

FIG. 3 is a plan view showing a layout example of a chip.

FIG. 4 is a perspective view showing the layout example of the chip.

FIG. 5 is a plan view showing an active region.

FIG. 6 is a cross-sectional perspective view showing the active region.

FIG. 7 is a cross-sectional perspective view showing the active region.

FIG. 8 is an enlarged cross-sectional view showing trench structures.

FIG. 9 is an enlarged cross-sectional view showing the trench structures.

FIG. 10 is an enlarged cross-sectional view showing gate structures.

FIG. 11 is an enlarged cross-sectional view showing the gate structures.

FIG. 12 is a graph showing an example of an n-type concentration gradient of a high concentration region.

FIG. 13 is a graph showing a comparative example of the n-type concentration gradient of the high concentration region.

FIG. 14 is a graph showing an example of a p-type concentration gradient of a column region.

FIG. 15 is a perspective view showing an arrangement of an outer peripheral region.

FIG. 16 is a cross-sectional view showing a main portion of the outer peripheral region.

FIG. 17 is a cross-sectional view showing a main portion of the outer peripheral region.

FIG. 18 is a schematic view showing a wafer used in manufacture of the SiC semiconductor device.

FIG. 19 is a flowchart showing a manufacturing method example of the SiC semiconductor device.

FIGS. 20A to 20R are cross-sectional perspective views showing the manufacturing method example of the SiC semiconductor device.

FIG. 21A is a schematic view for describing a measurement step of a crystal orientation.

FIG. 21B is a schematic view for describing the measurement step of the crystal orientation.

FIG. 22A is a schematic view for describing an ion implantation step.

FIG. 22B is a schematic view for describing the ion implantation step.

FIG. 23 is a cross-sectional perspective view showing the SiC semiconductor device according to a first modification example.

FIG. 24 is a cross-sectional perspective view showing the SiC semiconductor device according to a second modification example.

FIG. 25 is a cross-sectional perspective view showing the SiC semiconductor device according to a third modification example.

FIG. 26 is a cross-sectional perspective view showing the SiC semiconductor device according to a fourth modification example.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. Unless noted in particular otherwise, the trivalent element is at least one type among boron, aluminum, gallium, and indium. Unless noted in particular otherwise, the pentavalent element is at least one type among nitrogen, phosphorus, arsenic, antimony, and bismuth.

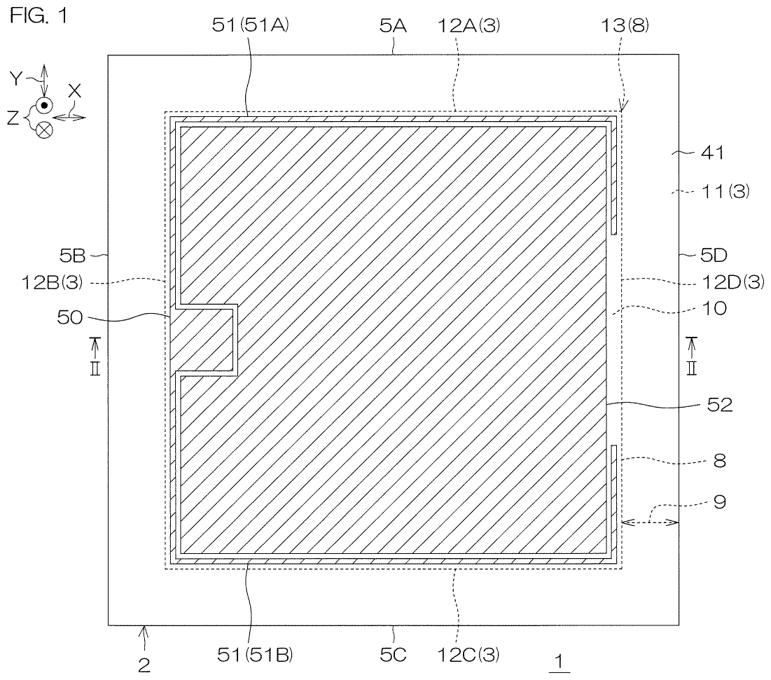

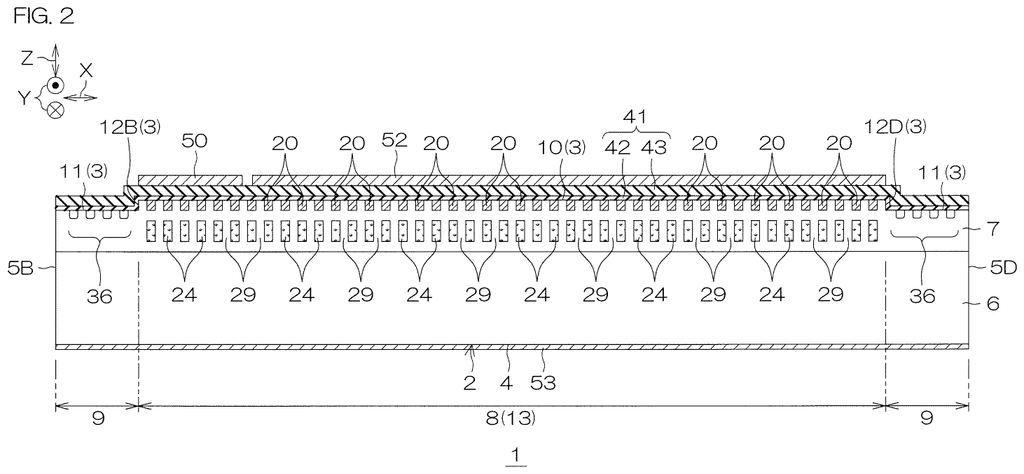

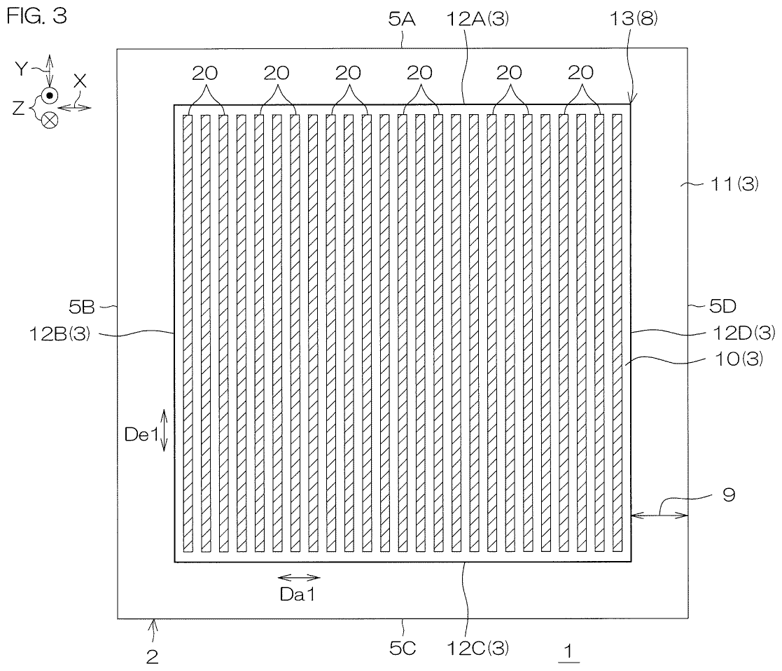

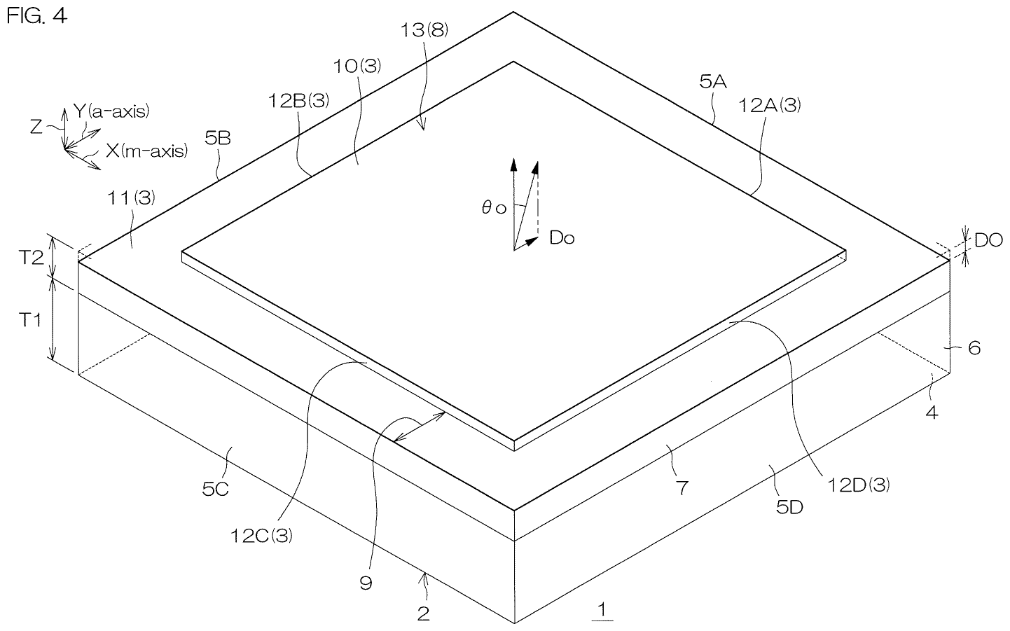

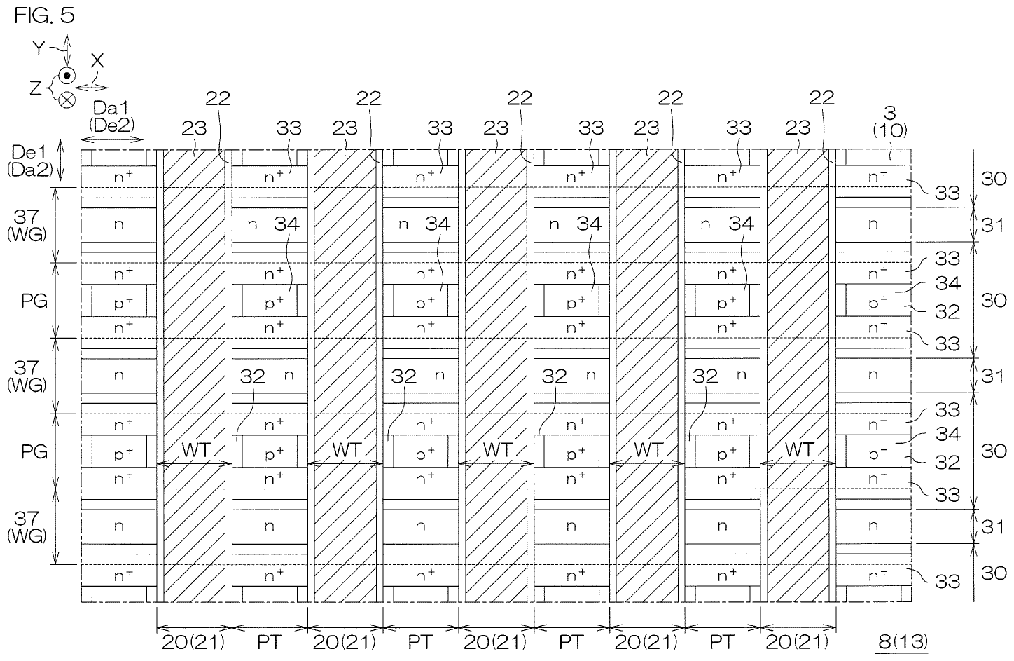

FIG. 1 is a plan view showing an SiC semiconductor device 1 according to a specific embodiment. FIG. 2 is a cross-sectional view taken along line II-II shown in FIG. 1. FIG. 3 is a plan view showing a layout example of a chip 2. FIG. 4 is a perspective view showing the layout example of the chip 2. FIG. 5 is a plan view showing an active region 8.

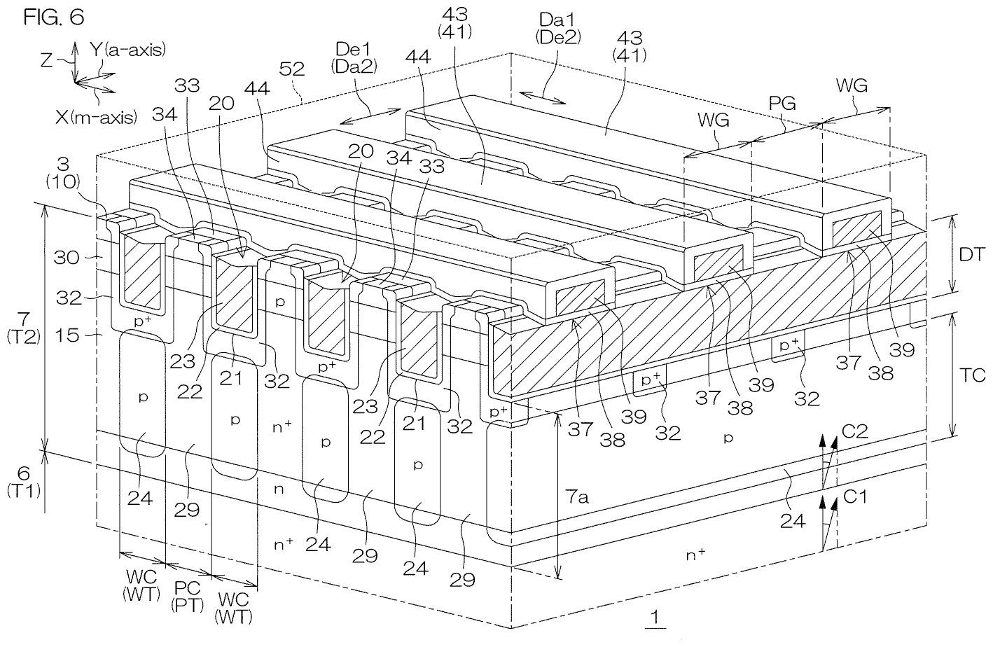

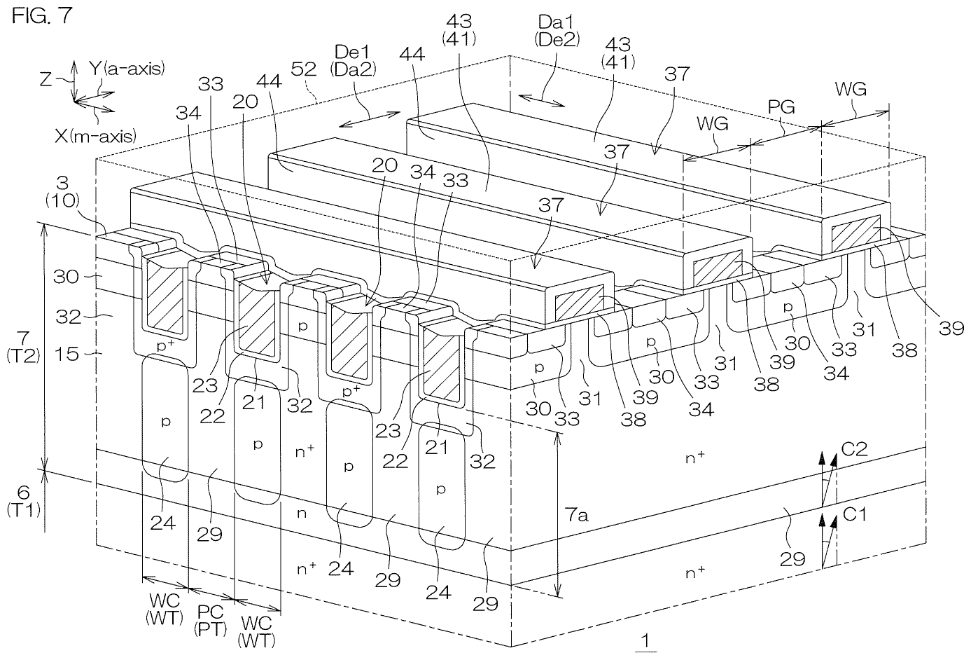

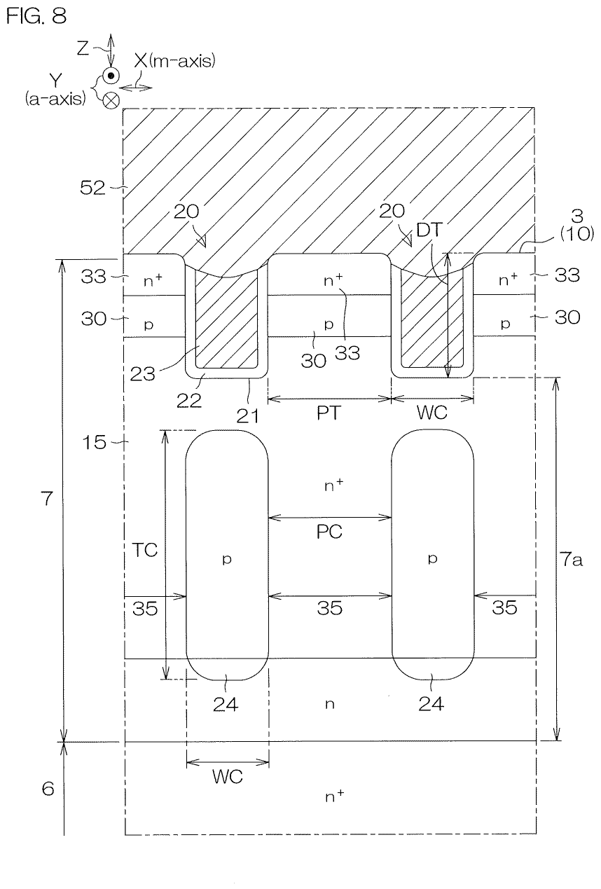

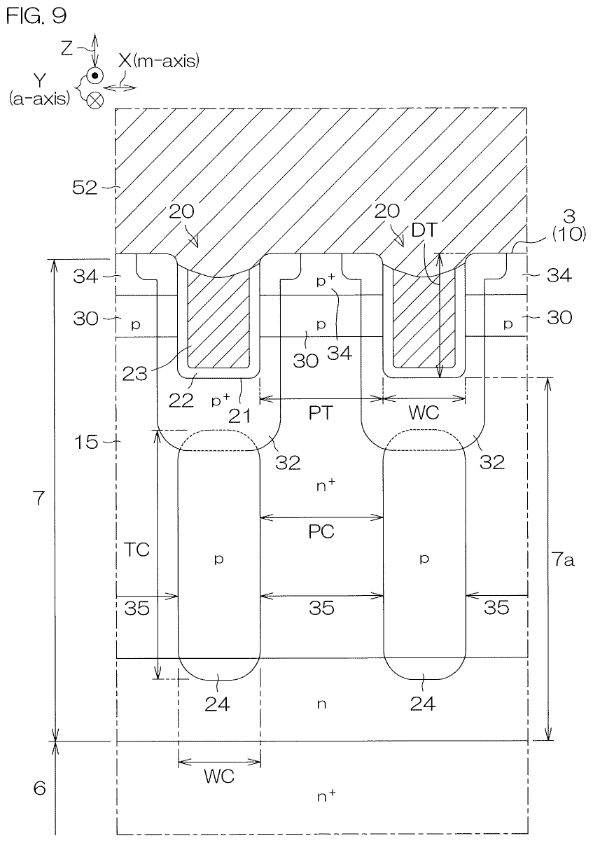

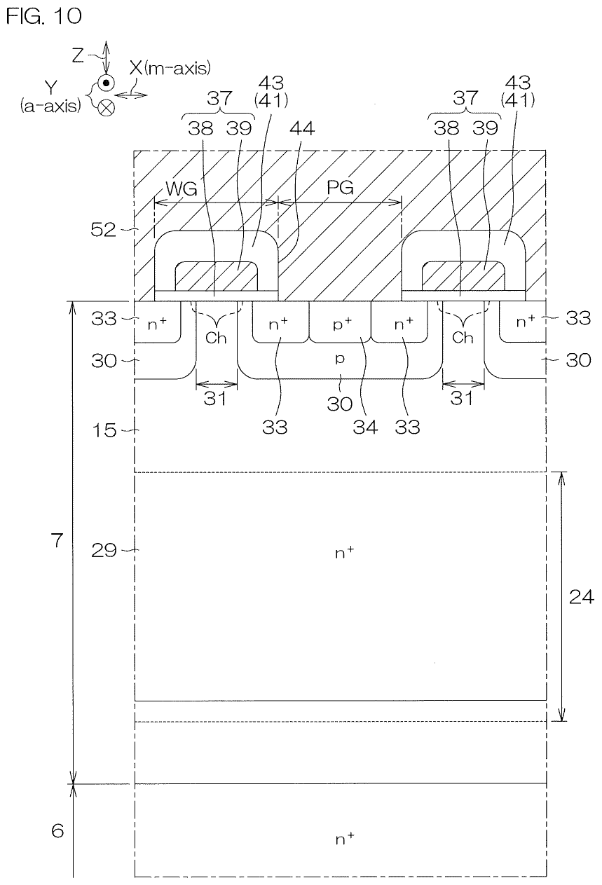

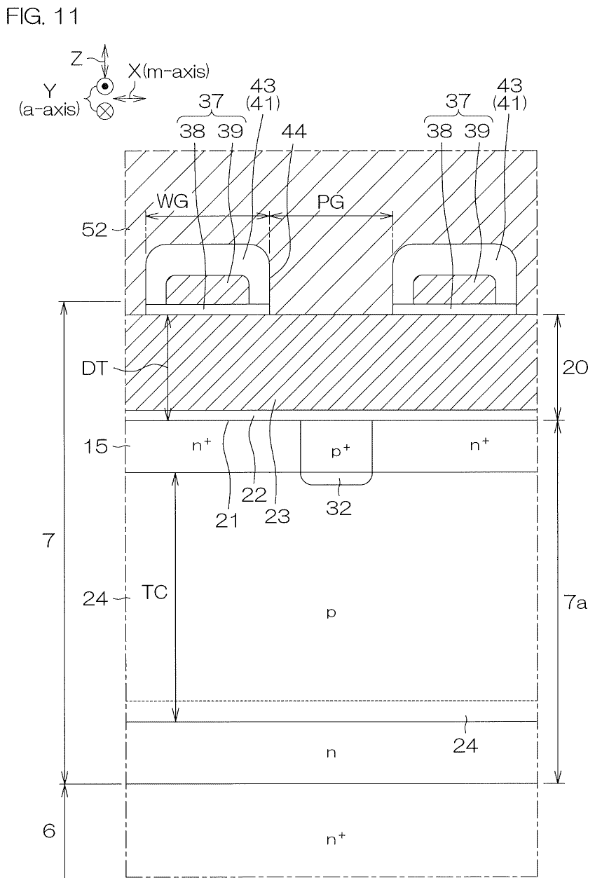

FIG. 6 is a cross-sectional perspective view showing the active region 8. FIG. 7 is a cross-sectional perspective view showing the active region 8. FIG. 8 is an enlarged cross-sectional view showing the trench structures 20. FIG. 9 is an enlarged cross-sectional view showing the trench structures 20. FIG. 10 is an enlarged cross-sectional view showing gate structures 37. FIG. 11 is an enlarged cross-sectional view showing the gate structures 37.

With reference to FIG. 1 to FIG. 11, the SiC semiconductor device 1 includes the chip 2 that includes an SiC monocrystal. The chip 2 may be referred to as an “SiC chip” or a “semiconductor chip.” In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has a first main surface 3 on one side, a second main surface 4 on the other side, and first to fourth side surfaces 5A to 5D connecting the first main surface 3 and the second main surface 4. In a plan view as viewed from a vertical direction Z (hereinafter referred to simply as “plan view”), the first main surface 3 and the second main surface 4 are formed in quadrangle shapes. The vertical direction Z is also a thickness direction of the chip 2 and a normal direction to the first main surface 3 (second main surface 4). The first main surface 3 and the second main surface 4 may be formed in a square shape or a rectangular shape in plan view.

The first main surface 3 and the second main surface 4 are preferably formed by c-planes of the SiC monocrystal. In this case, preferably, the first main surface 3 is formed by a silicon plane (a (0001) plane) of the SiC monocrystal and the second main surface 4 is formed by a carbon plane (a (000-1) plane) of the SiC monocrystal.

In regard to a circumferential direction of the chip 2 with the first side surface 5A as a starting point (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X oriented along the first main surface 3 and are opposed in a second direction Y intersecting (specifically, orthogonal to) the first direction X. The second side surface 5B and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may be the a-axis direction of the SiC monocrystal and the second direction Y may be the m-axis direction of the SiC monocrystal instead.

An XY plane that includes the first direction X and the second direction Y forms a horizontal plane that is orthogonal to the vertical direction Z. In the following, an axis extending along the vertical direction Z is expressed at times as a “vertical axis.” Also, in the following, the first direction X and the second direction Y is expressed at times as “horizontal directions.” Horizontal directions are also directions that extend along the first main surface 3.

With reference to FIG. 4, the chip 2 (the first main surface 3 and the second main surface 4) has an off angle θo inclined at a predetermined angle in a predetermined off direction Do with respect to the c-plane of the SiC monocrystal. That is, a c-axis (a (0001) axis) of the SiC monocrystal is inclined by just the off angle θo toward the off direction Do from the vertical axis. Also, the c-plane of the SiC monocrystal is inclined by just the off angle θo with respect to the horizontal plane.

The off direction Do is preferably the a-axis direction (that is, the second direction Y) of the SiC monocrystal. The off angle θo may exceed 0° and be not more than 10°. The off angle θo may have a value falling within any one of ranges of exceeding 0° and not more than 1°, not less than 1° and not more than 2.5°, not less than 2.5° and not more than 5°, not less than 5° and not more than 7.5°, and not less than 7.5° and not more than 10°.

The off angle θo is preferably not more than 5°. The off angle θo is particularly preferably not less than 2° and not more than 4.5°. The off angle θo is typically set in a range of 4°±0.1°. As a matter of course, this Description does not exclude an embodiment in which the off angle θ0 is 0° (that is, an embodiment in which the first main surface 3 is a just surface with respect to the c-plane).

The chip 2 includes a base layer 6 of the n-type that is constituted of the SiC monocrystal. The base layer 6 may be referred to as a “base SiC layer,” a “base region,” etc. The base layer 6 extends in a layered shape in the horizontal directions and forms the second main surface 4 and portions of the first to fourth side surfaces 5A to 5D. In this embodiment, the base layer 6 is constituted of a substrate made of the SiC monocrystal (in other words, an SiC substrate). The base layer 6 has the off direction Do and the off angle θo described above.

The base layer 6 has a first axis channel C1 oriented along a lamination direction. The first axis channel C1 is constituted of regions (channels) that are of comparatively wide interatomic distance (atomic interval) in the SiC monocrystal constituting the base layer 6 and are surrounded by atomic rows constituting a crystal axis extending in the lamination direction (crystal growth direction).

That is, the first axis channel C1 is constituted of regions that are sparse in atomic rows and extend in the lamination direction and are regions in which atomic rows (interatomic distance/atomic density) in the horizontal directions are sparse in plan view. The first axis channel C1 is preferably constituted of regions surrounded by atomic rows oriented along a low index crystal axis among crystal axes. A low index crystal axis is, in terms of Miller indices (a1, a2, a3, and c), a crystal axis expressed by absolute values of “a1,” “a2,” “a3,” and “c” all being not more than 2 (preferably not more than 1) (the same applies hereinafter in this Description).

In this embodiment, the first axis channel C1 is constituted of regions surrounded by atomic rows oriented along the c-axis (the (0001) axis) of the SiC monocrystal. That is, the first axis channel C1 extends along the c-axis and has the off direction Do and the off angle θo described above. In other words, the first axis channel C1 is inclined by just the off angle θo toward the off direction Do from the vertical axis.

The base layer 6 may have an n-type impurity concentration of not less than 1×10¹⁸ cm⁻3 and not more than 1×10²¹ cm⁻³ as a peak value. The base layer 6 preferably has an n-type impurity concentration that is substantially fixed in a thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a first thickness T1. The first thickness T1 may be not less than 5 μm and not more than 300 μm. The first thickness T1 may have a value falling within any one of ranges of not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, and not less than 250 μm and not more than 300 μm. The first thickness T1 is preferably not less than 50 μm and not more than 250 μm.

The chip 2 includes a semiconductor layer 7 made of the SiC monocrystal that is laminated on the base layer 6. The semiconductor layer 7 may be referred to as an “SiC layer,” a “semiconductor region,” etc. The semiconductor layer 7 extends in a layered shape in the horizontal directions and forms the first main surface 3 and portions of the first to fourth side surfaces 5A to 5D. The semiconductor layer 7 is constituted of an epitaxial layer (that is, an SiC epitaxial layer) formed by crystal growth with the base layer 6 as a starting point.

The semiconductor layer 7 has a lower end and an upper end. The lower end of the semiconductor layer 7 is a crystal growth starting point and the upper end of the semiconductor layer 7 is a crystal growth end point. The lower end of the semiconductor layer 7 is also a bottom portion of the semiconductor layer 7. The semiconductor layer 7 is formed by continuous crystal growth from the base layer 6 and therefore, the lower end of the semiconductor layer 7 is matched with an upper end of the base layer 6.

A boundary portion between the base layer 6 and the semiconductor layer 7 is not necessarily visually recognizable and can be evaluated and/or determined indirectly from other arrangements and elements. The semiconductor layer 7 has an off direction Do and the off angle θo that is substantially matched with the off direction Do and the off angle θo of the base layer 6.

The semiconductor layer 7 has a second axis channel C2 oriented along the lamination direction. The second axis channel C2 is constituted of regions (channels) that are of comparatively wide interatomic distance (atomic interval) in the SiC monocrystal constituting the semiconductor layer 7 and are surrounded by atomic rows constituting a crystal axis extending in the lamination direction (crystal growth direction).

That is, the second axis channel C2 is constituted of regions that are sparse in atomic rows and extend in the lamination direction and are regions in which atomic rows (interatomic distance/atomic density) in the horizontal directions are sparse in plan view. The second axis channel C2 is preferably constituted of regions surrounded by atomic rows oriented along a low index crystal axis among the crystal axes.

In this embodiment, the second axis channel C2 is constituted of regions surrounded by atomic rows oriented along the c-axis of the SiC monocrystal. That is, the second axis channel C2 extends along the c-axis and has the off direction Do and the off angle θo. In other words, the second axis channel C2 is inclined by just the off angle θo toward the off direction Do from the vertical axis. Also, the second axis channel C2 is matched with substantially with the first axis channel C1.

An n-type impurity concentration of the semiconductor layer 7 is preferably less than the n-type impurity concentration of the base layer 6. The semiconductor layer 7 may have an n-type impurity concentration of not less than 1×10¹⁵ cm⁻³ and not more than 1×10¹⁸ cm⁻³ as a peak value. The n-type impurity concentration of the semiconductor layer 7 may be substantially fixed in a thickness direction. As a matter of course, the n-type impurity concentration of the semiconductor layer 7 may have a concentration gradient that increases gradually and/or decreases gradually in the lamination direction (crystal growth direction).

In this embodiment, the n-type impurity concentration of the semiconductor layer 7 is adjusted by nitrogen. The semiconductor layer 7 may have an n-type impurity concentration that is adjusted by at least one type of pentavalent element. For example, the n-type impurity concentration of the semiconductor layer 7 may be adjusted by at least one type among nitrogen, phosphorus, arsenic, antimony, and bismuth. The semiconductor layer 7 preferably contains a pentavalent element other than phosphorus.

The n-type impurity concentration of the semiconductor layer 7 is preferably adjusted by at least nitrogen. When the semiconductor layer 7 contains two or more types of pentavalent elements, the semiconductor layer 7 preferably contains nitrogen and a pentavalent element other than nitrogen. In this case, the semiconductor layer 7 preferably contains either or both of arsenic and antimony as a pentavalent element other than phosphorus and nitrogen.

The semiconductor layer 7 has a second thickness T2 less than the first thickness T1. The second thickness T2 may be not less than 1 μm and not more than 10 μm. The second thickness T2 may have a value falling within any one of ranges of not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The second thickness T2 is preferably not less than 2 μm and not more than 8 μm.

The SiC semiconductor device 1 includes the active region 8 that is set in the chip 2. The active region 8 is set in an inner portion of the chip 2 at intervals from peripheral edges (the first to fourth side surfaces 5A to 5D) of the chip 2 in plan view. The active region 8 is set in a polygonal shape (in this embodiment, a quadrangle shape) having four sides parallel to the peripheral edges of the chip 2 in plan view. A planar area of the active region 8 is preferably not less than 50% and not more than 90% of a planar area of the first main surface 3.

The SiC semiconductor device 1 includes an outer peripheral region 9 that, in the chip 2, is set outside the active region 8. The outer peripheral region 9 is provided in a region between the peripheral edges of the chip 2 and the active region 8 in plan view. The outer peripheral region 9 extends as a band along the active region 8 and is set to a polygonal annular shape (in this embodiment, a quadrangle annular shape) that surrounds the active region 8 in plan view.

The SiC semiconductor device 1 includes an active surface 10, an outer surface 11, and first to fourth connecting surfaces 12A to 12D that are formed in the first main surface 3. The active surface 10, the outer surface 11, and the first to fourth connecting surfaces 12A to 12D demarcate an active mesa 13 in the first main surface 3.

The active surface 10 may be referred to as a “first surface portion,” the outer surface 11 may be referred to as a “second surface portion,” the first to fourth connecting surfaces 12A to 12D may be referred to as “connecting surface portions,” and the active mesa 13 may be referred to as a “mesa portion.” The active surface 10, the outer surface 11, and the first to fourth connecting surfaces 12A to 12D (that is, the active mesa 13) may be regarded as components of the chip 2 (the first main surface 3).

The active surface 10 is formed in the active region 8. That is, the active surface 10 is formed at intervals inward from the peripheral edges of the first main surface 3 (from the first to fourth side surfaces 5A to 5D). The active surface 10 has a flat surface extending in the first direction X and the second direction Y. In this embodiment, the active surface 10 is formed by a c-plane (Si plane). In this embodiment, the active surface 10 is formed in a quadrangle shape having four sides parallel to the first to fourth side surfaces 5A to 5D in plan view.

The outer surface 11 is formed in the outer peripheral region 9. That is, the outer surface 11 is formed outside the active surface 10. The outer surface 11 is recessed in the thickness direction of the chip 2 (toward the second main surface 4 side) with respect to the active surface 10. Specifically, in this embodiment, the outer surface 11 is recessed to a depth less than the thickness of the semiconductor layer 7 such as to expose the semiconductor layer 7. That is, the outer surface 11 faces the base layer 6 with a portion of the semiconductor layer 7 interposed therebetween and exposes the semiconductor layer 7.

The outer surface 11 extends as a band along the active surface 10 and is formed in an annular shape (specifically, a quadrangle annular shape) surrounding the active surface 10 in plan view. The outer surface 11 has a flat surface extending in the first direction X and the second direction Y and is formed substantially parallel to the active surface 10. In this embodiment, the outer surface 11 is formed by a c-plane (Si plane). The outer surface 11 is continuous to the first to fourth side surfaces 5A to 5D in plan view.

The outer surface 11 has an outer peripheral depth DO. The outer peripheral depth DO may be not less than 0.1 μm and not more than 2 μm. The outer peripheral depth DO may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, and not less than 1.5 μm and not more than 2 μm. The outer peripheral depth DO is preferably not less than 0.1 μm and not more than 1.5 μm.

The first to fourth connecting surfaces 12A to 12D extend in the vertical direction Z and connect the active surface 10 and the outer surface 11. The first connecting surface 12A is positioned at the first side surface 5A side, the second connecting surface 12B is positioned at the second side surface 5B side, the third connecting surface 12C is positioned at the third side surface 5C side, and the fourth connecting surface 12D is positioned at the fourth side surface 5D side. The first connecting surface 12A and the third connecting surface 12C extend in the first direction X and are opposed in the second direction Y. The second connecting surface 12B and the fourth connecting surface 12D extend in the second direction Y and are opposed in the first direction X.

The first to fourth connecting surfaces 12A to 12D may extend substantially perpendicularly between the active surface 10 and the outer surface 11 such as to demarcate the active mesa 13 of a quadrangle columnar shape. The first to fourth connecting surfaces 12A to 12D may be inclined obliquely downward from the active surface 10 toward the outer surface 11 such as to demarcate the active mesa 13 of a quadrangle truncated pyramid shape. The active mesa 13 is thus demarcated in a projecting shape on the semiconductor layer 7 in the first main surface 3. The active mesa 13 is formed just on the semiconductor layer 7 and is formed on the base layer 6.

Referring to FIG. 6 to FIG. 11, the SiC semiconductor device 1 includes a high concentration region 15 of the n-type that is formed in the semiconductor layer 7 at least in a portion positioned in the active region 8. The high concentration region 15 has a higher n-type impurity concentration than the n-type impurity concentration of the semiconductor layer 7. In this embodiment, the high concentration region 15 is led out from the active region 8 to the outer peripheral region 9. That is, the high concentration region 15 is led out from a portion of the semiconductor layer 7 positioned in the active region 8 to a portion of the semiconductor layer 7 positioned in the outer peripheral region 9. The high concentration region 15 is exposed from the outer surface 11.

Further, the high concentration region 15 extends from the outer peripheral region 9 toward the first to fourth side surfaces 5A to 5D and are exposed from the first to fourth side surfaces 5A to 5D. As a matter of course, the high concentration region 15 may instead be formed inside the semiconductor layer 7 at intervals inward from the first to fourth side surfaces 5A to 5D. In this case, peripheral edge portions of the high concentration region 15 may be positioned inside the active region 8 or may be positioned inside the outer peripheral region 9.

The high concentration region 15 has an upper end portion positioned at an upper end side of the semiconductor layer 7 and a lower end portion positioned at a lower end side of the semiconductor layer 7. In this embodiment, the upper end portion of the high concentration region 15 is positioned in a region at the upper end side of the semiconductor layer 7 with respect to a thickness range intermediate portion of the semiconductor layer 7 and the lower end portion of the high concentration region 15 is positioned in a region at the lower end side of the semiconductor layer 7 with respect to the thickness range intermediate portion of the semiconductor layer 7.

Although specific illustration shall be omitted, the upper end portion of the high concentration region 15 may be exposed from the first main surface 3. As a matter of course, the upper end portion of the high concentration region 15 may be formed at an interval to the lower end side from the upper end of the semiconductor layer 7 (that is, from the first main surface 3) and may face the first main surface 3 with a portion (the upper end portion) of the semiconductor layer 7 interposed therebetween. Such a structure is specified by analyzing the n-type impurity concentration (the concentration gradient) of the high concentration region 15.

A distance between the first main surface 3 and the upper end portion of the high concentration region 15 may be not less than 0 μm and not more than 1 μm. The distance between the first main surface 3 and the upper end portion of the high concentration region 15 may have a value falling within any one of ranges of not less than 0 μm and not more than 0.25 μm, not less than 0.25 μm and not more than 0.5 μm, not less than 0.5 μm and not more than 0.75 μm, and not less than 0.75 μm and not more than 1 μm.

The lower end portion of the high concentration region 15 is formed at an interval to the upper end side from the lower end of the semiconductor layer 7 (that is, from the base layer 6) and faces the base layer 6 with a portion (a lower end portion) of the semiconductor layer 7 interposed therebetween. A distance between the lower end of the semiconductor layer 7 and the lower end portion of the high concentration region 15 may exceed 0 μm and be not more than 5 μm. The distance between the lower end of the semiconductor layer 7 and the lower end portion of the high concentration region 15 may have a value falling within any one of ranges of exceeding 0 μm and not more than 1 μm, not less than 1 μm and not more than 2 μm, not less than 2 μm and not more than 3 μm, not less than 3 μm and not more than 4 μm, and not less than 4 μm and not more than 5 μm.

The high concentration region 15 has a thickness less than the second thickness T2 of the semiconductor layer 7. The thickness of the high concentration region 15 may be not less than 1 μm but less than 10 μm. The thickness of the high concentration region 15 may have a value falling within any one of ranges of not less than 1 μm and not more than 2 μm, not less than 2 μm and not more than 4 μm, not less than 4 μm and not more than 6 μm, not less than 6 μm and not more than 8 μm, and not less than 8 μm but less than 10 μm. The thickness of the high concentration region 15 is preferably not less than 2 μm and not more than 8 μm. As a matter of course, the lower end portion of the high concentration region 15 may cross the boundary portion between the base layer 6 and the semiconductor layer 7 and be positioned inside the base layer 6.

The high concentration region 15 is constituted of a channeling region of the n-type that extends along the second axis channel C2 inside the semiconductor layer 7 in cross-sectional view. That is, the high concentration region 15 is constituted of an impurity region introduced in parallel or substantially in parallel to the regions (the second axis channel C2) surrounded by the atomic rows oriented along the low index crystal axis inside the semiconductor layer 7 and extends inclinedly with respect to the first main surface 3.

The high concentration region 15 thus has the off direction Do and the off angle θo that are substantially matched with the off direction Do and the off angle θo of the second axis channel C2. In other words, the high concentration region 15 is inclined by just the off angle θo toward the off direction Do from the vertical axis. The high concentration region 15 is constituted of a single impurity region having a thickness (depth) of crossing an intermediate portion of the semiconductor layer 7 along the second axis channel C2.

The high concentration region 15 may have an n-type impurity concentration of not less than 1×10¹⁵ cm⁻³ and not more than 1×10¹⁸ cm⁻³ as a peak value. The n-type impurity concentration of the high concentration region 15 is preferably adjusted by at least one type of pentavalent element. For example, the n-type impurity concentration of the high concentration region 15 may be adjusted by at least one type among nitrogen, phosphorus, arsenic, antimony, and bismuth.

The high concentration region 15 preferably contains a pentavalent element other than nitrogen and phosphorus. The n-type impurity concentration of the high concentration region 15 is preferably adjusted by at least one type among arsenic, antimony, and bismuth. In consideration of easy availability, the n-type impurity concentration of the high concentration region 15 is preferably adjusted by arsenic or antimony.

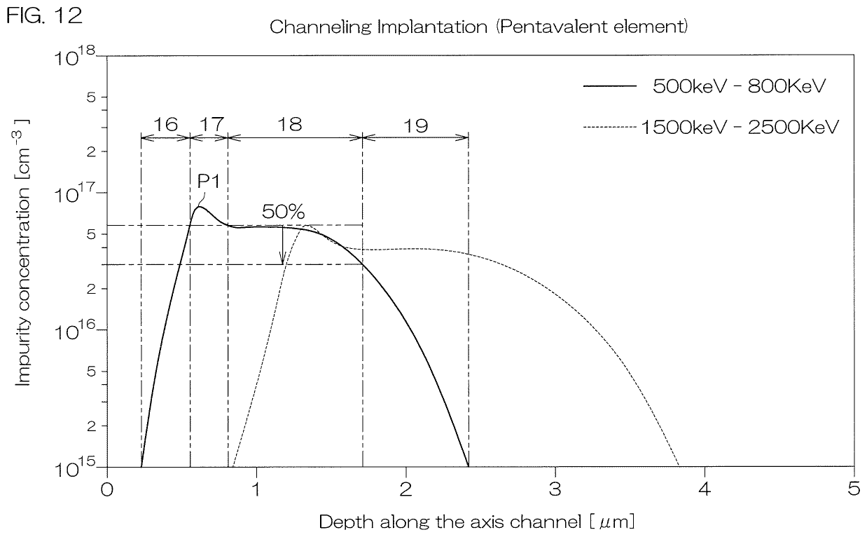

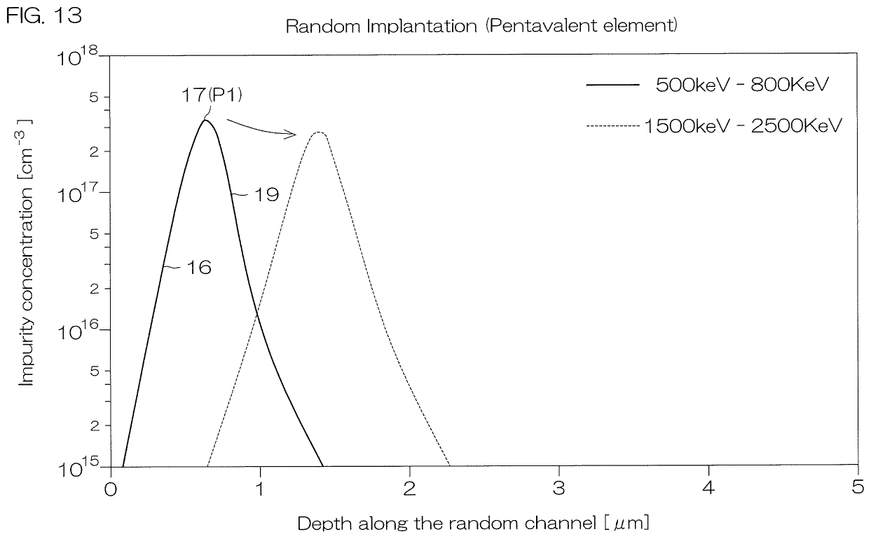

An n-type concentration gradient of the high concentration region 15 shall now be described specifically. FIG. 12 is a graph (simulation) showing an example of the n-type concentration gradient of the high concentration region 15. FIG. 13 is a graph showing a comparative example of the n-type concentration gradient of the high concentration region 15. In FIG. 12 and FIG. 13, the ordinate shows the n-type impurity concentration of the high concentration region 15 and the abscissa shows a depth along the second axis channel C2 with the first main surface 3 as a basis (zero point).

In FIG. 12 and FIG. 13, a region having an n-type impurity concentration of not less than 1×10¹⁵ cm⁻³ is defined as the high concentration region 15 and illustrated as a graph. Numerical values of impurity concentration, thickness, etc., indicated below are examples for describing the basic arrangement of the high concentration region 15 based on the concentration gradient and are not indicated with the intention of unequivocally restricting the arrangement of the high concentration region 15. The impurity concentration, thickness, etc., are adjusted to various values in accordance with implantation conditions (dose amount, implantation temperature, implantation energy, etc.) of the pentavalent element, etc.

FIG. 12 is a graph for a case where the high concentration region 15 is formed by a channeling implantation method. FIG. 12 shows the concentration gradient of the high concentration region 15 when a predetermined pentavalent element (here, arsenic) is introduced into the semiconductor layer 7 in parallel or substantially in parallel to the second axis channel C2 by an implantation energy of not less than 500 KeV and not more than 800 KeV.

The dose amount of the pentavalent element is 1×10¹³ cm⁻². The thickness of the semiconductor layer 7 is approximately 5 μm. In FIG. 12, the concentration gradient when the high concentration region 15 is formed by an implantation energy of not less than 1500 KeV and not more than 2500 KeV is indicated by a broken line.

On the other hand, FIG. 13 is a graph for a case where the high concentration region 15 is formed by a random implantation method. FIG. 13 shows the concentration gradient of the high concentration region 15 when a predetermined pentavalent element (here, arsenic) is introduced into the semiconductor layer 7 in a random direction by an implantation energy of not less than 500 KeV and not more than 800 KeV.

The random direction is a direction (for example, the vertical direction Z) that is not parallel (or substantially parallel) to the second axis channel C2. The dose amount of the pentavalent element is 1×10¹³ cm⁻². The thickness of the semiconductor layer 7 is approximately 5 μm. In FIG. 13, the concentration gradient when the high concentration region 15 is formed by an implantation energy of not less than 1500 KeV and not more than 2500 KeV is indicated by a broken line.

With reference to FIG. 12, the high concentration region 15 has the thickness of not less than 2.1 μm and not more than 2.4 μm and has the upper end portion that is separated to the lower end side of the semiconductor layer 7 from the first main surface 3 and the lower end portion that is separated to the upper end side from the lower end of the semiconductor layer 7. The high concentration region 15 has the concentration gradient that decreases gradually from the upper end portion side toward the lower end portion side.

Specifically, the n-type impurity concentration of the high concentration region 15 has the concentration gradient that includes, from the upper end portion side toward the lower end portion side, a first gradual increase portion 16, a first peak portion 17, a first gentle gradient portion 18, and a first gradual decrease portion 19. The first gradual increase portion 16 is a portion that forms the upper end portion of the high concentration region 15 and the n-type impurity concentration increases gradually to the first peak portion 17 at a comparatively steep increase rate from the upper end portion toward the lower end portion side.

The first peak portion 17 is a portion having a first peak value P1 (maximum value) of the n-type impurity concentration. The first peak portion 17 is also a main concentration transition portion of convex shape that includes a series of concentration changes (an inflection point) with which the n-type impurity concentration changes from increasing (an increasing trend) to decreasing (a decreasing trend).

The first gentle gradient portion 18 is formed in a region further to the lower end portion side than the first peak portion 17 and is a portion in which the impurity concentration decreases gradually at a comparatively slow decrease rate. That is, the first gentle gradient portion 18 is a portion in which a fixed n-type impurity concentration is maintained across a fixed depth range and forms a main body portion of the high concentration region 15. The n-type impurity concentration of the first gentle gradient portion 18 decreases gradually within a concentration range of less than the n-type impurity concentration of the first peak portion 17.

The first gentle gradient portion 18 is defined by a portion having a concentration decrease rate of not more than 50% within a thickness range of at least 0.5 μm. In the example of FIG. 12, the first gentle gradient portion 18 has a thickness of not less than 0.8 μm and not more than 1.1 μm and has the concentration decrease rate of not more than 50% within this thickness range.

The first gentle gradient portion 18 occupies a thickness range of not less than ¼ of the high concentration region 15. Specifically, a proportion of the high concentration region 15 occupied by the first gentle gradient portion 18 is not less than ⅓. The proportion of the high concentration region 15 occupied by the first gentle gradient portion 18 is typically not more than ½ (or less than ½). As a matter of course, the proportion of the high concentration region 15 occupied by the first gentle gradient portion 18 may be not less than ½.

The first gradual decrease portion 19 is a portion that forms the lower end portion of the high concentration region 15. The first gradual decrease portion 19 has a concentration decrease rate that is greater than the concentration decrease rate in the first gentle gradient portion 18 and is a portion in which the n-type impurity concentration decreases gradually from the first gentle gradient portion 18 toward the lower end portion. A concentration decrease rate per unit thickness of the first gradual decrease portion 19 is greater than a concentration decrease rate per unit thickness of the first gentle gradient portion 18.

In the case of the channeling implantation method, the thickness (the depth) of the high concentration region 15 increases with increase in implantation energy. A depth position of the upper end portion of the high concentration region 15 with respect to the first main surface 3 increases with increase in implantation energy. A thickness of the first gradual increase portion 16, a thickness of the first peak portion 17, the thickness of the first gentle gradient portion 18, and a thickness of the first gradual decrease portion 19 increase with increase in implantation energy. On the other hand, the first peak value P1 of the high concentration region 15 decreases with increase in implantation energy. This is because, with increase in implantation energy, the pentavalent element is introduced to a deeper region and the n-type impurity concentration of this deeper region increases.

Oppositely, the depth position of the upper end portion of the high concentration region 15 with respect to the first main surface 3 decreases with decrease in implantation energy. The thickness of the first gradual increase portion 16, the thickness of the first peak portion 17, the thickness of the first gentle gradient portion 18, and the thickness of the first gradual decrease portion 19 decrease with decrease in implantation energy. On the other hand, the first peak value P1 of the high concentration region 15 increases with decrease in implantation energy. This is because, with decrease in implantation energy, the pentavalent element is captured in a shallow region.

On the other hand, with reference to FIG. 13, in the case of the random implantation method, the high concentration region 15 has the first gradual increase portion 16, the first peak portion 17 (the first peak value P1), and the first gradual decrease portion 19 within a range of 0.5 μm but does not have the first gentle gradient portion 18 having a thickness of not less 0.5 μm. Also, in the case of the random implantation method, whereas the depth position of the first peak portion 17 (the first peak value P1) with respect to the first main surface 3 increased with increase in implantation energy, the thickness of the high concentration region 15 was less than 2 μm. That is, even when the implantation energy was increased, the thickness did not vary greatly.

From this, it is understood that while the SiC monocrystal has a physical property of being difficult for an impurity to diffuse, with the random implantation method, it is difficult to form, with respect to the semiconductor layer 7 having the comparatively large second thickness T2 (for example, of not less than 1 μm), the high concentration region 15 that is constituted of a single region and is of a comparatively large thickness (for example, a thickness of not less than 1 μm and not more than 5 μm).

The SiC semiconductor device 1 includes the plurality of trench structures 20 of a trench electrode type that are formed in the first main surface 3 (the active surface 10) in the active region 8. A potential other than a gate potential is applied to the trench structures 20. In this embodiment, a reference potential that serves as a reference for circuit operation is applied to the trench structures 20. The reference potential is, for example, a ground potential or a source potential. The trench structures 20 may be referred to as “field trench structures,” “trench source structures,” etc.

The plurality of trench structures 20 are arranged at intervals inward from peripheral edges of the active surface 10 (from the first to fourth connecting surfaces 12A to 12D) in the active region 8. In this embodiment, the plurality of trench structures 20 are arrayed at intervals in a first array direction Da1 and are each formed in a band shape extending in a first extension direction De1. In this embodiment, the first array direction Da1 is the first direction X (the m-axis direction) and the first extension direction De1 is the second direction Y (the a-axis direction).

That is, the plurality of trench structures 20 are arrayed at intervals in the m-axis direction and each extend in the a-axis direction. Also, in this embodiment, the plurality of trench structures 20 are arrayed as stripes extending in the a-axis direction (the second direction Y). The first extension direction De1 is matched with the off direction Do of the semiconductor layer 7.

The plurality of trench structures 20 are formed at intervals to the first main surface 3 (the active surface 10) side from the lower end of the semiconductor layer 7 (from the base layer 6) and faces the base layer 6 with a portion of the semiconductor layer 7 interposed therebetween. The plurality of trench structures 20 demarcate a lower region 7a in a region between bottom walls of the plurality of trench structures 20 and the lower end of the semiconductor layer 7 (the base layer 6).

In this embodiment, the plurality of trench structures 20 are formed at intervals to the first main surface 3 (active surface 10) side from a bottom portion of the high concentration region 15 and face a portion (the lower end portion) of the semiconductor layer 7 with a portion (the lower end portion) of the high concentration region 15 interposed therebetween. That is, the lower region 7a is formed by the portion (the lower end portion) of the semiconductor layer 7 and the portion (the lower end portion) of the high concentration region 15.

The plurality of trench structures 20 are preferably formed at intervals to the active surface 10 side from a thickness range intermediate portion of the high concentration region 15. As a matter of course, the plurality of trench structures 20 may instead be formed at depth positions of crossing the thickness range intermediate portion of the high concentration region 15.

Each trench structure 20 has a trench width WT in the first array direction Da1 and has a trench depth DT in the vertical direction Z. The trench width WT is preferably less than the second thickness T2 of the semiconductor layer 7. The trench width WT is preferably less than the thickness of the high concentration region 15.

The trench width WT may be not less than 0.1 μm and not more than 5 μm. The trench width WT may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The trench depth DT is preferably less than the second thickness T2 of the semiconductor layer 7. The trench depth DT is preferably less than the thickness of the high concentration region 15. The trench depth DT is particularly preferably substantially equal to the outer peripheral depth DO described above. As a matter of course, the trench depth DT may be not less than the outer peripheral depth DO or may be less than the outer peripheral depth DO.

The trench depth DT is preferably greater than the trench width WT. That is, each of the plurality of trench structures 20 preferably has an aspect ratio DT/WT of extending in a vertically long columnar shape. The aspect ratio DT/WT is a ratio of the trench depth DT with respect to the trench width WT.

The trench depth DT may be not less than 0.1 μm and not more than 5 μm. The trench depth DT may have a value falling within any one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The trench depth DT is preferably not less than 0.1 μm and not more than 1.5 μm.

The plurality of trench structures 20 are arrayed at intervals, each of a trench pitch PT, in the first array direction Da1. The trench pitch PT is preferably less than the second thickness T2 of the semiconductor layer 7. The trench pitch PT is preferably less than the thickness of the high concentration region 15. The trench pitch PT may be less than the trench depth DT. As a matter of course, the trench pitch PT may be greater than the trench depth DT.

The trench pitch PT may be not less than 0.1 μm and not more than 5 μm. The trench pitch PT may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The trench pitch PT is preferably not less than 0.5 μm and not more than 1.5 μm.

Each trench structure 20 includes a trench 21, an insulating film 22, and an embedded electrode 23. The trench 21 is formed in the active surface 10 and demarcates wall surfaces (side walls and a bottom wall) of the trench structure 20. A bottom wall of the trench 21 preferably has a portion that extends flatly.

The flat portion of the bottom wall particularly preferably extends substantially parallel to the first main surface 3. That is, the bottom wall of the trench 21 preferably has the off angle θo inclined at a predetermined angle in a predetermined off direction Do with respect to the c-plane. That is, the bottom wall of the trench 21 preferably has a flat portion that extends in the off direction Do. As a matter of course, the bottom wall may instead be curved in an arcuate shape toward the lower end side of the semiconductor layer 7.

The insulating film 22 covers the wall surfaces of the trench 21. The insulating film 22 may include at least one among a silicon oxide film, a silicon nitride film, and a silicon oxynitride film. In this embodiment, the insulating film 22 has a single layer structure constituted of the silicon oxide film. The insulating film 22 particularly preferably includes a silicon oxide film that consists of an oxide of the chip 2.

The embedded electrode 23 is embedded in the trench 21 and faces the semiconductor layer 7 with the insulating film 22 interposed therebetween. In this embodiment, the embedded electrode 23 faces the high concentration region 15 with the insulating film 22 interposed therebetween. The embedded electrode 23 may contain a conductive polysilicon of the p-type or the n-type.

The SiC semiconductor device 1 includes a plurality of column regions 24 of the p-type that are formed at intervals in a horizontal direction inside the semiconductor layer 7. Specifically, the plurality of column regions 24 are formed in the lower region 7a inside the semiconductor layer 7. That is, the plurality of column regions 24 are formed in a thickness range between the lower end of the semiconductor layer 7 and the bottom walls of the plurality of trench structures 20.

Inside the lower region 7a, the plurality of column regions 24 are arrayed at intervals in the first array direction Da1 and are each formed in a band shape extending in the first extension direction De1. That is, the plurality of column regions 24 are arrayed at intervals in the m-axis direction (the first direction X) and extend in the a-axis direction (the second direction Y) of the SiC monocrystal. Also, the plurality of column regions 24 are formed as stripes extending in the a-axis direction (the second direction Y). The extension direction of the plurality of column regions 24 is matched with the off direction Do of the semiconductor layer 7.

The plurality of column regions 24 overlap with the plurality of trench structures 20 in the lamination direction. Specifically, the plurality of column regions 24 overlap with the plurality of trench structures 20 in one-to-one correspondence in the lamination direction. The plurality of column regions 24 are formed at intervals inward from the peripheral edges of the active surface 10 (from the first to fourth connecting surfaces 12A to 12D) in the active region 8.

In regard to the second direction Y, both end portions of the plurality of column regions 24 may be positioned at inner sides of the active region 8 with respect to both end portions of the plurality of trench structures 20. In regard to the second direction Y, both end portions of the plurality of column regions 24 may be positioned at peripheral edge sides of the active region 8 with respect to both end portions of the plurality of trench structures 20.

The plurality of column regions 24 have upper end portions positioned at the bottom wall side of the trench structures 20 and lower end portions positioned at the lower end side of the semiconductor layer 7. In this embodiment, the upper end portions of the plurality of column regions 24 are positioned in regions at the bottom wall side of the trench structures 20 with respect to a thickness range intermediate portion of the lower region 7a and the lower end portions of the plurality of column regions 24 are positioned in regions at the lower end side of the semiconductor layer 7 with respect to the thickness range intermediate portion of the lower region 7a.

The upper end portions of the plurality of column regions 24 are formed at intervals toward the lower end side of the semiconductor layer 7 with respect to the depth position of the outer surface 11. The upper end portions of the plurality of column regions 24 are formed at intervals to the lower end side of the semiconductor layer 7 from the bottom walls of the plurality of trench structures 20 and face the plurality of trench structures 20 with a portion of the semiconductor layer 7 interposed therebetween.

Specifically, the upper end portions of the plurality of column regions 24 face the plurality of trench structures 20 with a portion of the high concentration region 15 interposed therebetween. That is, the upper end portions of the plurality of column regions 24 are electrically connected to the high concentration region 15 of comparatively high concentration. As a matter of course, the upper end portions of the plurality of column regions 24 may instead be connected to the bottom walls of the plurality of trench structures 20.

An intermediate distance between the bottom walls of the plurality of trench structures 20 and the upper end portions of the plurality of column regions 24 may be not less than 0 μm and not more than 1 μm. The intermediate distance may have a value falling within any one of ranges of not less than 0 μm and not more than 0.25 μm, not less than 0.25 μm and not more than 0.5 μm, not less than 0.5 μm and not more than 0.75 μm, and not less than 0.75 μm and not more than 1 μm.

The lower end portions of the plurality of column regions 24 cross the bottom portion of the high concentration region 15 and led out into the semiconductor layer 7. That is, the plurality of column regions 24 include portions that are positioned in a region between the bottom portion of the high concentration region 15 and the bottom walls of the plurality of trench structures 20 and portions that are positioned in a region between the lower end of the semiconductor layer 7 and the bottom portion of the high concentration region 15. The lower end portions of the plurality of column regions 24 are electrically connected to the semiconductor layer 7 of comparatively low concentration.

A cross-sectional area of portions of the plurality of column regions 24 positioned inside the high concentration region 15 is preferably greater than a cross-sectional area of portions of the plurality of column regions 24 positioned inside the semiconductor layer 7. As a matter of course, the cross-sectional area of the portions of the plurality of column regions 24 positioned inside the high concentration region 15 may instead be smaller than the cross-sectional area of the portions of the plurality of column regions 24 positioned inside the semiconductor layer 7.

In this embodiment, the lower end portions of the plurality of column regions 24 are formed at intervals to the bottom portion side of the high concentration region 15 from the lower end of the semiconductor layer 7 and face the base layer 6 with a portion of the semiconductor layer 7 interposed therebetween. As a matter of course, the lower end portions of the plurality of column regions 24 may cross the boundary portion between the semiconductor layer 7 and the base layer 6 and be positioned inside the base layer 6 instead. When the lower end portion of the high concentration region 15 is positioned inside the base layer 6, the lower end portions of the plurality of column regions 24 may cross the bottom portion of the high concentration region 15 inside the base layer 6.

A lower end distance between the lower end of the semiconductor layer 7 and the

lower end portions of the plurality of column regions 24 may be not less than 0 μm and not more than 2 μm. The lower end distance may have a value falling within any one of ranges of not less than 0 μm and not more than 0.5 μm, not less than 0.5 μm and not more than 1 μm, not less than 1 μm and not more than 1.5 μm, and not less than 1.5 μm and not more than 2 μm.

As a matter of course, when the high concentration region 15 that is comparatively thick is formed, the lower end portions of the plurality of column regions 24 may be formed at intervals to the bottom wall side of the trench structures 20 from the bottom portion of the high concentration region 15. That is, the plurality of column regions 24 may be electrically connected to the high concentration region 15 at both the upper end portions and the lower end portions.

The plurality of column regions 24 are each constituted of a channeling region of the p-type that extends along the second axis channel C2 in cross-sectional view. That is, each column region 24 is an impurity region introduced in parallel or substantially in parallel to the regions (the second axis channel C2) surrounded by the atomic rows oriented along the low index crystal axis inside the semiconductor layer 7 and extends inclinedly with respect to the first main surface 3.

The plurality of column regions 24 thus have the off direction Do and the off angle θo that are substantially matched with the off direction Do and the off angle θo of the second axis channel C2. In other words, the plurality of column regions 24 are inclined by just the off angle θo toward the off direction Do from the vertical axis. The plurality of column regions 24 are each constituted of a single impurity region having a thickness (depth) of crossing the intermediate portion of the lower region 7a along the second axis channel C2.

The plurality of column regions 24 may have a p-type impurity concentration of not less than 1×10¹⁵ cm⁻³ and not more than 1×10¹⁸ cm⁻³ as a peak value. The p-type impurity concentration of the column regions 24 is preferably adjusted by at least one type of trivalent element. The p-type impurity concentration of the column regions 24 is particularly preferably adjusted by a trivalent element belonging to heavy elements heavier than carbon.

That is, the column regions 24 preferably contain a trivalent element other than boron (at least one type among aluminum, gallium, and indium). In this embodiment, the p-type impurity concentration of the column regions 24 is adjusted by aluminum.

The plurality of column regions 24 each have a column width WC in the first array direction Da1. The column width WC may be substantially equal to the trench width WT. The column width WC may be greater than the trench width WT. The column width WC may be less than the trench width WT. The column width WC may be less than the trench depth DT. The column width WC may be greater than the trench depth DT. The column width WC is preferably less than the second thickness T2 of the semiconductor layer 7. The column width WC is preferably less than the thickness of the high concentration region 15.

The column width WC may be not less than 0.1 μm and not more than 5 μm. The column width WC may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The plurality of column regions 24 each have a column thickness TC (region depth). The column thickness TC is preferably less than the second thickness T2 of the semiconductor layer 7. The column thickness TC is preferably less than the thickness of the high concentration region 15. The column thickness TC is preferably greater than the trench width WT. The column thickness TC is preferably not less than the trench depth DT. The column thickness TC is particularly preferably greater than the trench depth DT. As a matter of course, the column thickness TC may be less than the trench depth DT.

The column thickness TC may be not less than 1 times and not more than 5 times the trench depth DT. A ratio TC/DT of the column thickness TC with respect to the trench depth DT may have a value falling within any one of ranges of not less than 1 and not more than 1.5, not less than 1.5 and not more than 2, not less than 2 and not more than 2.5, not less than 2.5 and not more than 3, not less than 3 and not more than 3.5, not less than 3.5 and not more than 4, not less than 4 and not more than 4.5, and not less than 4.5 and not more than 5.

The column thickness TC is preferably greater than the column width WC. That is, each of the plurality of column regions 24 preferably has an aspect ratio TC/WC of extending in a vertically long columnar shape along the second axis channel C2. The aspect ratio TC/WC is a ratio of the column thickness TC with respect to the column width WC.

The column thickness TC is preferably not less than 1 μm and not more than 5 μm. The column thickness TC may have a value falling within any one of ranges of not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The plurality of column regions 24 are formed at intervals, each of a column pitch PC, in the first array direction Da1. The column pitch PC may be substantially equal to the trench pitch PT. The column pitch PC may be greater than the trench pitch PT. The column pitch PC may be less than the trench pitch PT.

The column pitch PC is preferably less than the column thickness TC. The column pitch PC is preferably less than the trench depth DT. The column pitch PC is preferably less than the second thickness T2 of the semiconductor layer 7. The column pitch PC is preferably less than the thickness of the high concentration region 15.

The column pitch PC may be not less than 0.1 μm and not more than 5 μm. The column pitch PC may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The column pitch PC is preferably not less than 0.5 μm and not more than 1.5 μm.

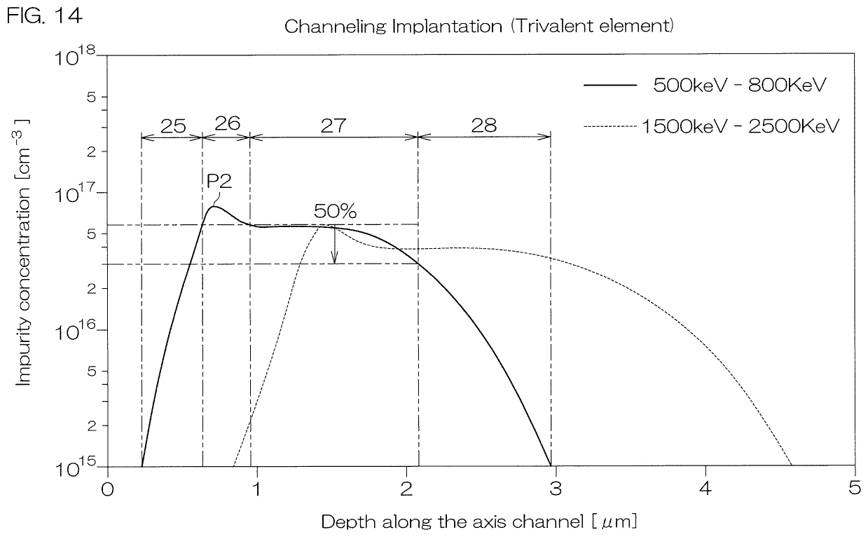

A p-type concentration gradient of each column region 24 shall now be described specifically. FIG. 14 is a graph showing an example of the p-type concentration gradient of the column region 24. In FIG. 14, the ordinate shows the p-type impurity concentration of the column region 24 and the abscissa shows a depth along the second axis channel C2 with the bottom walls of the trench structures 20 as a basis (zero point).

In FIG. 14, a region having a p-type impurity concentration of not less than 1×10¹⁵ cm⁻³ is defined as the column region 24 and illustrated as a graph. Numerical values of impurity concentration, thickness, etc., indicated below are examples for describing the basic arrangement of the column region 24 based on the concentration gradient and are not indicated with the intention of unequivocally restricting the arrangement of the column region 24. The impurity concentration, thickness, etc., are adjusted to various values in accordance with implantation conditions (dose amount, implantation temperature, implantation energy, etc.) of the trivalent element, etc.

FIG. 14 is a graph for a case where the column region 24 is formed by the channeling implantation method. FIG. 14 shows the concentration gradient of the column region 24 when a predetermined trivalent element (here, aluminum) is introduced into the lower region 7a in parallel or substantially in parallel to the second axis channel C2 by an implantation energy of not less than 500 KeV and not more than 800 KeV.

The dose amount of the trivalent element is 1×10¹³ cm⁻². The trench depth DT is approximately 1 μm and the thickness of the lower region 7a is approximately 4 μm. In FIG. 14, the concentration gradient when the column region 24 is formed by an implantation energy of not less than 1500 KeV and not more than 2500 KeV is indicated by a broken line.

With reference to FIG. 14, the column region 24 has the thickness of not less than 2.5 μm and not more than 2.8 μm and has the upper end portion that is separated to the lower end side of the semiconductor layer 7 from the bottom walls of the trench structures 20 and the lower end portion that is separated to the upper end side from the lower end of the semiconductor layer 7.

The p-type impurity concentration of the column region 24 has the concentration gradient that includes, from the upper end portion side toward the lower end portion side, a second gradual increase portion 25, a second peak portion 26, a second gentle gradient portion 27, and a second gradual decrease portion 28. The second gradual increase portion 25 is a portion that forms the upper end portion of the column region 24 and the p-type impurity concentration increases gradually to the second peak portion 26 at a comparatively steep increase rate from the upper end portion toward the lower end portion side. In this embodiment, the second gradual increase portion 25 is positioned inside the high concentration region 15 and is electrically connected to the high concentration region 15.

The second peak portion 26 is a portion having a second peak value P2 (maximum value) of the p-type impurity concentration. The second peak portion 26 is also a main concentration transition portion of convex shape that includes a series of concentration changes (an inflection point) with which the p-type impurity concentration changes from increasing (an increasing trend) to decreasing (a decreasing trend). The second peak portion 26 is electrically connected to the high concentration region 15. In this embodiment, the second peak value P2 is positioned further to the lower end side of the semiconductor layer 7 than the first peak value P1 of the high concentration region 15.

The second gentle gradient portion 27 is formed in a region further to the lower end portion side than the second peak portion 26 and is a portion in which the impurity concentration decreases gradually at a comparatively slow decrease rate. That is, the second gentle gradient portion 27 is a portion in which a fixed p-type impurity concentration is maintained across a fixed depth range and forms a main body portion of the column region 24. The p-type impurity concentration of the second gentle gradient portion 27 decreases gradually within a concentration range of less than the p-type impurity concentration of the second peak portion 26.

The second gentle gradient portion 27 is defined by a portion having a concentration decrease rate of not more than 50% within a thickness range of at least 0.5 μm. In the example of FIG. 14, the second gentle gradient portion 27 has a thickness of not less than 1 μm and not more than 1.3 μm and has the concentration decrease rate of not more than 50% within this thickness range. The second gentle gradient portion 27 is positioned in the high concentration region 15 and is electrically connected to the high concentration region 15. The second gentle gradient portion 27 may have a portion positioned within a thickness range between the lower end of the semiconductor layer 7 and the lower end portion of the high concentration region 15 and be electrically connected to the semiconductor layer 7.

The second gentle gradient portion 27 occupies a thickness range of not less than ¼ of the column region 24. Specifically, a proportion of the column region 24 occupied by the second gentle gradient portion 27 is not less than ⅓. The proportion of the column region 24 occupied by the second gentle gradient portion 27 is typically not more than ½ (or less than ½). As a matter of course, the proportion of the column region 24 occupied by the second gentle gradient portion 27 may be not less than ½.

The second gradual decrease portion 28 is a portion that forms the lower end portion of the column region 24. The second gradual decrease portion 28 has a concentration decrease rate that is greater than the concentration decrease rate in the second gentle gradient portion 27 and is a portion in which the p-type impurity concentration decreases gradually from the second gentle gradient portion 27 toward the lower end portion. A concentration decrease rate per unit thickness of the second gradual decrease portion 28 is greater than a concentration decrease rate per unit thickness of the second gentle gradient portion 27. The second gradual decrease portion 28 is positioned within the thickness range between the lower end of the semiconductor layer 7 and the lower end portion of the high concentration region 15 and is electrically connected to the semiconductor layer 7.

In the case of the channeling implantation method, the thickness (the depth) of the column region 24 increases with increase in implantation energy. A depth position of the upper end portion of the column region 24 with respect to the bottom walls of trench structures 20 increases with increase in implantation energy. A thickness of the second gradual increase portion 25, a thickness of the second peak portion 26, the thickness of the second gentle gradient portion 27, and a thickness of the second gradual decrease portion 28 increase with increase in implantation energy. On the other hand, the second peak value P2 of the column region 24 decreases with increase in implantation energy. This is because, with increase in implantation energy, the trivalent element is introduced to a deeper region and the p-type impurity concentration of this deeper region increases.

Oppositely, the depth position of the upper end portion of the column region 24 with respect to the bottom walls of the trench structures 20 decreases with decrease in implantation energy. The thickness of the second gradual increase portion 25, the thickness of the second peak portion 26, the thickness of the second gentle gradient portion 27, and the thickness of the second gradual decrease portion 28 decrease with decrease in implantation energy. On the other hand, the second peak value P2 of the column region 24 increases with decrease in implantation energy. This is because, with decrease in implantation energy, the introduction of the trivalent element is obstructed in a shallow region.

It must be borne in mind that, since a trivalent element is introduced into the semiconductor layer 7 in place of a pentavalent element in the case of the column region 24, even when the same process conditions as process conditions for the high concentration region 15 are applied, a concentration profile and the thickness (the depth) of the column region 24 will differ from a concentration profile and the thickness (the depth) of the high concentration region 15. Therefore, to achieve an appropriate charge balance, it is preferable to set the process conditions for the column region 24 and the process conditions for the high concentration region 15 separately.

The SiC semiconductor device 1 includes a plurality of drift regions 29 of the n-type that are formed inside the semiconductor layer 7. The plurality of drift regions 29 are respectively constituted of regions of the semiconductor layer 7 demarcated by the plurality of column regions 24. Inside the semiconductor layer 7, the plurality of drift regions 29 are arrayed at intervals in the first array direction Da1 and are each demarcated in a band shape extending in the first extension direction De1.

That is, the plurality of drift regions 29 are arrayed at intervals in the m-axis direction (the first direction X) and extend in the a-axis direction (the second direction Y) of the SiC monocrystal. The plurality of drift regions 29 are arrayed as stripes extending in the a-axis direction (the second direction Y). The extension direction of the plurality of drift regions 29 is matched with the off direction Do of the semiconductor layer 7.

In this embodiment, the plurality of drift regions 29 are formed by portions of the semiconductor layer 7 and portions of the high concentration region 15. The portions of the plurality of drift regions 29 that include the high concentration region 15 are constituted of the channeling region of the n-type that extends along the second axis channel C2.

The plurality of drift regions 29, together with the plurality of column regions 24, form a plurality of pn-junction portions having a charge balance. A state of having a charge balance means a state where, for the plurality of column regions 24 that are mutually adjacent, depletion layers spreading from the pn-junction portions at one side and depletion layers spreading from the pn-junction portions at another side are connected inside the plurality of drift regions 29.

In this embodiment, the plurality of drift regions 29 (the semiconductor layer 7) of the n-type that are adjusted in concentration by the high concentration region 15 form the charge balance with the plurality of column regions 24 of the p-type that are adjusted in concentration. The plurality of drift regions 29 form a super junction structure with the plurality of column regions 24 in the lower region 7a.

With reference to FIG. 6 to FIG. 11, the SiC semiconductor device 1 includes a plurality of body regions 30 of the p-type that are formed in a surface layer portion of the first main surface 3 (the active surface 10). The plurality of body regions 30 are respectively formed in regions between the plurality of trench structures 20 that are mutually adjacent in the surface layer portion of the first main surface 3 (the active surface 10). The plurality of body regions 30 are arrayed at intervals along the first extension direction De1 such as to be connected to the plurality of trench structures 20 positioned at both sides.

The plurality of body regions 30 at one side that are arrayed along the side walls at the one side of the trench structures 20 face, in one-to-one correspondence, the plurality of body regions 30 at another side that are arrayed along the side walls at the other side of the trench structures 20. That is, the plurality of body regions 30 are arrayed in a matrix at intervals in the first array direction Da1 and the first extension direction De1 in plan view.

The plurality of body regions 30 have portions exposed from the side walls of the trenches 21 at opening ends of the trenches 21 and face the embedded electrodes 23 with the insulating films 22 interposed therebetween. The plurality of body regions 30 are formed at intervals to the active surface 10 side from the bottom walls of the plurality of trench structures 20 and face the plurality of drift regions 29 in the lamination direction.

An outermost plurality of body regions 30 that are positioned at peripheral edge sides of the active surface 10 may be formed in the surface layer portion of the active surface 10 at intervals inward from the peripheral edges of the active surface 10 (from the first to fourth connecting surfaces 12A to 12D). The outermost plurality of body regions 30 are preferably formed in the surface layer portion of the active surface 10 at intervals inward from both end portions of the plurality of trench structures 20. As a matter of course, the outermost plurality of body regions 30 may be positioned further to the peripheral edge sides of the active surface 10 than both end portions of the plurality of trench structures 20. In this case, the outermost plurality of body regions 30 may be exposed from the first to fourth connecting surfaces 12A to 12D.

A length in the first extension direction De1 of each body region 30 is preferably greater than the column width WC. The length in the first extension direction De1 of the body region 30 is preferably greater than the column pitch PC. The length in the first extension direction De1 of the body region 30 is preferably greater than the trench width WT. The length in the first extension direction De1 of the body region 30 is preferably greater than the trench pitch PT.

As a matter of course, the length in the first extension direction De1 of the body region 30 may instead be less than the column width WC. The length in the first extension direction De1 of the body region 30 may be less than the column pitch PC. The length in the first extension direction De1 of the body region 30 may be less than the trench width WT. The length in the first extension direction De1 of the body region 30 may be less than the trench pitch PT.

The body regions 30 are constituted of random regions introduced into a surface layer portion of the semiconductor layer 7 by the random implantation method performed on the semiconductor layer 7. Thus, unlike the column regions 24, the body regions 30 do not have a gentle gradient portion such as the first gentle gradient portion 18. The body regions 30 have a thickness less than thickness of the column regions 24 in regard to a direction along the second axis channel C2.

The body regions 30 may have a p-type impurity concentration of not less than 1×10¹⁵ cm⁻³ and not more than 1×10¹⁸ cm⁻³ as a peak value. The p-type impurity concentration (peak value) of the body regions 30 may be less than the p-type impurity concentration (peak value) of the column regions 24. As a matter of course, the p-type impurity concentration (peak value) of the body regions 30 may be higher than the p-type impurity concentration (peak value) of the column regions 24.

The p-type impurity concentration of the body regions 30 is preferably adjusted by at least one type of trivalent element. The trivalent element of the body regions 30 may be at least one type among boron, aluminum, gallium, and indium.

The SiC semiconductor device 1 includes a plurality of surface layer drift regions 31 of the n-type that are respectively demarcated in regions between the plurality of body regions 30 in the regions between the plurality of trench structures 20 that are mutually adjacent. The plurality of surface layer drift regions 31 are each constituted of a portion of the semiconductor layer 7 and are electrically connected to the plurality of drift regions 29 positioned directly below. The plurality of surface layer drift regions 31 may include portions of the high concentration region 15.

The plurality of surface layer drift regions 31 at one side that are arrayed along the side walls at the one side of the trench structures 20 face, in one-to-one correspondence, the plurality of surface layer drift regions 31 at another side that are arrayed along the side walls at the other side of the trench structures 20. That is, the plurality of surface layer drift regions 31 are arrayed in a matrix at intervals in the first array direction Da1 and the first extension direction De1 in plan view.

A length in the first extension direction De1 of each surface layer drift region 31 is preferably greater than the column width WC. The length in the first extension direction De1 of the surface layer drift region 31 is preferably greater than the column pitch PC. The length in the first extension direction De1 of the surface layer drift region 31 is preferably greater than the trench width WT. The length in the first extension direction De1 of the surface layer drift region 31 is preferably greater than the trench pitch PT.

As a matter of course, the length in the first extension direction De1 of the surface layer drift region 31 may instead be less than the column width WC. The length in the first extension direction De1 of the surface layer drift region 31 may be less than the column pitch PC. The length in the first extension direction De1 of the surface layer drift region 31 may be less than the trench width WT. The length in the first extension direction De1 of the surface layer drift region 31 may be less than the trench pitch PT.

The SiC semiconductor device 1 includes a plurality of intermediate regions 32 of the p-type that are respectively interposed in regions inside the semiconductor layer 7 between the bottom walls of the plurality of trench structures 20 and the plurality of column regions 24. In this embodiment, a plurality of intermediate regions 32 are interposed in a region between the bottom wall of the single trench structure 20 and the upper end portion of the single column region 24.

The plurality of intermediate regions 32 are respectively formed directly below the corresponding trench structure 20 at intervals along the first extension direction De1 (the second direction Y). Specifically, the plurality of intermediate regions 32 are arrayed at intervals in the first extension direction De1 (the second direction Y) such as to be positioned on virtual rectilinear lines joining the plurality of body regions 30 in the first array direction Da1 (the first direction X) in plan view.

That is, for trench structures 20 at one side and another side, the plurality of intermediate regions 32 at the one side that are positioned directly below the trench structure 20 at the one side are formed at intervals in the first array direction Da1 (the first direction X) from the plurality of intermediate regions 32 at the other side that are positioned directly below the plurality of trench structures 20 at the other side.

The plurality of intermediate regions 32 at the one side face the plurality of intermediate regions 32 at the other side in one-to-one correspondence in the first array direction Da1 (the first direction X) with a portion of the semiconductor layer 7 (a portion of the high concentration region 15) interposed therebetween. As a matter of course, the plurality of intermediate regions 32 at the one side may instead face regions between the plurality of intermediate regions 32 at the other side in one-to-one correspondence in the first array direction Da1.

In regard to the first extension direction De1, each intermediate region 32 preferably has a width less than the length of the body region 30. The width of each intermediate region 32 may be greater than the column width WC. The width of each intermediate region 32 may be greater than the column pitch PC. As a matter of course, the width of each intermediate region 32 may instead be less than the column width WC. The width of each intermediate region 32 may be less than the column pitch PC.

The width of each intermediate region 32 may be greater than the trench width WT. The width of each intermediate region 32 may be greater than the trench pitch PT. As a matter of course, the width of each intermediate region 32 may instead be less than the trench width WT. The width of each intermediate region 32 may be less than the trench pitch PT.

The plurality of intermediate regions 32 are each connected to the bottom wall of the trench structure 20 and the upper end portion of the column region 24. Further, the plurality of intermediate regions 32 each have portions that protrude to both sides of the trench structure 20 from a region directly below the trench structure 20 and extend along the side walls of the trench structure 20.

The plurality of intermediate regions 32 are electrically connected to the body region 30 in the surface layer portion of the first main surface 3 (active surface 10). That is, the plurality of intermediate regions 32 electrically connect the plurality of column regions 24 to the body region 30. The plurality of column regions 24 are thereby suppressed from being in an electrically floating state.

The plurality of intermediate regions 32 may extend inside the body region 30 in the vertical direction Z along the side walls of the trench structures 20 and be exposed from the first main surface 3. In this case, the plurality of intermediate regions 32 may each have a portion that extends in the horizontal directions in the surface layer portion of the first main surface 3. Intermediate regions 32 that are mutually adjacent in the first array direction Da1 (the first direction X) of the plurality of trench structures 20 are formed at intervals in the surface layer portion of the first main surface 3. As a matter of course, the intermediate regions 32 that are mutually adjacent may be connected to each other in the surface layer portion of the first main surface 3.

The plurality of intermediate regions 32 relax an electric field with respect to the trench structures 20. The plurality of intermediate regions 32 do not necessarily have to form a charge balance together with the plurality of drift regions 29. As a matter of course, the plurality of intermediate regions 32 may form, together with the plurality of drift regions 29, a plurality of pn-junction portions having a charge balance.

The plurality of intermediate regions 32 are constituted of random regions introduced into surface layer portions of the plurality of drift regions 29 by the random implantation method performed on the semiconductor layer 7. That is, the plurality of intermediate regions 32 have a thickness less than the thickness of the plurality of column regions 24 in regard to the direction along the second axis channel C2. Also, the plurality of intermediate regions 32 do not have the second gentle gradient portion 27 having a thickness of not less than 0.5 μm in regard to the direction along the second axis channel C2.

The plurality of intermediate regions 32 may have a p-type impurity concentration of not less than 1×10¹⁵ cm⁻³ and not more than 1×10¹⁸ cm⁻³ as a peak value. The intermediate regions 32 may have a p-type impurity concentration (peak value) higher than the p-type impurity concentration (peak value) of the body regions 30.

The p-type impurity concentration (peak value) of the intermediate regions 32 may be less than the p-type impurity concentration (peak value) of the body regions 30. The p-type impurity concentration (peak value) of the intermediate regions 32 may be higher than the p-type impurity concentration (peak value) of the column regions 24. The p-type impurity concentration (peak value) of the intermediate regions 32 may be less than the p-type impurity concentration (peak value) of the column regions 24.

The p-type impurity concentration of the intermediate regions 32 is preferably adjusted by at least one type of trivalent element. The trivalent element of the intermediate regions 32 may be of the same type as the trivalent element of the column regions 24 or may be of a different type from the trivalent element of the column regions 24. The trivalent element of the intermediate regions 32 may be at least one type among boron, aluminum, gallium, and indium.

The SiC semiconductor device 1 includes a plurality of source regions 33 that are formed at both sides of the plurality of trench structures 20 in the surface layer portion of the first main surface 3 (the active surface 10). The plurality of source regions 33 are respectively formed in surface layer portions of the body regions 30. In this embodiment, two source regions 33 are formed at an interval in the surface layer portion of each body region 30.

The plurality of source regions 33 have a higher n-type impurity concentration (peak value) than the semiconductor layer 7. The n-type impurity concentration of the plurality of source regions 33 is higher than the n-type impurity concentration of the high concentration region 15. The plurality of source regions 33 may have an n-type impurity concentration of not less than 1×10¹⁸ cm⁻³ and not more than 1×10²¹ cm⁻³ as a peak value.

The plurality of source regions 33 are formed in the surface layer portions of the respective body regions 30 at intervals in the first extension direction De1. Specifically, the source regions 33 at one side are formed in the surface layer portions at one end portion side of the body regions 30 and the source regions 33 at another side are formed in the surface layer portions at another end portion side of the body regions 30 at intervals in the first extension direction De1 from the source regions 33 at the one side. The plurality of source regions 33 are connected to the plurality of trench structures 20 positioned at both sides.

The plurality of source regions 33 at one side that are arrayed along the side walls at the one side of the trench structures 20 face, in one-to-one correspondence, the plurality of source regions 33 at another side that are arrayed along the side walls at the other side of the trench structures 20. That is, the plurality of source regions 33 are arrayed in a matrix at intervals in the first array direction Da1 and the first extension direction De1 in plan view.

The plurality of source regions 33 have portions exposed from the side walls of the trenches 21 at the opening ends of the trenches 21 and face the embedded electrodes 23 with the insulating films 22 interposed therebetween. The plurality of source regions 33 are formed at intervals to the active surface 10 side from bottom portions of the body regions 30 and face the drift regions 29 (the semiconductor layer 7/the high concentration region 15) directly below with portions of the body regions 30 interposed therebetween in the lamination direction.

The source regions 33 at the one side are formed at intervals inward from one end portions of the respective body regions 30 and, together with the corresponding surface layer drift regions 31, demarcate channels Ch, which serve as current paths, in surface layer portions at the one end portion side of the respective body regions 30. The source regions 33 at the other side are formed at intervals inward from other end portions of the respective body regions 30 and, together with the corresponding surface layer drift regions 31, demarcate channels Ch, which serve as current paths, in surface layer portions at the other end portion side of the respective body regions 30.

That is, the plurality of source regions 33, together with the plurality of surface layer drift regions 31, demarcate the plurality of channels Ch that extend in the horizontal directions (the first array direction Da1 and the first extension direction De1). The plurality of channels Ch at the one side that are demarcated along the side walls at the one side of the trench structures 20 face, in one-to-one correspondence, the plurality of channels Ch at the other side that are demarcated along the side walls at the other side of the trench structures 20. That is, the plurality of channels Ch are arrayed in a matrix at intervals in the first array direction Da1 and the first extension direction De1 in plan view.

The SiC semiconductor device 1 includes a plurality of contact regions 34 that are formed in regions between the plurality of trench structures 20 in the surface layer portion of the first main surface 3 (the active surface 10). The plurality of contact regions 34 are respectively formed in the surface layer portions of the plurality of body regions 30. In this embodiment, the single contact region 34 is formed in the surface layer portion of each body region 30.

The plurality of contact regions 34 have a higher p-type impurity concentration (peak value) than the p-type impurity concentration (peak value) of the body region 30. The p-type impurity concentration (peak value) of the plurality of contact regions 34 is higher than the p-type impurity concentration (peak value) of the plurality of column regions 24. The p-type impurity concentration (peak value) of the plurality of contact regions 34 is higher than the p-type impurity concentration (peak value) of the plurality of intermediate regions 32. The plurality of contact regions 34 may have a p-type impurity concentration of not less than 1×10¹⁸ cm⁻³ and not more than 1×10²¹ cm⁻³ as a peak value.

In the surface layer portions of the plurality of body regions 30, the plurality of contact regions 34 are respectively formed in regions between the plurality of source regions 33 that are mutually adjacent. The plurality of contact regions 34 are electrically connected to the plurality of intermediate regions 32 via the body regions 30. That is, the plurality of contact regions 34 are electrically connected to the plurality of column regions 24 via the plurality of intermediate regions 32.

The plurality of contact regions 34 are connected to the plurality of trench structures 20 positioned at both sides. The plurality of contact regions 34 at one side that are arrayed along the side walls at the one side of the trench structures 20 face, in one-to-one correspondence, the plurality of contact regions 34 at another side that are arrayed along the side walls at the other side of the trench structures 20. That is, the plurality of contact regions 34 are arrayed in a matrix at intervals in the first array direction Da1 and the first extension direction De1 in plan view.

The plurality of contact regions 34 are preferably positioned on virtual rectilinear lines joining the plurality of intermediate regions 32 in the first array direction Da1 (the first direction X) in plan view. In this case, the plurality of contact regions 34 may be connected to the intermediate regions 32 inside the body regions 30. As a matter of course, the plurality of contact regions 34 may instead be shifted in the first extension direction De1 from the plurality of intermediate regions 32. In this case, the plurality of contact regions 34 may be connected to the plurality of intermediate regions 32 or may be formed at intervals from the plurality of intermediate regions 32.

The plurality of contact regions 34 have portions exposed from the side walls of the trenches 21 at the opening ends of the trenches 21 and face the embedded electrodes 23 with the insulating films 22 interposed therebetween. The plurality of contact regions 34 are formed at intervals to the active surface 10 side from the bottom portions of the body regions 30 and face the semiconductor layer 7 (the high concentration region 15) with portions of the body regions 30 interposed therebetween.

With this embodiment, a configuration example in which the plurality of contact regions 34 are constituted separately from the plurality of intermediate regions 32 was illustrated. However, the plurality of contact regions 34 may instead be formed using portions of the plurality of intermediate regions 32. That is, portions of the plurality of intermediate regions 32 that are positioned inside the body regions 30 may be deemed to be the contact regions 34.

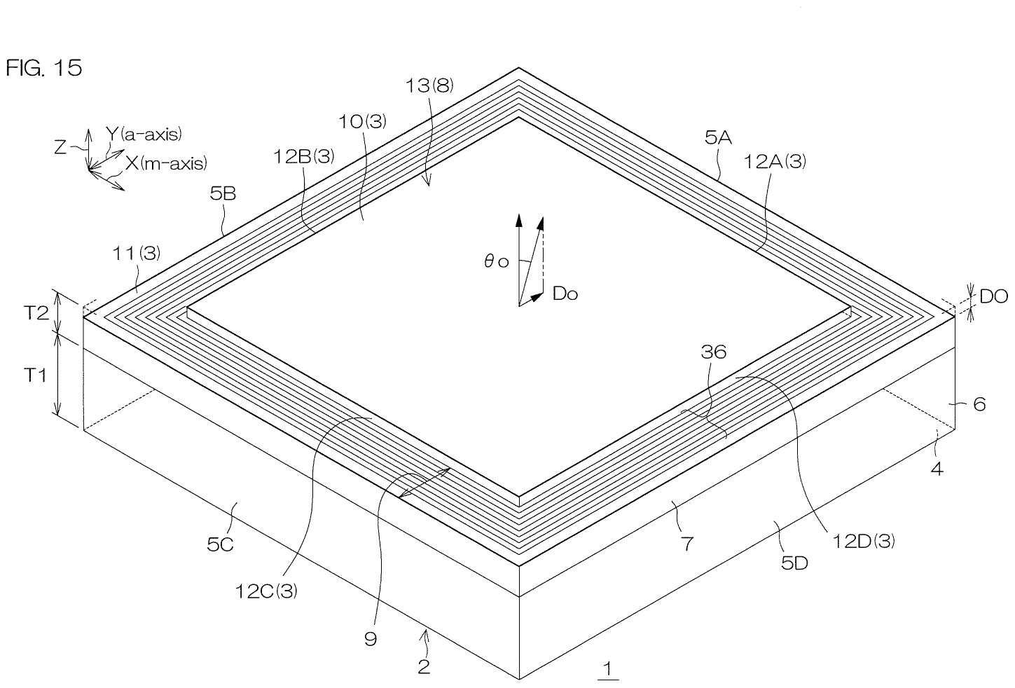

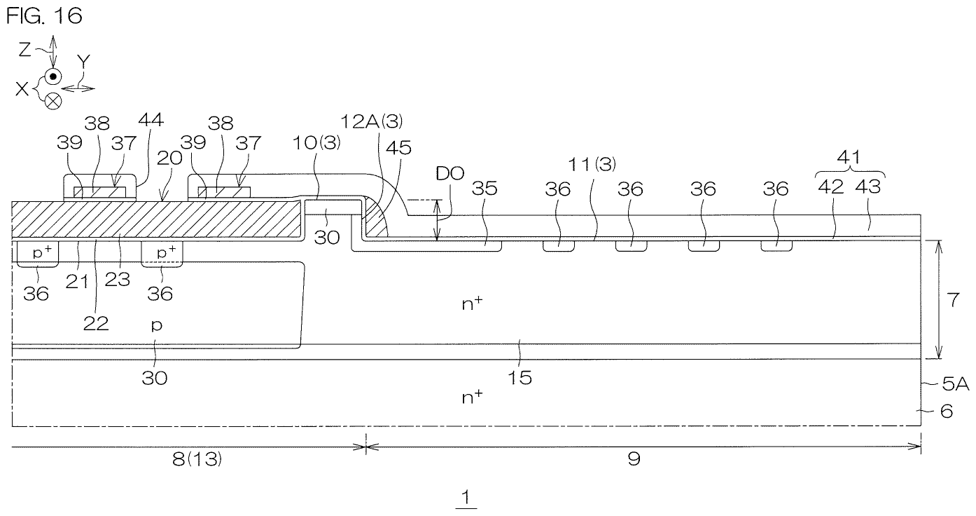

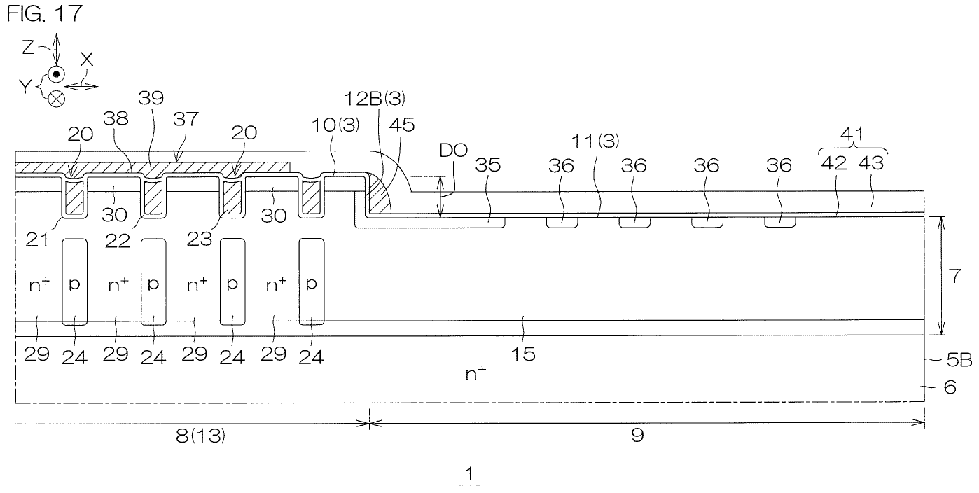

An arrangement at the outer peripheral region 9 side shall now be illustrated. FIG. 15 is a perspective view showing an arrangement of the outer peripheral region 9. FIG. 16 is a cross-sectional view showing a main portion of the outer peripheral region 9. FIG. 17 is a cross-sectional view showing a main portion of the outer peripheral region 9.

The SiC semiconductor device 1 includes a well region 35 of the p-type that is formed in a surface layer portion of the outer surface 11. In plan view, the well region 35 is formed at intervals to the active surface 10 side from the peripheral edges of the outer surface 11 (from the first to fourth side surfaces 5A to 5D) and extends in a band shape along the active surface 10. In this embodiment, the well region 35 is formed in an annular shape (specifically, a quadrangle annular shape) surrounding the active surface 10 in plan view.

The well region 35 is led out from the surface layer portion of the outer surface 11 to the first to fourth connecting surfaces 12A to 12D sides and extends along surface layer portions of the first to fourth connecting surfaces 12A to 12D. The well region 35 may be electrically connected to the body region 30 in a surface layer portion of the active surface 10. The well region 35 may be electrically connected to the plurality of column regions 24.

The well region 35 is formed at an interval to the outer surface 11 side from the lower end of the semiconductor layer 7 and faces the base layer 6 with a portion of the semiconductor layer 7 interposed therebetween. Specifically, the well region 35 is formed at an interval to the outer surface 11 side from the bottom portion of the high concentration region 15 and is positioned further to the bottom portion side of the high concentration region 15 than the bottom walls of the trench structures 20. The well region 35 forms a pn-junction portion with the semiconductor layer 7 (high concentration region 15).

The well region 35 is constituted of a random region introduced into a surface layer portion of the semiconductor layer 7 by the random implantation method performed on the semiconductor layer 7. The well region 35 has a thickness less than the thickness of the high concentration region 15 in regard to the direction along the second axis channel C2. Also, the thickness of the well region 35 is less than the thickness of the column regions 24.

Unlike the column regions 24, the well region 35 does not have a gentle gradient portion having a thickness of not less than 0.5 μm. The well region 35 may have a p-type impurity concentration of not less than 1×10¹⁵ cm⁻³ and not more than 1×10¹⁸ cm⁻³ as a peak value. The well region 35 has a lower p-type impurity concentration than the p-type impurity concentration of the contact regions 34.

The p-type impurity concentration of the well region 35 may be higher than the p-type impurity concentration of the body region 30. As a matter of course, the p-type impurity concentration of the well region 35 may be lower than that of the body region 30. The p-type impurity concentration of the well region 35 may be substantially equal to the p-type impurity concentration of the intermediate regions 32. As a matter of course, the p-type impurity concentration of the well region 35 may be higher than the p-type impurity concentration of the intermediate regions 32 or may be lower than that of the intermediate regions 32.

The p-type impurity concentration of the well region 35 is preferably adjusted by at least one type of trivalent element. The trivalent element of the well region 35 may be of the same type as the trivalent element of the column regions 24 or may be of a different type from the trivalent element of the column regions 24. The trivalent element of the well region 35 may be at least one type among boron, aluminum, gallium, and indium.

The SiC semiconductor device 1 includes at least one (preferably 2 or more and not more than 20) of a field region 36 of the p-type formed in a surface layer portion of the outer surface 11 (the first main surface 3) in the outer peripheral region 9. The number of the plurality of the field regions 36 is typically not less than 4 and not more than 8. The plurality of field regions 36 are formed in an electrically floating state and relax an electric field inside the chip 2 at peripheral edge portions of the first main surface 3. The number, a width, a depth, a p-type impurity concentration, etc., of the field regions 36 are arbitrary and can take on various values in accordance with the electric field to be relaxed.

In this embodiment, the plurality of field regions 36 are arrayed at intervals from the peripheral edges of the active surface 10 (from the first to fourth connecting surfaces 12A to 12D) and from the peripheral edges (the first to fourth side surfaces 5A to 5D) of the chip 2. Specifically, the plurality of field regions 36 are arrayed at intervals to the peripheral edge sides of the outer surface 11 from the well region 35.

The plurality of field regions 36 are formed in band shapes extending along the active region 8 in plan view. The plurality of field regions 36 each have portions extending in a band shape in the first direction X and portions extending in a band shape in the second direction Y. In this embodiment, the plurality of field regions 36 are formed in annular shapes (specifically, quadrangle annular shapes) surrounding the active region 8 (that is, the plurality of column regions 24) in plan view.

The plurality of field regions 36 are formed inside the semiconductor layer 7 at intervals to the outer surface 11 side from the lower end of the semiconductor layer 7 and form pn-junction portions with the semiconductor layer 7. The plurality of field regions 36 preferably have bottom portions positioned at the outer surface 11 side with respect to the thickness range intermediate portion of the semiconductor layer 7. Preferably, the plurality of field regions 36 are formed at intervals to the outer surface 11 side from the bottom portion of the high concentration region 15 and form pn-junction portions with the high concentration region 15.

In this embodiment, the plurality of field regions 36 are formed at intervals to the peripheral edge sides of the chip 2 from the plurality of column regions 24. The plurality of field regions 36 thus do not face the plurality of column regions 24 in the lamination direction. The plurality of field regions 36 are positioned further to the bottom portion side of the semiconductor layer 7 (the high concentration region 15) than the bottom walls of the trench structures 20.

The bottom portions of the plurality of field regions 36 may be positioned further to the bottom portion side of the semiconductor layer 7 (the high concentration region 15) than the depth position of the upper end portions of the plurality of column regions 24. As a matter of course, the bottom portions of the plurality of field regions 36 may be positioned further to the bottom wall side of the trench structures 20 than the depth position of the upper end portions of the plurality of column regions 24.

The plurality of field regions 36 are constituted of random regions introduced into a surface layer portion of the semiconductor layer 7 by the random implantation method performed on the semiconductor layer 7. The plurality of field regions 36 have a thickness less than the thickness of the high concentration region 15 in regard to the direction along the second axis channel C2. Also, the thickness of the plurality of field regions 36 is less than the thickness of the column regions 24.

Unlike the column regions 24, etc., the plurality of field regions 36 do not have a gentle gradient portion having a thickness of not less than 0.5 μm. The plurality of field regions 36 may have a p-type impurity concentration of not less than 1×10¹⁵ cm⁻³ and not more than 1×10¹⁸ cm⁻³ as a peak value. The p-type impurity concentration of the plurality of field regions 36 may be substantially equal to the p-type impurity concentration of the body region 30. The p-type impurity concentration of the plurality of field regions 36 may be higher than the p-type impurity concentration of the body region 30. The p-type impurity concentration of the plurality of field regions 36 may be lower than the p-type impurity concentration of the body region 30.

The p-type impurity concentration of the plurality of field regions 36 is preferably adjusted by at least one type of trivalent element. The trivalent element of the field regions 36 may be of the same type as the trivalent element of the column regions 24 or may be of a different type from the trivalent element of the column regions 24. The trivalent element of the field regions 36 may be at least one type among boron, aluminum, gallium, and indium.

The plurality of field regions 36 preferably have a width differing from the column width WC of the column regions 24. That is, an electric field relaxation effect by the plurality of field regions 36 is preferably adjusted separately from the plurality of column regions 24. The width of the plurality of field regions 36 is particularly preferably greater than the column width WC. As a matter of course, the width of the plurality of field regions 36 may be smaller than the column width WC. Also, the width of the column regions 24 may be substantially equal to the column width WC.

The plurality of field regions 36 are preferably formed at a pitch differing from the column pitch PC of the column regions 24. The pitch of the plurality of field regions 36 is particularly preferably greater than the column pitch PC. The pitch of the plurality of field regions 36 may be smaller than the column pitch PC. The pitch of the plurality of field regions 36 may be substantially equal to the column pitch PC.

With reference again to FIG. 5 to FIG. 11, the SiC semiconductor device 1 includes a plurality of the gate structures 37 of a planar electrode type that are arranged on the first main surface 3 (the active surface 10). The gate structures 37 may be referred to as “planar gate structures.” A potential (second potential) different from the potential (first potential) applied to the trench structures 20 is applied to the plurality of gate structures 37. Specifically, the gate potential is applied as a control potential to the plurality of gate structures 37.

The plurality of gate structures 37 are arranged at intervals inward from the peripheral edges of the active surface 10 (from the first to fourth connecting surfaces 12A to 12D) in the active region 8. The plurality of gate structures 37 are arrayed at intervals on the first main surface 3 such as to overlap with the plurality of channels Ch in the lamination direction and control inversion and non-inversion of the plurality of channels Ch inside the body regions 30 in response to the gate potential.

Specifically, the plurality of gate structures 37 are arrayed at intervals in a second array direction Da2 other than the first array direction Da1 and are each formed in a band shape extending in a second extension direction De2 other than the first extension direction De1. In this embodiment, the plurality of gate structures 37 are arrayed in the second array direction Da2 that is orthogonal to the first array direction Da1 and extend in the second extension direction De2 that is orthogonal to the first extension direction De1.

That is, the plurality of gate structures 37 are arrayed at intervals in the a-axis direction (the second direction Y) of the SiC monocrystal and extend in the m-axis direction (the first direction X) of the SiC monocrystal. Also, the plurality of gate structures 37 are arrayed as stripes extending in the m-axis direction (the first direction X). The second extension direction De2 is orthogonal to the off direction Do of the SiC monocrystal.

In plan view, the plurality of gate structures 37 intersect (specifically, are orthogonal to) the plurality of trench structures 20, the plurality of column regions 24, and the plurality of drift regions 29 and cover the plurality of channels Ch that are mutually adjacent in the first array direction Da1 (the second extension direction De2). In regard to the single trench structure 20, the plurality of gate structures 37 intersect the single trench structure 20 at plural locations. The plurality of gate structures 37 are electrically insulated from the plurality of trench structures 20 at intersections with the plurality of trench structures 20.

In each region between two trench structures 20 that are mutually adjacent, the plurality of gate structures 37 each extend across two body regions 30 that are mutually adjacent in the first extension direction De1 (the second array direction Da2) and each cover the single corresponding surface layer drift region 31. The plurality of gate structures 37 each partially cover the source region 33 at one side that is formed inside the body region 30 at the one side and partially cover the source region 33 at another side that is formed inside the body region 30 at the other side. The plurality of gate structures 37 expose the plurality of contact regions 34.

In this embodiment, the plurality of gate structures 37 are shifted in the first extension direction De1 (the second array direction Da2) from virtual rectilinear lines joining the plurality of intermediate regions 32 in the first array direction Da1 (the first direction X) in plan view. The plurality of gate structures 37 are thus positioned in regions between the plurality of intermediate regions 32 in plan view. As a matter of course, the plurality of gate structures 37 may have portions positioned on the virtual rectilinear lines joining the plurality of intermediate regions 32 in the first array direction Da1 (the first direction X) in plan view.

Each gate structure 37 has a gate width WG in the second array direction Da2. The gate width WG is preferably greater than the column width WC. The gate width WG is preferably greater than the column pitch PC. The gate width WG is preferably greater than the trench width WT. The gate width WG is preferably greater than the trench pitch PT. As a matter of course, the gate width WG may be less than the column width WC. The gate width WG may be less than the column pitch PC. The gate width WG may be less than the trench width WT. The gate width WG may be less than the trench pitch PT.

The plurality of gate structures 37 are arrayed with a gate pitch PG therebetween in the second array direction Da2. The gate pitch PG may be greater than the column width WC. The gate pitch PG may be less than the column width WC. The gate pitch PG may be less than the column thickness TC. The gate pitch PG may be greater than the column thickness TC. The gate pitch PG may be greater than the column pitch PC. The gate pitch PG may be less than the column pitch PC.

The gate pitch PG may be greater than the trench width WT. The gate pitch PG may be less than the trench width WT. The gate pitch PG may be less than the trench depth DT. The gate pitch PG may be greater than the trench depth DT. The gate pitch PG may be greater than the trench pitch PT. The gate pitch PG may be less than the trench pitch PT.

The gate pitch PG is less than the first thickness T1. The gate pitch PG may be less than the second thickness T2. The gate pitch PG may be greater than the second thickness T2. The gate pitch PG may be less than the thickness of the high concentration region 15. The gate pitch PG may be greater than the thickness of the high concentration region 15.

Each gate structure 37 has a laminated structure that includes a gate insulating film 38 and a gate electrode 39 that are laminated in that order from the first main surface 3 side. The gate insulating film 38 has portions covering the first main surface 3 in a film shape and portions covering the plurality of trench structures 20 in a film shape. The gate insulating film 38 covers the wall surfaces (the side walls) of the trenches 21, the insulating films 22, and the embedded electrodes 23 in a film shape inside the trenches 21.

The gate insulating film 38 may include at least one among a silicon oxide film, a silicon nitride film, and a silicon oxynitride film. In this embodiment, the gate insulating film 38 has a single layer structure constituted of the silicon oxide film. In this case, the portions of the gate insulating film 38 covering the first main surface 3 may contain a silicon oxide that contains carbon. On the other hand, the portions of the gate insulating film 38 covering the embedded electrodes 23 may include a silicon oxide film that consists of an oxide of the embedded electrodes 23 (a polysilicon oxide).

The gate electrode 39 covers the gate insulating film 38 in a film shape. Specifically, the gate electrode 39 has portions covering the first main surface 3 in a film shape with the gate insulating film 38 interposed therebetween and portions covering the plurality of trench structures 20 in a film shape with the gate insulating film 38 interposed therebetween.

On the first main surface 3, the gate electrode 39 faces the plurality of body regions 30, the plurality of surface layer drift regions 31, the plurality of source regions 33, and the plurality of channels Ch with the gate insulating film 38 interposed therebetween. The gate electrode 39 covers the wall surfaces (the side walls) of the trenches 21, the insulating films 22, and the embedded electrodes 23 in a film shape with the gate insulating film 38 interposed therebetween inside the trenches 21.

Inside the trenches 21, the gate electrode 39 is electrically insulated from the embedded electrodes 23 by the gate insulating film 38. The gate electrode 39 may contain a conductive polysilicon of the p-type or the n-type. The conductivity type of the gate electrode 39 may be the same as the conductivity type of the embedded electrodes 23. The conductivity type of the gate electrode 39 may differ from the conductivity type of the embedded electrodes 23. In regard to the lamination direction, the gate electrode 39 preferably has a thickness less than the thickness of the embedded electrodes 23.

When the gate potential is applied to the gate electrode 39, the plurality of channels Ch positioned directly below the gate electrode 39 are brought into an on state. Current paths leading from the plurality of drift regions 29 to the plurality of source regions 33 via the plurality of surface layer drift regions 31 are thereby formed.

That is, the current paths that extend in the vertical direction Z along the plurality of drift regions 29 are formed in regions below the plurality of trench structures 20. Also, current paths extending in the vertical direction Z along the plurality of trench structures 20 and a plurality of current paths extending in the horizontal directions in the plurality of channels Ch (the regions between the plurality of surface layer drift regions 31 and the plurality of source regions 33) are formed in regions between the plurality of trench structures 20.

The SiC semiconductor device 1 includes an interlayer insulating film 41 that covers the first main surface 3. The interlayer insulating film 41 may be referred to as an “insulating film,” an “interlayer film,” an “intermediate insulating film,” etc. In this embodiment, the interlayer insulating film 41 has a laminated structure including a first insulating film 42 and a second insulating film 43. The first insulating film 42 may include at least one among a silicon oxide film, a silicon nitride film, and a silicon oxynitride film. The first insulating film 42 particularly preferably includes a silicon oxide film that consists of the oxide of the chip 2 (the semiconductor layer 7).

The first insulating film 42 selectively covers the first main surface 3 in the active region 8 and the outer peripheral region 9. Specifically, the first insulating film 42 selectively covers the active surface 10, the outer surface 11, and the first to fourth connecting surfaces 12A to 12D. On the active surface 10, the first insulating film 42 is connected to the insulating films 22 and the gate insulating films 38 and exposes the embedded electrodes 23 and the gate electrodes 39.

On the outer surface 11, the first insulating film 42 covers the well region 35 and the plurality of field regions 36. In this embodiment, the first insulating film 42 is continuous to the first to fourth side surfaces 5A to 5D. As a matter of course, the first insulating film 42 may instead be formed at intervals inward from the peripheral edges of the outer surface 11 and expose the semiconductor layer 7 from peripheral edge portions of the outer surface 11. On the first to fourth connecting surfaces 12A to 12D, the first insulating film 42 covers the body region 30 and the well region 35.

The second insulating film 43 is laminated on the first insulating film 42. The second insulating film 43 may include at least one among a silicon oxide film, a silicon nitride film, and a silicon oxynitride film. The interlayer insulating film 41 preferably includes a silicon oxide film. The second insulating film 43 covers the first main surface 3 with the first insulating film 42 interposed therebetween in the active region 8 and the outer peripheral region 9. Specifically, the second insulating film 43 selectively covers the active surface 10, the outer surface 11, and the first to fourth connecting surfaces 12A to 12D with the first insulating film 42 interposed

In the active region 8, the second insulating film 43 covers the plurality of trench structures 20 (the embedded electrodes 23) and the plurality of gate structures 37 (the gate electrodes 39). In the outer peripheral region 9, the second insulating film 43 covers the well region 35 and the plurality of field regions 36 with the first insulating film 42 interposed therebetween. In this embodiment, the second insulating film 43 is continuous to the first to fourth side surfaces 5A to 5D. As a matter of course, the second insulating film 43 may instead be formed at intervals inward from the peripheral edges of the outer surface 11 and, together with the first insulating film 42, expose peripheral edge portions of the first main surface 3.

The SiC semiconductor device 1 includes a plurality of contact openings 44 that are formed in the interlayer insulating film 41. The plurality of contact openings 44 include the plurality of contact openings 44 (not shown) that expose the plurality of gate structures 37 (the gate electrodes 39) and the plurality of contact openings 44 that expose the plurality of trench structures 20 (the embedded electrodes 23) and the plurality of source regions 33.

The plurality of contact openings 44 for the trench structures 20 are formed in regions between the plurality of gate structures 37 that are mutually adjacent and expose the plurality of trench structures 20, the plurality of source regions 33, and the plurality of contact regions 34. Specifically, the plurality of contact openings 44 are arrayed at intervals in the second array direction Da2 such as to be positioned in the regions between the plurality of gate structures 37 and are each formed in a band shape extending in the second extension direction De2.

The plurality of contact openings 44 thereby expose the plurality of trench structures 20 (the embedded electrodes 23), the plurality of source regions 33, and the plurality of contact regions 34 along the second extension direction De2. In this embodiment, the plurality of contact openings 44 also expose portions of the plurality of intermediate regions 32 that are exposed from the first main surface 3.

The SiC semiconductor device 1 includes a side wall structure 45 that is arranged inside the interlayer insulating film 41 such as to cover at least one of the first to fourth connecting surfaces 12A to 12D. The side wall structure 45 is arranged on the first insulating film 42 and is covered by the second insulating film 43. The side wall structure 45 moderates a level difference formed between the active surface 10 and the outer surface 11.

The side wall structure 45 is formed in a band shape extending along at least one of the first to fourth connecting surfaces 12A to 12D. In this embodiment, the side wall structure 45 is formed in an annular shape (specifically, a quadrangle annular shape) extending along the first to fourth connecting surfaces 12A to 12D such as to surround the active surface 10 in plan view.

The side wall structure 45 may have a portion extending in a film shape along the outer surface 11 and a portion extending in a film shape along the first to fourth connecting surfaces 12A to 12D. In this embodiment, the side wall structure 45 is formed at an interval to the active surface 10 side from the innermost field region 36 and faces the well region 35 with the first insulating film 42 interposed therebetween in the horizontal directions and the lamination direction. The side wall structure 45 may face the body region 30 with the first insulating film 42 interposed therebetween.

With reference to FIG. 1, the SiC semiconductor device 1 includes a gate pad 50 that is arranged on the interlayer insulating film 41. The gate pad 50 is an electrode to which the gate potential is applied from the exterior. The gate pad 50 may be referred to as a “gate pad electrode,” a “first pad electrode,” etc. The gate pad 50 may have a laminated structure that includes a Ti-based metal film and an Al-based metal film that are laminated in that order from the interlayer insulating film 41 side.

In this embodiment, the gate pad 50 is arranged on a portion of the interlayer insulating film 41 that covers the active region 8. Specifically, the gate pad 50 is arranged on the active surface 10 at intervals from the outer surface 11 in plan view. The gate pad 50 is arranged in a region adjacent to a central portion of one side (in this embodiment, the second connecting surface 12B side) of the active surface 10 in plan view.

As a matter of course, the gate pad 50 may be arranged in a region along any of central portions of the first to fourth connecting surfaces 12A to 12D. As a matter of course, the gate pad 50 may be arranged in an arbitrary corner portion of the active surface 10 in plan view. Also, the gate pad 50 may be arranged in a central portion of the active surface 10 in plan view. In this embodiment, the gate pad 50 is formed in a quadrangle shape in plan view.

The SiC semiconductor device 1 includes at least one (in this embodiment, a plurality) of a gate wiring 51 that is led out onto the interlayer insulating film 41 from the gate pad 50. The gate wirings 51 may be referred to as “wirings,” “wiring electrodes,” etc. In this embodiment, the plurality of gate wirings 51 are arranged on the active surface 10 at intervals from the outer surface 11 in plan view.

The plurality of gate wirings 51 may have a laminated structure that includes a Ti-based metal film and an Al-based metal film that are laminated in that order from the interlayer insulating film 41 side. In this embodiment, the plurality of gate wirings 51 include a first gate wiring 51A and a second gate wiring 51B.

The first gate wiring 51A is led out toward the first connecting surface 12A side from the gate pad 50 and extends in a line shape along the peripheral edge of the active surface 10 such as to intersect (specifically, be orthogonal to) portions (specifically, one end portions) of the plurality of gate structures 37. The first gate wiring 51A penetrates through the interlayer insulating film 41 via the plurality of contact openings 44 and is electrically connected to the one end portions of the plurality of gate structures 37 (the gate electrodes 39).

The second gate wiring 51B is led out toward the third connecting surface 12C side from the gate pad 50 and extends in a line shape along the peripheral edge of the active surface 10 such as to intersect (specifically, be orthogonal to) portions (specifically, other end portions) of the plurality of gate structures 37. The second gate wiring 51B penetrates through the interlayer insulating film 41 via the plurality of contact openings 44 and is electrically connected to the other end portions of the plurality of gate structures 37 (the gate electrodes 39).

The SiC semiconductor device 1 includes a source pad 52 that is arranged on the interlayer insulating film 41 at intervals from the gate pad 50 and the gate wirings 51. The source pad 52 is an electrode to which a source potential is applied from the exterior. The source pad 52 may be referred to as a “source pad electrode,” a “second pad electrode,” etc. The source pad 52 may have a laminated structure that includes a Ti-based metal film and an Al-based metal film that are laminated in that order from the interlayer insulating film 41 side.

In this embodiment, the source pad 52 is arranged on the active surface 10 at intervals from the outer surface 11 in plan view. In this embodiment, the source pad 52 is formed in a polygonal shape having a recess portion that is recessed along the gate pad 50 in plan view. As a matter of course, the source pad 52 may instead be formed in a quadrangle shape in plan view.

The source pad 52 faces the plurality of gate structures 37 with the interlayer insulating film 41 interposed therebetween and is electrically insulated from the plurality of gate structures 37. The source pad 52 penetrates through the interlayer insulating film 41 via the plurality of contact openings 44 and is electrically connected to the plurality of trench structures 20, the plurality of body regions 30, the plurality of intermediate regions 32, the plurality of source regions 33, and the plurality of contact regions 34. That is, the source pad 52 is electrically connected to the plurality of column regions 24 via the body regions 30 and the plurality of intermediate regions 32.

The SiC semiconductor device 1 includes a drain pad 53 that covers the second main surface 4. The drain pad 53 is an electrode to which a drain potential is applied from the exterior. The drain pad 53 may be referred to as a “drain pad electrode,” a “third pad electrode,” etc. The drain pad 53 forms an ohmic contact with the base layer 6 exposed from the second main surface 4.

That is, the drain pad 53 is electrically connected to the plurality of drift regions 29 via the base layer 6. The drain pad 53 may cover an entirety of the second main surface 4 such as to be continuous to the peripheral edges (the first to fourth side surfaces 5A to 5D) of the chip 2. The drain pad 53 may instead cover the second main surface 4 at intervals inward from the peripheral edges of the chip 2 such as to expose peripheral edge portions of the chip 2.

A breakdown voltage applicable between the source pad 52 and the drain pad 53 (between the first main surface 3 and the second main surface 4) may be not less than 500 V and not more than 3000 V. The breakdown voltage may have a value falling within any one of ranges of not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

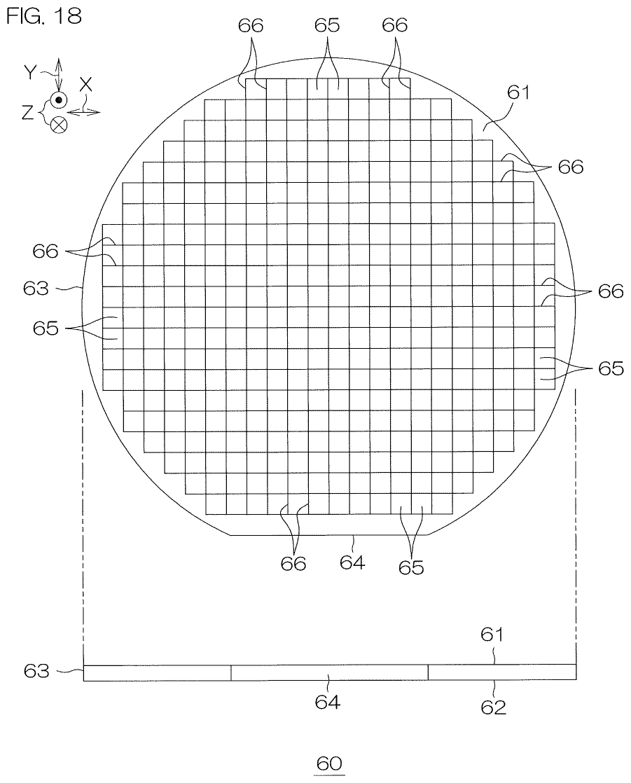

FIG. 18 is a schematic view showing a wafer 60 used in manufacture of the SiC semiconductor device 1. The wafer 60 is a base material of the base layer 6 and includes the SiC monocrystal. The wafer 60 is formed in a flat disc shape. As a matter of course, the wafer 60 may be formed in a flat rectangular parallelepiped shape instead. The wafer 60 has a first wafer main surface 61 at one side, a second wafer main surface 62, at another side, and a wafer side surface 63 that connects the first wafer main surface 61 and the second wafer main surface 62.

The first wafer main surface 61 corresponds to the upper end of the base layer 6 and the second wafer main surface 62 corresponds to a lower end of the base layer 6. The first wafer main surface 61 and the second wafer main surface 62 are formed by c-planes of the SiC monocrystal. The first wafer main surface 61 is formed by a silicon plane of the SiC monocrystal and the second wafer main surface 62 is formed by a carbon plane of the SiC monocrystal. The wafer 60 (the first wafer main surface 61 and the second wafer main surface 62) have the off direction Do and the off angle θo described above.

The wafer 60 has, on the wafer side surface 63, a mark 64 that indicates a crystal orientation of the SiC monocrystal. The mark 64 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer main surface 61 in plan view.

The mark 64 may include either or both of a first orientation flat that extends in the m-axis direction and a second orientation flat that extends in the a-axis direction. The mark 64 may include either or both of an orientation notch that is recessed in the m-axis direction and an orientation notch flat that is recessed in the a-axis direction. In FIG. 18, the orientation flat that extends in the m-axis direction (the first direction X) in plan view is shown.

For example, a plurality of device regions 65 and a plurality of intended cutting lines 66 are set by alignment marks, etc., in the wafer 60. Each device region 65 is a region corresponding to the SiC semiconductor device 1. The plurality of device regions 65 are each set in a quadrangle shape in plan view.

In this embodiment, the plurality of device regions 65 are set in a matrix along the first direction X and the second direction Y. The plurality of device regions 65 are each set at intervals inward from a peripheral edge of the first wafer main surface 61 in plan view. The plurality of intended cutting lines 66 are set in a lattice extending along the first direction X and the second direction Y such as to demarcate the plurality of device regions 65.

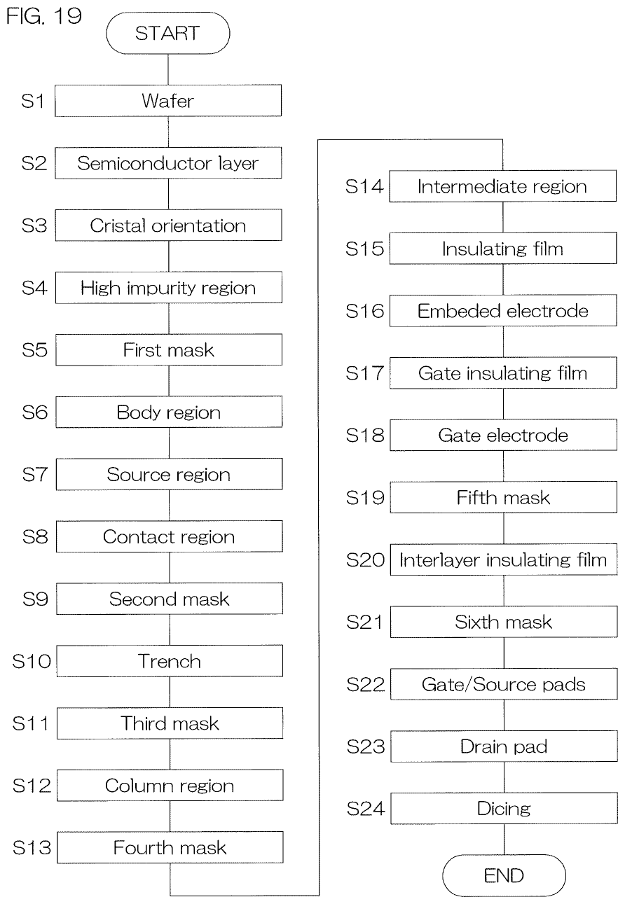

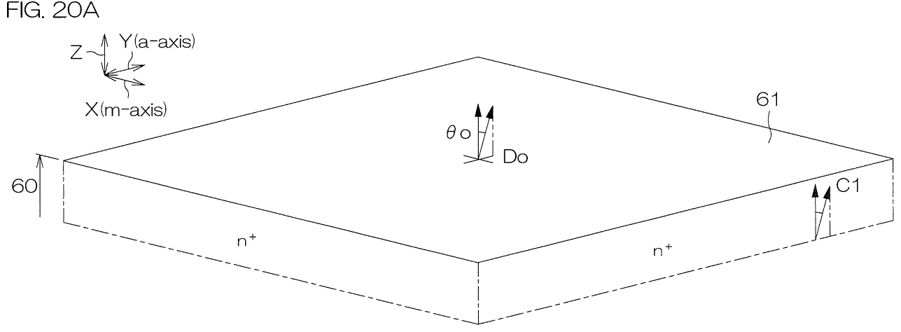

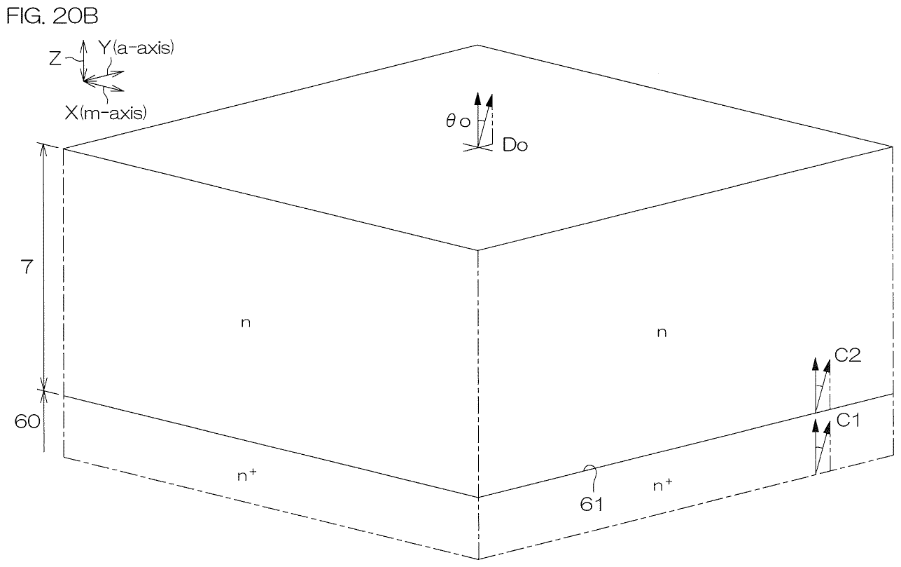

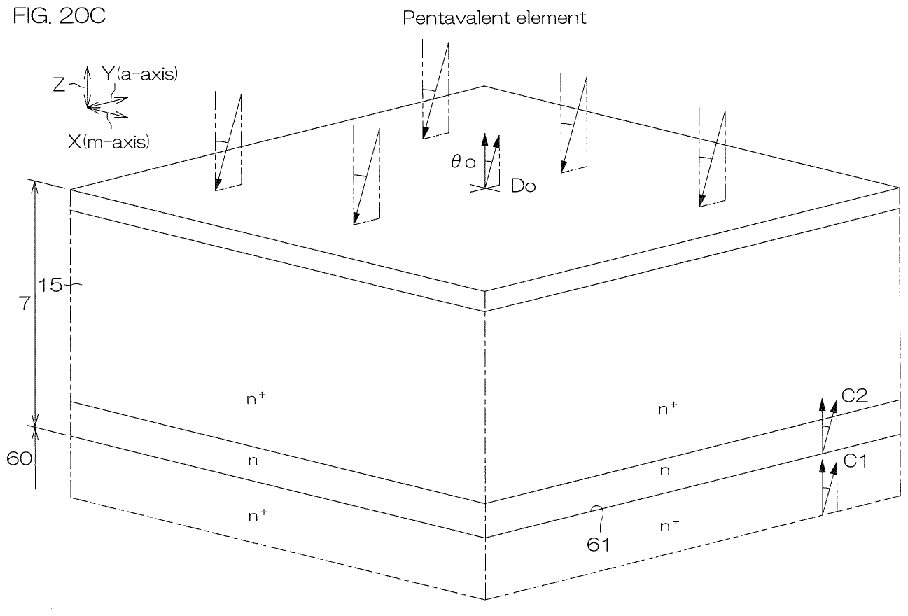

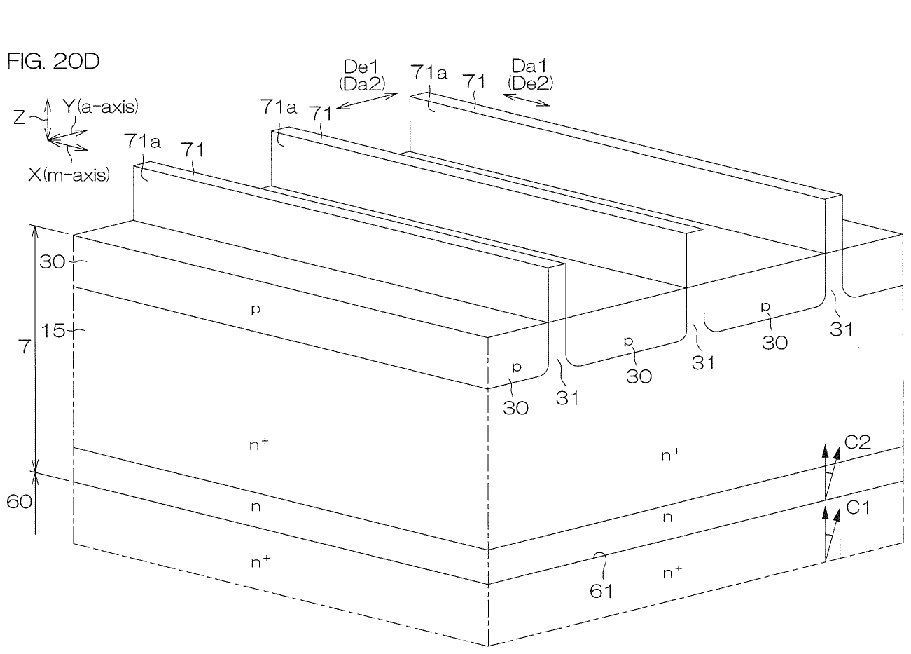

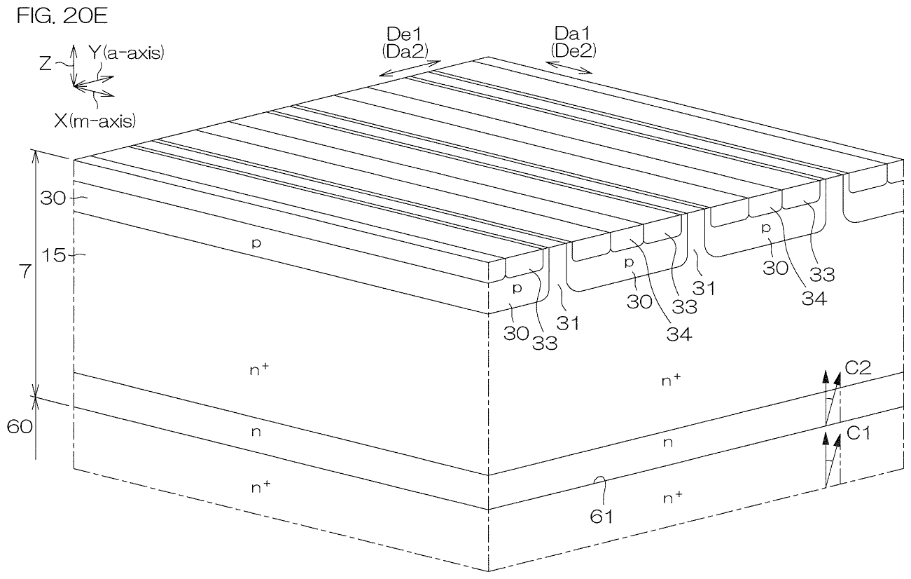

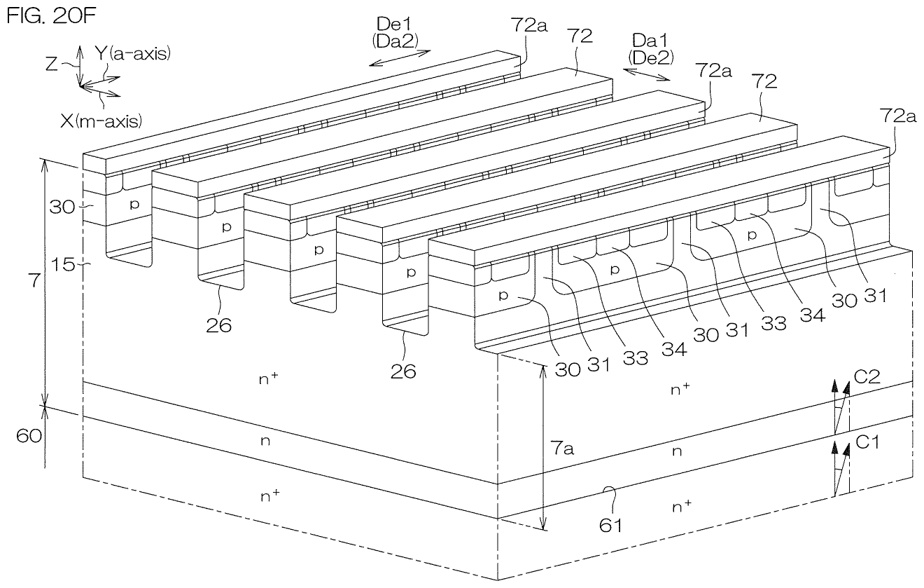

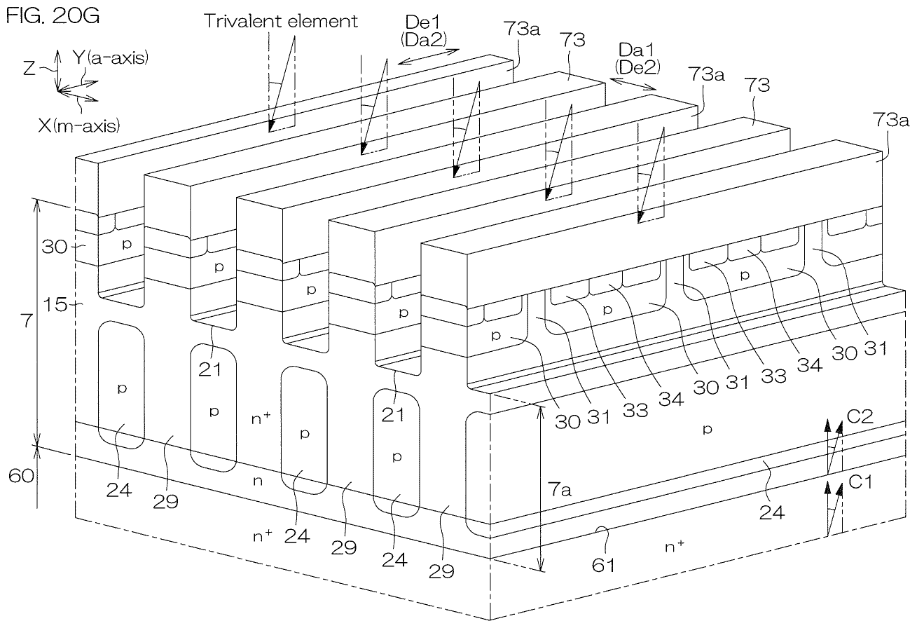

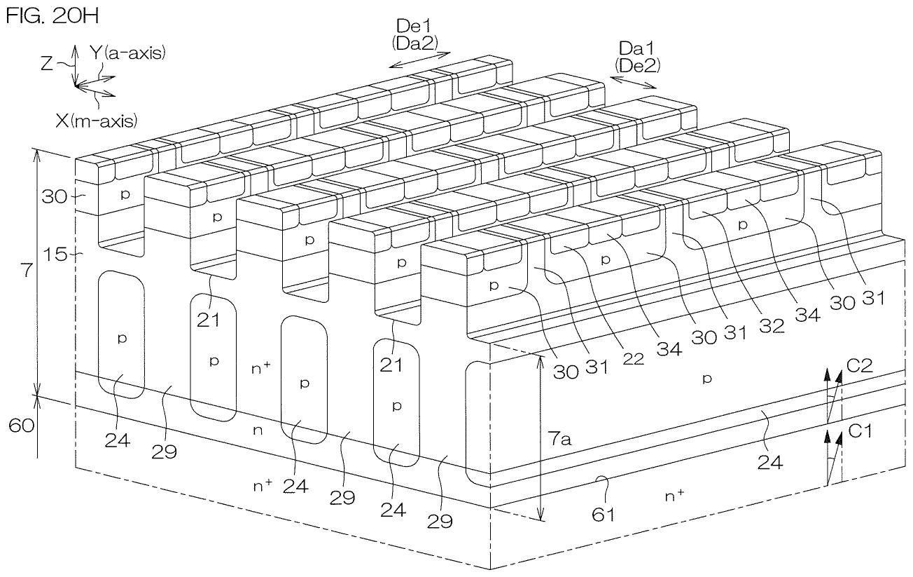

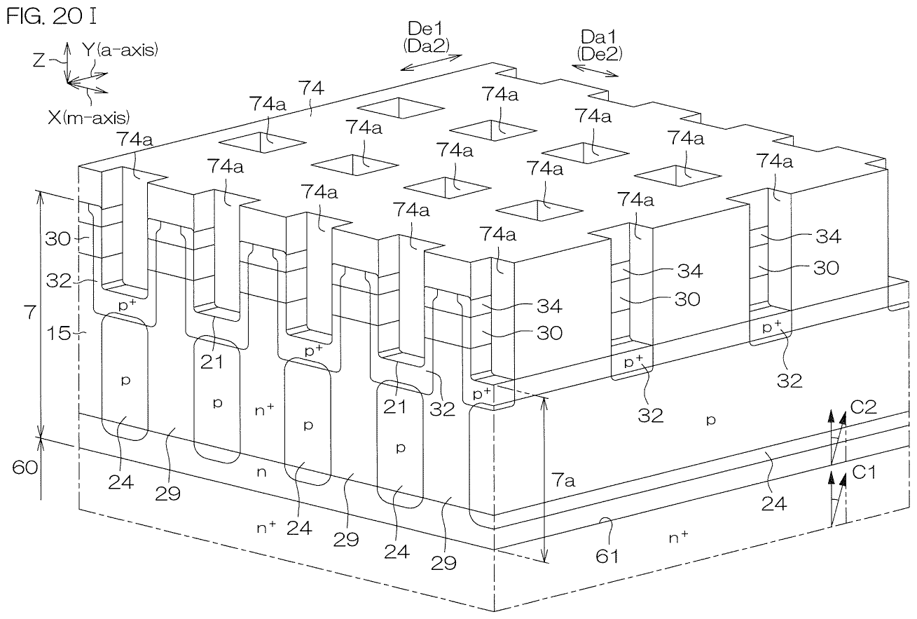

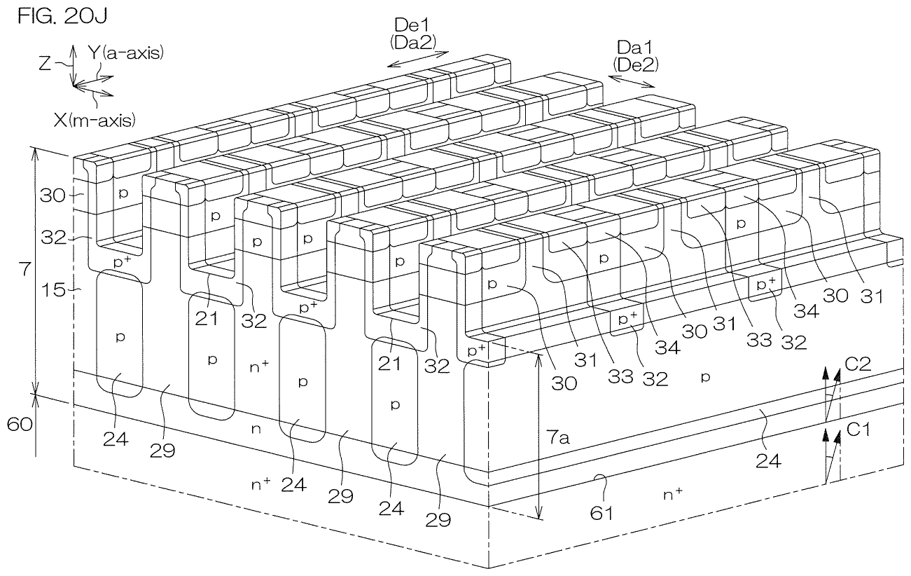

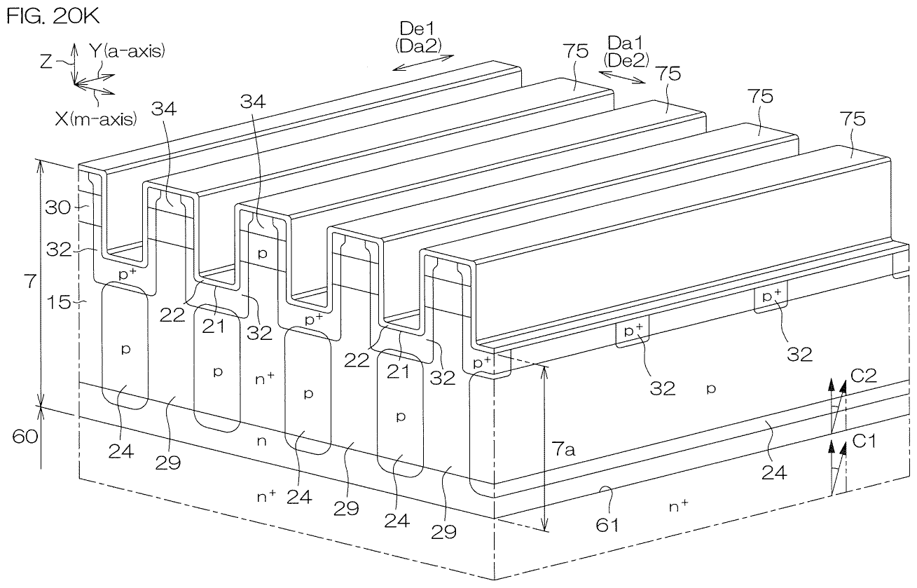

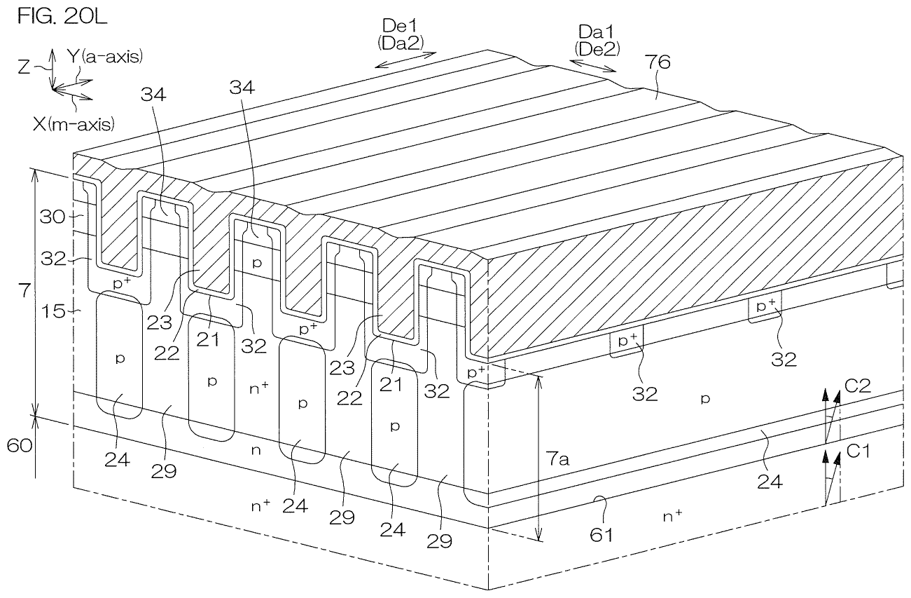

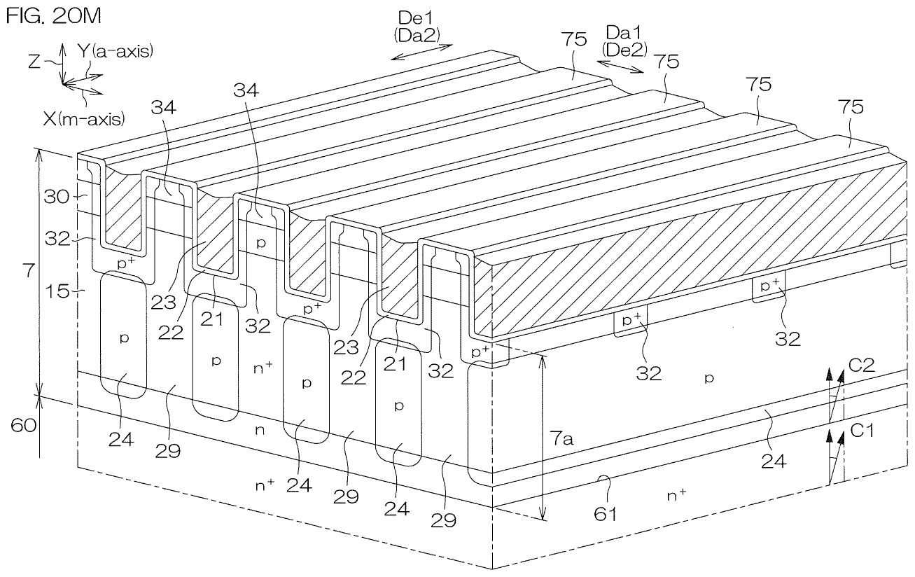

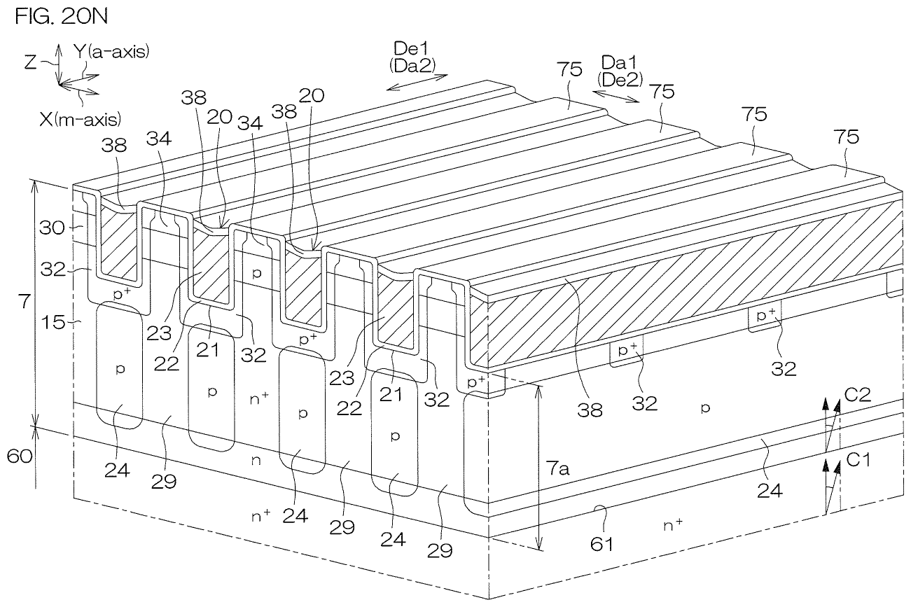

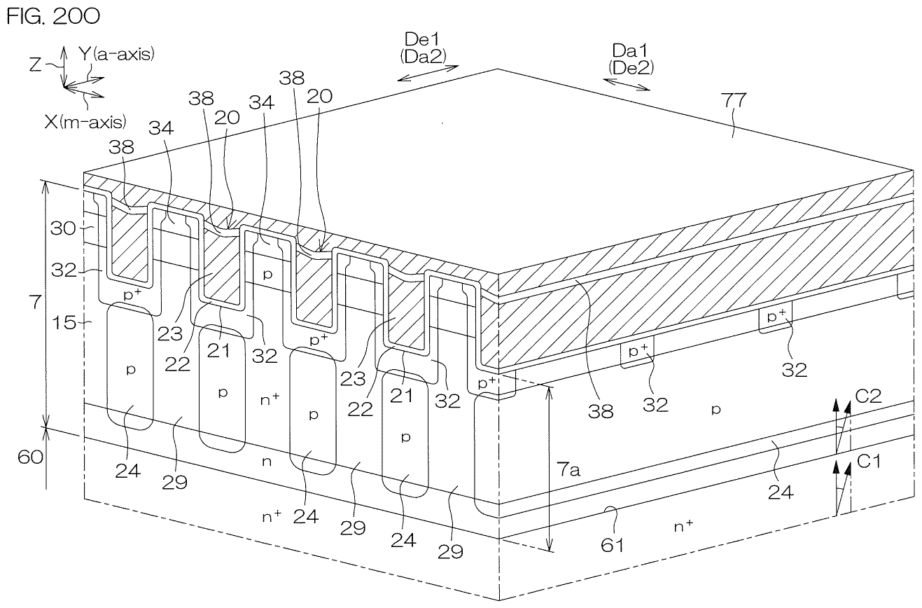

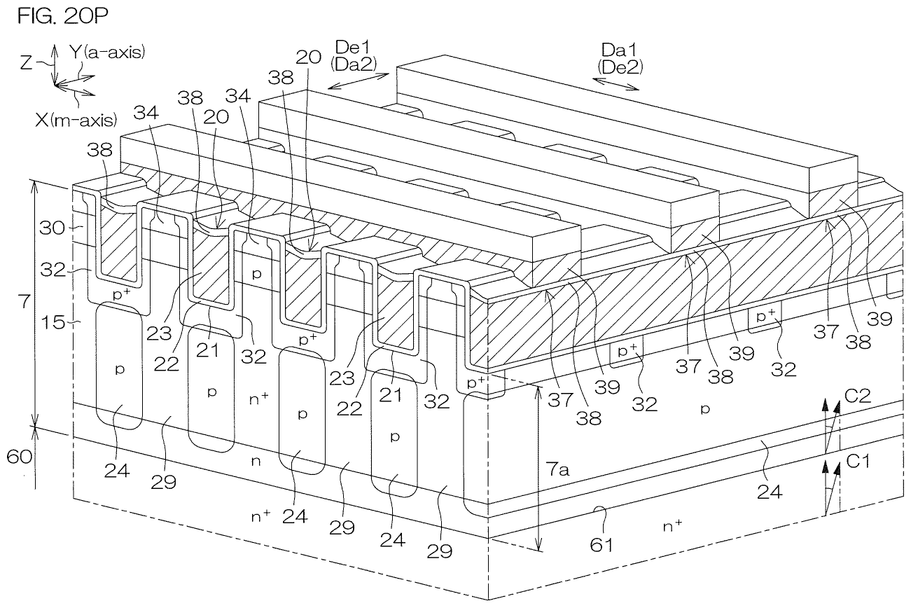

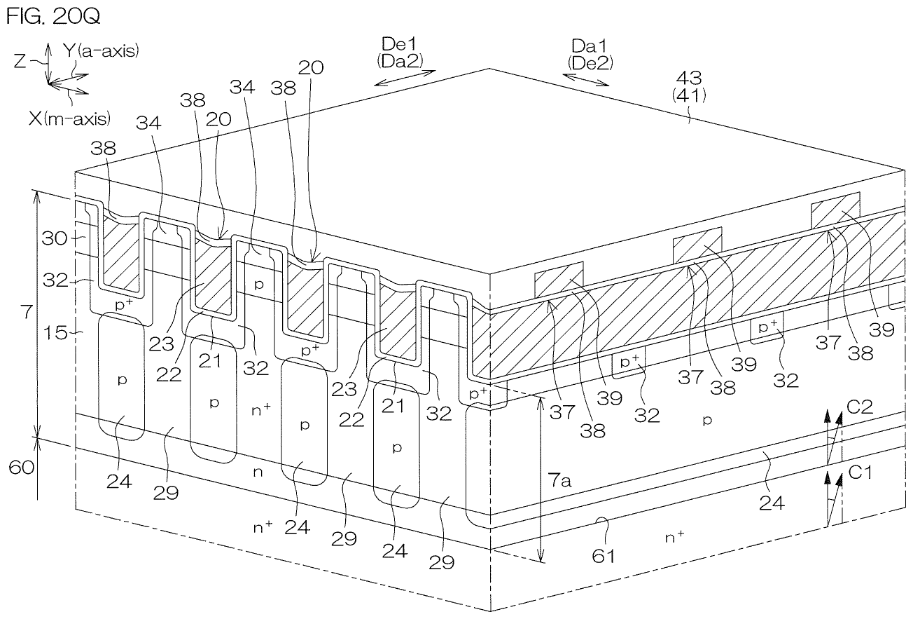

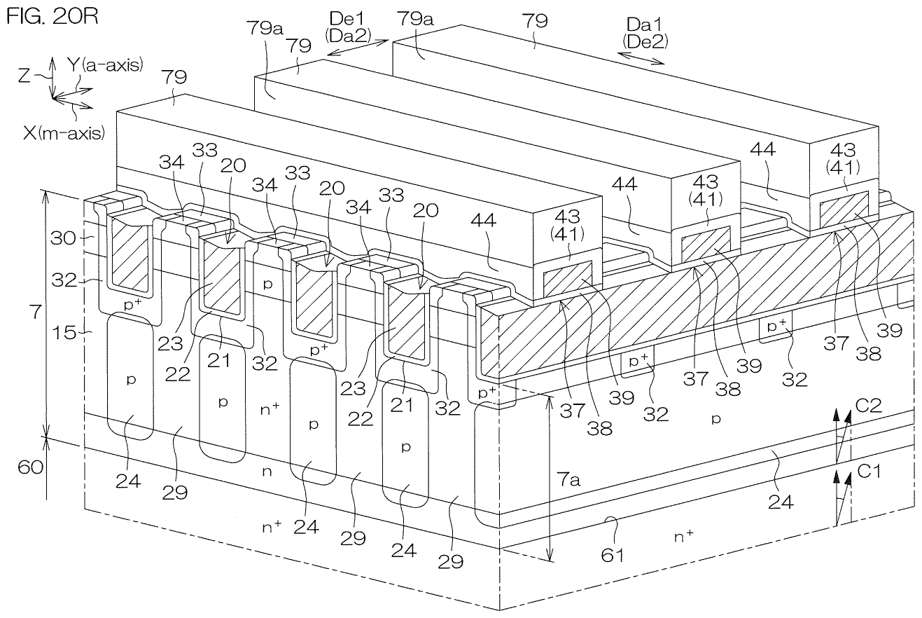

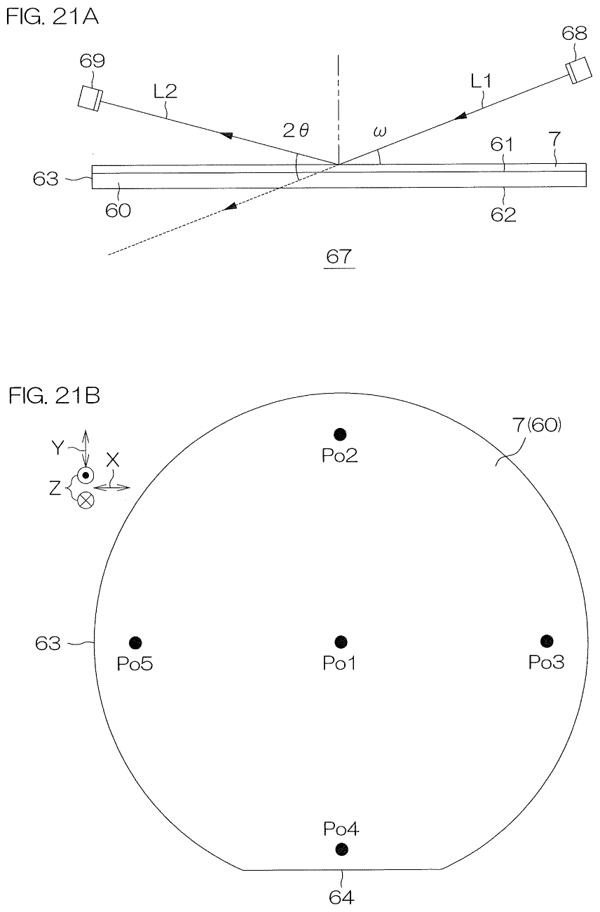

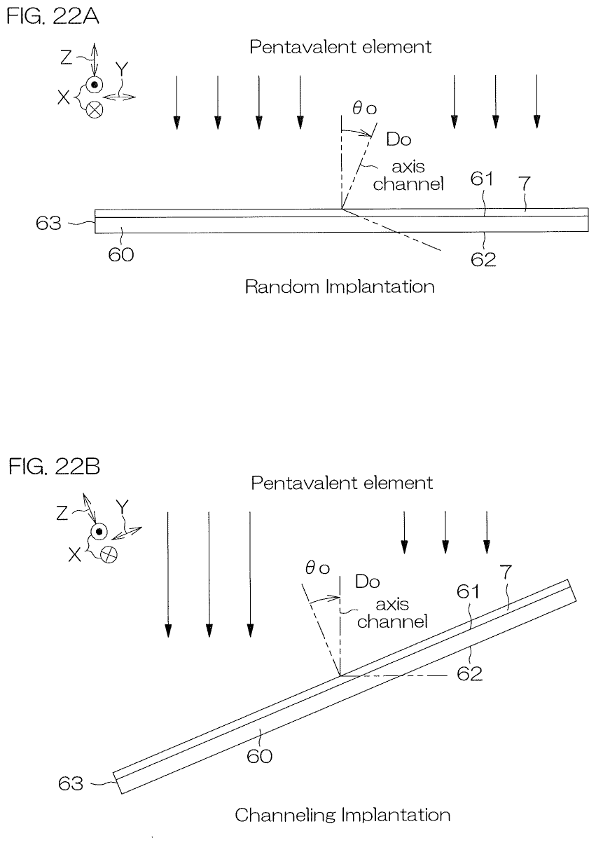

FIG. 19 is a flowchart showing a manufacturing method example of the SiC semiconductor device 1. FIG. 20A to FIG. 20R are cross-sectional perspective views showing the manufacturing method example of the SiC semiconductor device 1. FIG. 21A and FIG. 21B are schematic views for describing a measurement step of the crystal orientation. FIG. 22A and FIG. 22B are schematic views for describing an ion implantation step. FIG. 20A to FIG. 20R show cross-sectional perspective views of a portion of the active region 8 of the single device region 65.

First, with reference to FIG. 20A, a preparation step of the wafer 60 described above is performed (step S1 of FIG. 19). Next, with reference to FIG. 20B, a forming step of the semiconductor layer 7 is performed (step S2 of FIG. 19). The semiconductor layer 7 is formed by an epitaxial growth method with the first wafer main surface 61 (the wafer 60) as a starting point.

Next, the measurement step of the crystal orientation of the semiconductor layer 7 is performed (step S3 of FIG. 19). The measurement step of the crystal orientation of the semiconductor layer 7 includes a step of measuring the off angle θo of the semiconductor layer 7. That is, this step includes a step of measuring a crystal orientation of the second axis channel C2 of the semiconductor layer 7.

Although the wafer 60 is cut out from an ingot (an SiC ingot) that is a crystalline mass, there is a risk of an error occurring in the off angle θo due to a process error. When an error occurs in the off angle θo of the wafer 60, a process error also occurs in the off angle θo of the semiconductor layer 7 and this becomes a blocking object during a channeling implantation step. It is therefore preferable to acquire data (information) on the off angle θo before the channeling implantation step and to perform the channeling implantation step based on the data (information) on this off angle θo.

With reference to FIG. 21A, in this step, the crystal orientation of the semiconductor layer 7 is measured by an X-ray diffraction method (a so-called ω-2θ measurement method) using an X-ray diffractometer 67. The X-ray diffractometer 67 may also be referred to as an “XRD (X-ray diffraction) device.”

The X-ray diffractometer 67 includes an irradiation portion 68 and a detection portion 69 and executes a rocking curve measurement method. The irradiation portion 68 irradiates an incident X-ray L1 having a predetermined incident angle ω onto the upper end of the semiconductor layer 7 (the first wafer main surface 61 of the wafer 60). The incident angle ω is defined as an angle between the incident X-ray L1 and the upper end of the semiconductor layer 7 (the first wafer main surface 61 of the wafer 60).

The detection portion 69 is arranged at an angle position of a diffraction angle 2θ (where θ is a Bragg angle) with respect to an irradiation position of the incident X-ray L1 with respect to the wafer 60 and detects a diffracted X-ray L2. The diffraction angle 2θ is an angle between an incident direction of the incident X-ray L1 and a diffraction direction of the diffracted X-ray L2.

With the rocking curve measurement method, the incident angle ω is changed over a minute angle range in a state where the diffraction angle 2θ is fixed and a rocking curve that expresses an intensity of the diffracted X-ray L2 (an intensity profile of the diffracted X-ray L2) is measured. The rocking curve has the intensity of the diffracted X-ray L2 as the ordinate and has the incident angle ω as the abscissa. The incident angle ω is determined by an angle position at which the intensity of the diffracted X-ray L2 takes a peak value.

In this step, the rocking curve measurement method is performed on just one location (for example, a central portion) of the upper end of the semiconductor layer 7 (the first wafer main surface 61 of the wafer 60). When in-plane variation of the off angle θo is presumed, the rocking curve measurement method may be performed on a plurality of locations (for example, the central portion and peripheral edge portions) of the upper end of the semiconductor layer 7 (the first wafer main surface 61 of the wafer 60).

Measuring locations when the rocking curve measurement method is performed on a plurality of locations (here, five locations) of the upper end of the semiconductor layer 7 are shown in FIG. 21B. Here, the off angle θo of the semiconductor layer 7 is set to approximately 4°. In FIG. 21B, first to fifth measuring points Po1 to Po5 are shown.

The first measuring point Po1 is set at a central portion of the semiconductor layer 7. The second measuring point Po2 is set at a peripheral edge portion of the semiconductor layer 7 at an interval to one side in the second direction Y (an opposite side to the mark 64) from the first measuring point Po1. The third measuring point Po3 is set at a peripheral edge portion of the semiconductor layer 7 at an interval to one side in the first direction X (the right side with respect to the mark 64) from the first measuring point Po1.

The fourth measuring point Po4 is set at a peripheral edge portion of the semiconductor layer 7 at an interval to the other side in the second direction Y (the mark 64 side) from the first measuring point Po1. The fifth measuring point Po5 is set at a peripheral edge portion of the semiconductor layer 7 at an interval to the other side in the first direction X (the left side with respect to the mark 64) from the first measuring point Po1.

Measurement results of the incident angle ω, the diffraction angle 2θ, and the off angle θo at the first to fifth measuring points Po1 to Po5 are as shown in Table 1 below. The off angle θo is determined by a calculation formula “ω−(2θ×½)” using the incident angle @ and the diffraction angle 2θ.

TABLE 1

| Measuring point | ω (°) | 2θ (°) | θoff (°) |
|---|---|---|---|
| Po1 | 21.836 | 35.606 | 4.033 |
| Po2 | 21.830 | 35.609 | 4.025 |
| Po3 | 21.841 | 35.611 | 4.035 |
| Po4 | 21.837 | 35.609 | 4.033 |
| Po5 | 21.856 | 35.606 | 4.053 |
| Average | | | 4.036 |
| Standard deviation | | | 0.009 |

As shown in Table 1, an average value of the off angles θo of the first to fifth measuring points Po1 to Po5 was 4.036° and a standard deviation of these off angles θo was 0.009° (±0.01°). From this, it can be understood that the in-plane variation of the off angle θo occurring at the upper end of the semiconductor layer 7 (the first wafer main surface 61 of the wafer 60) is extremely small and is of a level that would not obstruct the channeling implantation step.

It can therefore be understood that there is no problem with there being at least one location as the measuring locations for the upper end of the semiconductor layer 7 (the first wafer main surface 61). For example, the measuring location or locations may be any one or plurality (or all) of the first to fifth measuring points Po1 to Po5. For example, the measuring location may be just the first measuring point Po1. By decreasing the measuring locations (measurement times), manufacturing man-hours (manufacturing cost) can be reduced.

As a matter of course, the off angle θo may be measured for a plurality of locations of the upper end of the semiconductor layer 7 (the first wafer main surface 61) and an implantation angle that is in accordance with the in-plane variation of the off angle θo may be set in the channeling implantation step. In this case, although the manufacturing man-hours (the manufacturing cost) increases, in-plane error of the column regions 24 formed in the semiconductor layer 7 is suppressed appropriately.

The off angle θo of the semiconductor layer 7 is substantially matched with the off angle θo of the wafer 60. Therefore, the measurement step of the crystal orientation may be performed on the wafer 60 prior to the forming step of the semiconductor layer 7. However, from a standpoint of ensuring accuracy, the measurement step of the crystal orientation is preferably performed on the semiconductor layer 7.

Next, with reference to FIG. 20C, a forming step of the high concentration region 15 is performed (step S4 of FIG. 19). The forming step of the high concentration region 15 includes a channeling implantation step of the pentavalent element (the n-type impurity) with respect to the semiconductor layer 7. In this step, the pentavalent element is introduced into an entirety of the semiconductor layer 7. The semiconductor layer 7 (the wafer 60) has the off angle θo inclined at the predetermined angle in the predetermined off direction Do with respect to the first wafer main surface 61. The channeling implantation step is performed based on the data (the information) on the off angle θo.

With reference to FIG. 22A, with a random implantation method, the pentavalent element is introduced into the semiconductor layer 7 at a predetermined implantation energy in a direction that intersects the second axis channel C2 (the off angle 00) (see also FIG. 13). For example, with the random implantation method, the pentavalent element is implanted along the vertical direction Z perpendicular to the upper end of the semiconductor layer 7 (the first wafer main surface 61).

In the case of the random implantation method, the pentavalent element is introduced along a direction in which the atomic rows are comparatively dense in plan view and therefore, the pentavalent element collides with the atomic rows at a comparatively shallow depth position. Introduction of the pentavalent element with respect to a comparatively deep depth position of the semiconductor layer 7 is thus obstructed by the atomic rows. Consequently, the high concentration region 15 not having the first gentle gradient portion 18 is formed.

On the other hand, with reference to FIG. 22B, with the channeling implantation method, an implantation angle of the pentavalent element with respect to the semiconductor layer 7 is controlled and the pentavalent element is introduced into the semiconductor layer 7 at a predetermined implantation energy along the second axis channel C2 (in this embodiment, the c-axis of the SiC monocrystal) (see also FIG. 12). In this case, either or both of the implantation angle of the pentavalent element with respect to the semiconductor layer 7 and an inclination angle of the semiconductor layer 7 with respect to the implantation angle of the pentavalent element is or are controlled.

For example, the wafer 60 may be supported horizontally and the pentavalent element may be introduced into the semiconductor layer 7 along the second axis channel C2. As a matter of course, the wafer 60 may instead be supported in a state of being inclined by just the off angle θo with respect to the horizontal and the pentavalent element may be introduced into the semiconductor layer 7 along the second axis channel C2. The high concentration region 15 having a predetermined thickness is formed at a predetermined depth position by an arbitrary combination of the implantation energy of the pentavalent element and an implantation temperature of the pentavalent element.

The implantation energy of the pentavalent element may be not less than 100 KeV and not more than 2000 KeV. The implantation energy may have a value falling within any one of ranges of not less than 100 KeV and not more than 250 KeV, not less than 250 KeV and not more than 500 KeV, not less than 500 KeV and not more than 750 KeV, not less than 750 KeV and not more than 1000 KeV, not less than 1000 KeV and not more than 1250 KeV, not less than 1250 KeV and not more than 1500 KeV, not less than 1500 KeV and not more than 1750 KeV, and not less than 1750 KeV and not more than 2000 KeV.

The implantation temperature of the pentavalent element may be adjusted within a range of not less than 0° C. and not more than 1500° C. The implantation temperature may have a value falling within any one of ranges of not less than 0° C. and not more than 25° C., not less than 25° C. and not more than 50° C., not less than 50° C. and not more than 100° C., not less than 100° C. and not more than 250° C., not less than 250° C. and not more than 500° C., not less than 500° C. and not more than 750° C., not less than 750° C. and not more than 1000° C., not less than 1000° C. and not more than 1250° C., and not less than 1250° C. and not more than 1500° C.

The implantation angle of the pentavalent element is preferably set within a range of ±2° with respect to an axis (in this embodiment, the c-axis of the SiC monocrystal) along the second axis channel C2 as a basis) (0°). The implantation angle of the pentavalent element is particularly preferably set within a range of ±1° with respect to the axis (in this embodiment, the c-axis of the SiC monocrystal) along the second axis channel C2 as a basis (0°).

In the case of the channeling implantation method, the pentavalent element is introduced along the second axis channel C2 where the atomic rows are comparatively sparse in plan view. The pentavalent element proceeds inside the second axis channel C2 while repeating small-angle scattering due to a channeling effect and reaches a comparatively deep depth position of the semiconductor layer 7. That is, in the case of the channeling implantation method, a collision probability of the pentavalent element with respect to the atomic rows of the SiC monocrystal is reduced. The pentavalent element is preferably arsenic or antimony.

After the implantation step of the pentavalent element, the pentavalent element may be electrically activated and lattice defects, etc., that formed in the semiconductor layer 7 may be repaired at the same time by an annealing method. An annealing temperature with respect to the semiconductor layer 7 may be not less than 500° C. and not more than 2000° C.

Next, with reference to FIG. 20D, a forming step of a first mask 71 having a predetermined pattern is performed (step S5 of FIG. 19). The first mask 71 is preferably an organic mask (a resist mask). The first mask 71 is arranged on the upper end of the semiconductor layer 7 and has a plurality of first openings 71a that expose regions in which the plurality of body regions 30 are to be formed.

The plurality of first openings 71a are each formed in a band shape extending in the second extension direction De2 (the first direction X) and are demarcated at intervals in the second array direction Da2 (the second direction Y). That is, the plurality of first openings 71a have an extension direction extending along a direction orthogonal to the off direction Do in plan view.

Next, a forming step of the plurality of body regions 30 is performed (step S6 of FIG. 19). The forming step of the plurality of body regions 30 includes a random implantation step of the trivalent element (the p-type impurity) with respect to the semiconductor layer 7. For example, with the random implantation method, the trivalent element is implanted along the vertical direction Z, which is perpendicular to the upper end of the semiconductor layer 7 (the first wafer main surface 61), via the plurality of first openings 71a of the first mask 71. The plurality body regions 30 are thereby formed in the surface layer portion of the semiconductor layer 7.

The plurality of body regions 30 are each formed in a band shape extending in the second extension direction De2 (the first direction X). As a matter of course, the plurality of body regions 30 may instead be formed in a matrix at intervals in the first direction X and the second direction Y in consideration of the layout of the plurality of trench structures 20 (the trenches 21). After the forming step of the plurality of body regions 30, the first mask 71 is removed.

Next, with reference to FIG. 20E, a forming step of the plurality of source regions 33 is performed (step S7 of FIG. 19). The plurality of source regions 33 are formed by introducing the pentavalent element into surface layer portions of the semiconductor layer 7 (the plurality of body regions 30) by a random implantation method performed via a mask (not shown) having predetermined layout.

Also, a forming step of the plurality of contact regions 34 is performed (step S8 of FIG. 19). The plurality of contact regions 34 are formed by introducing the trivalent element into surface layer portions of the semiconductor layer 7 (the plurality of body regions 30) by a random implantation method performed via a mask (not shown) having predetermined layout. The forming step of the contact regions 34 may be performed prior to the forming step of the source regions 33.

Next, with reference to FIG. 20F, a forming step of a second mask 72 having a predetermined pattern is performed (step S9 of FIG. 19). The second mask 72 is preferably an inorganic mask (a hard mask). The second mask 72 is arranged on the upper end of the semiconductor layer 7 and has a plurality of second openings 72a that expose regions in which the plurality of trenches 21 are to be formed.

The plurality of second openings 72a are formed at intervals in the first array direction Da1 (the first direction X) and are each demarcated in a band shape extending in the first extension direction De1 (the second direction Y). That is, the plurality of second openings 72a have the extension direction extending along the off direction Do in plan view. Also, the second mask 72 has a second opening 72a (not shown) that exposes a region in which the outer surface 11 is to be formed. The second opening 72a for the outer surface 11 is formed in a lattice along the plurality of intended cutting lines 66.

Next, a forming step of the plurality of trenches 21 is performed (step S10 of FIG. 19). In the forming step of the trenches 21, unnecessary portions of the semiconductor layer 7 are removed by an etching method performed via the second mask 72. The etching method may be either or both of a wet etching method and a dry etching method.

The etching method is preferably an RIE (reactive ion etching) method. The plurality of trenches 21 are thereby formed in the upper end of the semiconductor layer 7. Also, the active surface 10, the outer surface 11, and the first to fourth connecting surfaces 12A to 12D are formed in the upper end of the semiconductor layer 7. After the forming step of the plurality of trenches 21, the second mask 72 is removed.

Next, with reference to FIG. 20G, a forming step of a third mask 73 having a predetermined pattern is performed (step S11 of FIG. 19). The third mask 73 is preferably an organic mask (a resist mask). The third mask 73 is arranged on the upper end of the semiconductor layer 7 and has a plurality of third openings 73a that expose the plurality of trenches 21 in one-to-one correspondence.

The plurality of third openings 73a are formed at intervals in the first array direction Da1 (the first direction X) and are each demarcated in a band shape extending in the first extension direction De1 (the second direction Y). That is, the plurality of third openings 73a have an extension direction extending along the off direction Do in plan view.

Next, a forming step of the plurality of column regions 24 is performed (step S12 of FIG. 19). The forming step of the plurality of column regions 24 includes a channeling implantation step of the trivalent element (the p-type impurity) with respect to the semiconductor layer 7. The trivalent element is introduced inside the lower region 7a of the semiconductor layer 7 from the plurality of third openings 73a of the third mask 73 via the bottom walls of the plurality of trenches 21. The channeling implantation step is performed based on the data (the information) on the off angle θo.

With the channeling implantation method, an implantation angle of the trivalent element with respect to the semiconductor layer 7 is controlled and the trivalent element is introduced into the semiconductor layer 7 at a predetermined implantation energy along the second axis channel C2 (in this embodiment, the c-axis of the SiC monocrystal). In this case, either or both of the implantation angle of the trivalent element with respect to the semiconductor layer 7 and an inclination angle of the semiconductor layer 7 with respect to the implantation angle of the trivalent element is or are adjusted.

For example, the wafer 60 may be supported horizontally and the trivalent element may be introduced into the semiconductor layer 7 along the second axis channel C2. As a matter of course, the wafer 60 may instead be supported in a state of being inclined by just the off angle θo with respect to the horizontal and the trivalent element may be introduced into the semiconductor layer 7 along the second axis channel C2. The plurality of column regions 24 having a predetermined thickness is formed at a predetermined depth position by an arbitrary combination of the implantation energy of the trivalent element and an implantation temperature of the trivalent element (temperature of the wafer 60).

The implantation energy of the trivalent element may be not less than 100 KeV and not more than 2000 KeV. The implantation energy may have a value falling within any one of ranges of not less than 100 KeV and not more than 250 KeV, not less than 250 KeV and not more than 500 KeV, not less than 500 KeV and not more than 750 KeV, not less than 750 KeV and not more than 1000 KeV, not less than 1000 KeV and not more than 1250 KeV, not less than 1250 KeV and not more than 1500 KeV, not less than 1500 KeV and not more than 1750 KeV, and not less than 1750 KeV and not more than 2000 KeV.

The implantation energy for the column regions 24 may be substantially equal to the implantation energy for the high concentration region 15 or may differ from the implantation energy for the high concentration region 15. The implantation energy for the column regions 24 may be not less than the implantation energy for the high concentration region 15. The implantation energy for the column regions 24 may be less than the implantation energy for the high concentration region 15.

The implantation temperature of the trivalent element may be adjusted within a range of not less than 0° C. and not more than 1500° C. The implantation temperature may have a value falling within any one of ranges of not less than 0° C. and not more than 25° C., not less than 25° C. and not more than 50° C., not less than 50° C. and not more than 100° C., not less than 100° C. and not more than 250° C., not less than 250° C. and not more than 500° C., not less than 500° C. and not more than 750° C., not less than 750° C. and not more than 1000° C., not less than 1000° C. and not more than 1250° C., and not less than 1250° C. and not more than 1500° C.

The implantation temperature for the column regions 24 may be substantially equal to the implantation temperature for the high concentration region 15 or may differ from the implantation temperature for the high concentration region 15. The implantation temperature for the column regions 24 may be not less than the implantation temperature for the high concentration region 15. The implantation temperature for the column regions 24 may be less than the implantation temperature for the high concentration region 15.

The implantation angle of the trivalent element is preferably set within a range of ±2° with respect to an axis (in this embodiment, the c-axis of the SiC monocrystal) along the second axis channel C2 as a basis (0°). The implantation angle of the trivalent element is particularly preferably set within a range of ±1° with respect to the axis (in this embodiment, the c-axis of the SiC monocrystal) along the second axis channel C2 as a basis (0°).

In the case of the channeling implantation method, the trivalent element is introduced along the second axis channel C2 where the atomic rows are comparatively sparse in plan view. The trivalent element proceeds inside the second axis channel C2 while repeating small-angle scattering due to a channeling effect and reaches a comparatively deep depth position of the semiconductor layer 7. That is, in the case of the channeling implantation method, a collision probability of the trivalent element with respect to the atomic rows of the SiC monocrystal is reduced.

In this case, the trivalent element belonging to the heavy elements heavier than carbon is preferably introduced into the semiconductor layer 7. That is, the trivalent element is preferably a trivalent element other than boron (at least one type among aluminum, gallium, and indium). In this embodiment, the trivalent element is aluminum.

The plurality of third openings 73a have an extension direction (the first extension direction De1) of extending along the off direction Do and the implantation angle of the trivalent element is inclined in the off direction Do. Thus, in a cross-sectional view orthogonal to the extension direction, the trivalent element is introduced inside the semiconductor layer 7 substantially perpendicularly with respect to the bottom walls of the trenches 21 via the plurality of third openings 73a.

The forming of the plurality of column regions 24 in an inclined orientation inside the semiconductor layer 7 is thereby suppressed. Also, wall surfaces of the plurality of third openings 73a are suppressed from becoming blocking objects to an incidence path of the trivalent element. Process errors of the plurality of column regions 24 due to shadowing by the wall surfaces of the plurality of third openings 73a are thereby suppressed. Precision of the charge balance is thereby improved.

After the implantation step of the trivalent element, the trivalent element may be electrically activated and lattice defects, etc., that formed in the semiconductor layer 7 may be repaired at the same time by an annealing method. An annealing temperature with respect to the semiconductor layer 7 may be not less than 500° C. and not more than 2000° C. The plurality of column regions 24 and the plurality of drift regions 29 are thereby formed and, at the same time, the super junction structure is formed.

The annealing method for the column regions 24 may serve in common as the annealing method for the high concentration region 15. In this case, the annealing method for the high concentration region 15 before the forming step of the column regions 24 may be omitted. With reference to FIG. 20H, after the forming step of the plurality of column regions 24, the third mask 73 is removed.

Next, with reference to FIG. 20I, a forming step of a fourth mask 74 having a predetermined pattern, is performed (step S13 of FIG. 19). The fourth mask 74 is preferably an organic mask (a resist mask). The fourth mask 74 is arranged on the upper end of the semiconductor layer 7 and has a plurality of fourth openings 74a that selectively expose the plurality of trenches 21. The plurality of fourth openings 74a are demarcated in a matrix at intervals in the first direction X (the first array direction Da1) and the second direction Y (the first extension direction De1) and respectively expose portions of the plurality of trenches 21.

Next, a forming step of the plurality of intermediate regions 32 is performed (step S14 of FIG. 19). The forming step of the plurality of intermediate regions 32 includes a step of introducing the trivalent element into the semiconductor layer 7 at a predetermined implantation energy in a direction intersecting the second axis channel C2 (the off angle θo) by a random implantation method performed via the fourth mask 74. The trivalent element is introduced inside the semiconductor layer 7 (the high concentration region 15) from the plurality of fourth openings 74a via the wall surfaces (the side walls and the bottom walls) of the plurality of trenches 21. The trivalent element may be introduced inside the semiconductor layer 7 once or a plurality of times.

When the trivalent element is introduced a plurality of times, the trivalent element may be introduced in multiple steps to different depth positions of the semiconductor layer 7 by a plurality of implantation energies. The trivalent element may be introduced inside the semiconductor layer 7 (the high concentration region 15) via the wall surfaces (the side walls and the bottom walls) of the plurality of trenches 21 by an oblique ion implantation method. With reference to FIG. 20J, after the forming step of the plurality of intermediate regions 32, the fourth mask 74 is removed.

The forming step of the plurality of intermediate regions 32 may serve in common as a forming step of the well region 35. The well region 35 is formed by introducing the trivalent element inside the semiconductor layer 7 (the high concentration region 15) from the fourth openings 74a that expose the well region 35 and via the outer surface 11 and the first to fourth connecting surfaces 12A to 12D. As a matter of course, the well region 35 may instead be formed by introducing the trivalent element into the surface layer portion of the semiconductor layer 7 by a random implantation method performed via a mask different from the fourth mask 74.

Although specific illustration is omitted, a forming step of the plurality of field regions 36 is performed prior to the forming step of the well region 35 or after the forming step of the well region 35. The plurality of field regions 36 are formed by introducing the trivalent element into the surface layer portion of the semiconductor layer 7 by a random implantation method performed via a mask (not shown) having a predetermined layout.

Next, with reference to FIG. 20K, a forming step of a base insulating film 75 is performed (step S15 of FIG. 19). The base insulating film 75 serves as a base of the insulating films 22, the gate insulating films 38, and the first insulating film 42. The base insulating film 75 may be formed by either or both of a CVD (chemical vapor deposition) method and an oxidation treatment method.

The base insulating film 75 is typically formed by a thermal oxidation treatment method. Portions of the base insulating film 75 covering the wall surfaces of the plurality of trenches 21 are formed as the insulating films 22. Portions of the base insulating film 75 covering the upper end of the semiconductor layer 7 become the gate insulating films 38. A portion of the base insulating film 75 covering a region other than the insulating films 22 and the gate insulating films 38 becomes the first insulating film 42.

Next, with reference to FIG. 20L, a forming step of the embedded electrodes 23 is performed (step S16 of FIG. 19). This step includes a step of forming a first base electrode film 76 on the base insulating film 75. In this embodiment, the first base electrode film 76 contains a conductive polysilicon. The first base electrode film 76 backfills the plurality of trenches 21 and covers the upper end of the semiconductor layer 7. The first base electrode film 76 may be formed by a CVD method.

Next, with reference to FIG. 20M, unnecessary portions of the first base electrode film 76 are removed by an etching method. The unnecessary portions of the first base electrode film 76 are removed until the base insulating film 75 is exposed. The etching method may be either or both of a wet etching method and a dry etching method. Thereby, the plurality of embedded electrodes 23 are respectively embedded inside the plurality of trenches 21 and the plurality of trench structures 20 are formed.

Next, with reference to FIG. 20N, a forming step of the gate insulating films 38 is performed (step S17 of FIG. 19). The gate insulating films 38 may be formed by either or both of a CVD (chemical vapor deposition) method and an oxidation treatment method. The gate insulating films 38 are typically formed by a thermal oxidation treatment method. The gate insulating films 38 cover electrode surfaces of the embedded electrodes 23 in film shapes and is made integral to the base insulating film 75.

When a film thickness of the gate insulating films 38 is controlled precisely, portions of the above-described base insulating film 75 outside the trenches 21 (that is, the portions covering the upper end of the semiconductor layer 7, the portions covering the embedded electrodes 23, etc.) may be removed after the forming step of the embedded electrodes 23 and prior to the forming step of the gate insulating films 38. Thereafter, in the forming step of the gate insulating films 38, a gate insulating film 38 that integrally covers the upper end of the semiconductor layer 7 and the electrode surfaces of the embedded electrodes 23 may be formed.

Next, with reference to FIG. 20O, a forming step of the gate electrodes 39 is performed (step S18 of FIG. 19). This step includes a step of forming a second base electrode film 77 on the insulating films 22. In this embodiment, the second base electrode film 77 contains a conductive polysilicon. The second base electrode film 77 covers the upper end of the semiconductor layer 7 and the plurality of trench structures 20 (the embedded electrodes 23) with the gate insulating films 38 interposed therebetween. The second base electrode film 77 may be formed by a CVD method.

Next, with reference to FIG. 20P, a forming step of a fifth mask 78 having a predetermined pattern is performed (step S19 of FIG. 19). The fifth mask 78 is preferably an organic mask (a resist mask). The fifth mask 78 is arranged on the second base electrode film 77 such as to cover regions in which the plurality of gate electrodes 39 are to be formed and has a plurality of fifth openings 78a that expose other regions. The plurality of fifth openings 78a are arrayed at intervals in the second array direction Da2 (the second direction Y) and are each demarcated in a band shape extending in the second extension direction De2 (the first direction X).

Next, unnecessary portions of the second base electrode film 77 are removed by an etching method performed via the fifth mask 78. The unnecessary portions of the second base electrode film 77 are removed until the gate insulating films 38 are exposed. The etching method may be either or both of a wet etching method and a dry etching method. Thereby, the plurality of gate electrodes 39 are formed and, at the same time, the gate structures 37 of the planar electrode type are formed. After the forming step of the gate structures 37, the fifth mask 78 is removed.

Next, with reference to FIG. 20Q, a forming step of the second insulating film 43 is performed (step S20 of FIG. 19). The second insulating film 43 may be formed by a CVD method. The interlayer insulating film 41 that includes the first insulating film 42 and the second insulating film 43 is thereby formed.

Next, with reference to FIG. 20R, a forming step of a sixth mask 79 having a predetermined pattern is performed (step S21 of FIG. 19). The sixth mask 79 is preferably an organic mask (a resist mask). The sixth mask 79 is arranged on the interlayer insulating film 41 and has a plurality of sixth openings 79a that expose regions in which the plurality of contact openings 44 are to be formed. The plurality of sixth openings 79a are arrayed at intervals in the second array direction Da2 (the second direction Y) such as to be positioned in regions between the plurality of gate electrodes 39 and are each demarcated in a band shape extending in the second extension direction De2 (the first direction X).

Next, unnecessary portions of the interlayer insulating film 41 are removed by an etching method performed via the sixth mask 79. The unnecessary portions of the interlayer insulating film 41 are removed until the upper end of the semiconductor layer 7 is exposed. The etching method may be either or both of a wet etching method and a dry etching method. Thereby, the plurality of contact openings 44 are formed in the interlayer insulating film 41.

Next, a forming step of the gate pad 50, the gate wirings 51, and the source pad 52 is performed (step S22 of FIG. 19). The gate pad 50, the gate wirings 51, and the source pad 52 are formed by depositing a metal film on the interlayer insulating film 41 by a sputter method and thereafter forming to a predetermined layout by an etching method performed via a mask (not shown) having the predetermined layout.

Next, a forming step of the drain pad 53 is performed (step S23 of FIG. 19). The drain pad 53 is formed by depositing a metal film on the second wafer main surface 62 by a sputtering method. Thereafter, the wafer 60 is cut along the plurality of intended cutting lines 66 (step S24 of FIG. 19). Through steps including the above, a plurality of SiC semiconductor devices 1 are manufactured from the single wafer 60.

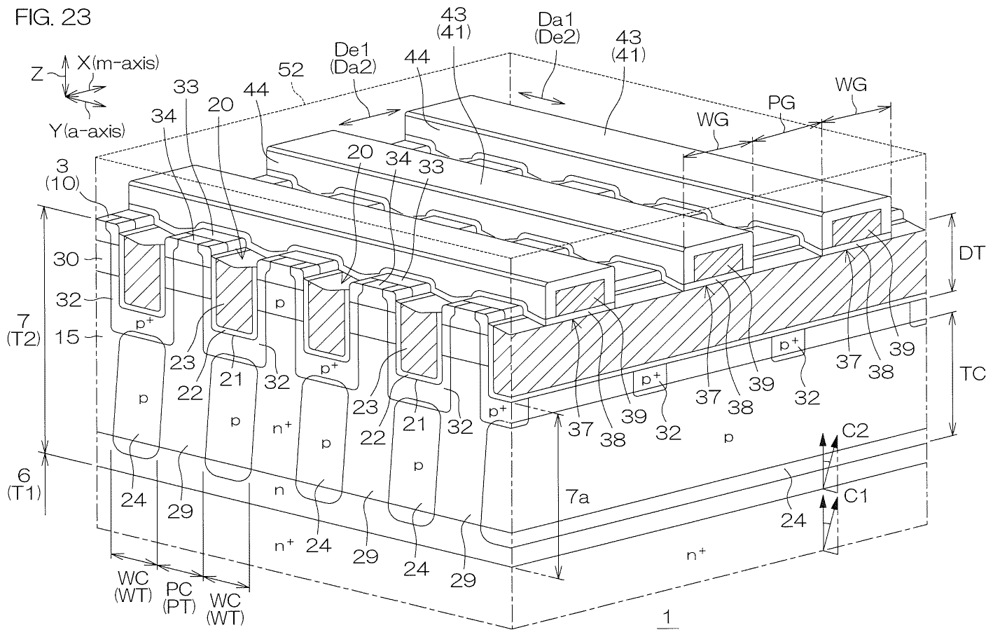

SiC semiconductor devices 1 according to modification examples shall now be illustrated. Features according to the modification examples illustrated below can also be applied in combination. FIG. 23 is a cross-sectional perspective view showing the SiC semiconductor device 1 according to a first modification example. With the SiC semiconductor device 1 described above, the first array direction Da1 of the plurality of trench structures 20 is the m-axis direction (the first direction X) and the first extension direction De1 of the plurality of trench structures 20 is the a-axis direction (the second direction Y).

On the other hand, with the SiC semiconductor device 1 according to the first modification example, the first array direction Da1 is the a-axis direction (the second direction Y) and the first extension direction De1 is the m-axis direction (the first direction X). That is, the plurality of trench structures 20 are each formed in a band shape extending in the m-axis direction (the first direction X) and are arrayed at intervals in the a-axis direction (the second direction Y).

The array direction of the plurality of body regions 30, the array direction of the plurality of surface layer drift regions 31, the array direction of the plurality of column regions 24, the array direction of the plurality of intermediate regions 32, and the array direction of the plurality of source regions 33 are respectively changed from the a-axis direction to the m-axis direction in accordance with the layout of the plurality of trench structures 20.

In this case, since the extension direction of the plurality of column regions 24 intersects (specifically, is orthogonal to) the off direction Do of the SiC monocrystal, the plurality of column regions 24 are inclined by substantially just the off angle θo toward the off direction Do from the vertical axis in a cross-sectional view viewed from an m-plane of the SiC monocrystal. Therefore, in view of precision of the charge balance, the plurality of column regions 24 preferably extend in the off direction Do.

The plurality of gate structures 37 are arrayed at intervals in the second array direction Da2 other than the first array direction Da1 and are each formed in a band shape extending in the second extension direction De2 other than the first extension direction De1. In this example, the plurality of gate structures 37 are arrayed at intervals in the second array direction Da2 that is orthogonal to the first array direction Da1 and extend in the second extension direction De2 that is orthogonal to the first extension direction De1.

That is, the second array direction Da2 is the m-axis direction (the first direction X) and the second extension direction De2 is the a-axis direction (the second direction Y). The plurality of gate structures 37 are arrayed at intervals in the m-axis direction (the first direction X) and are each formed to a band shape extending in the a-axis direction (the second direction Y).

As a matter of course, the first array direction Da1 of the plurality of trench structures 20 may be a direction other than the a-axis direction and the m-axis direction and the first extension direction De1 may be a direction other than the a-axis direction and the m-axis direction. That is, the plurality of trench structures 20 may extend in a direction intersecting both the a-axis direction and the m-axis direction.

In this case, the array direction of the plurality of column regions 24 becomes a direction other than the a-axis direction and the m-axis direction and the extension direction of the plurality of column regions 24 becomes a direction other than the a-axis direction and the m-axis direction. That is, the plurality of column regions 24 extend in a direction intersecting both the a-axis direction and the m-axis direction.

On the other hand, the second array direction Da2 of the plurality of gate structures 37 may be one of the a-axis direction and the m-axis direction and the second extension direction De2 of the plurality of gate structures 37 may be the other of the a-axis direction and the m-axis direction. In this case, the plurality of gate structures 37 may intersect the plurality of trench structures 20 non-orthogonally.

As a matter of course, the second array direction Da2 of the plurality of gate structures 37 may be a direction other than the a-axis direction and the m-axis direction and the second extension direction De2 of the plurality of gate structures 37 may be a direction other than the a-axis direction and the m-axis direction. That is, the plurality of gate structures 37 may extend in a direction that intersects both the a-axis direction and the m-axis direction. In this case, the plurality of gate structures 37 may be orthogonal to the plurality of trench structures 20 or may intersect the plurality of trench structures 20 non-orthogonally.

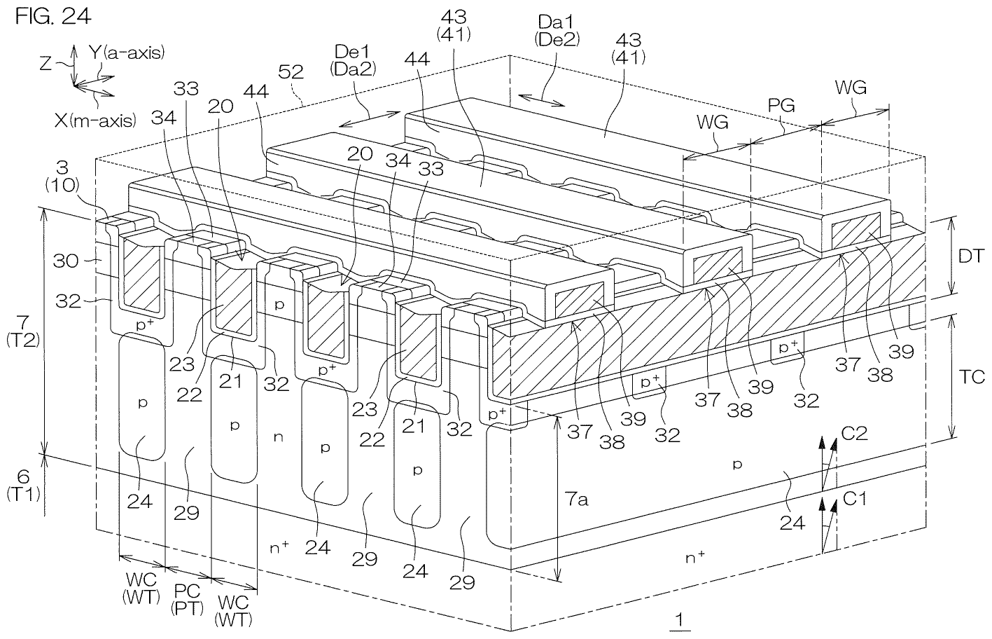

FIG. 24 is a cross-sectional perspective view showing the SiC semiconductor device 1 according to a second modification example. In the embodiment described above, the SiC semiconductor device 1 has the high concentration region 15. On the other hand, the SiC semiconductor device 1 according to the second modification example does not have the high concentration region 15. In this case, the plurality of trench structures 20, the plurality of body regions 30, the plurality of surface layer drift regions 31, the plurality of column regions 24, the plurality of drift regions 29, and the plurality of intermediate regions 32 are formed inside the semiconductor layer 7.

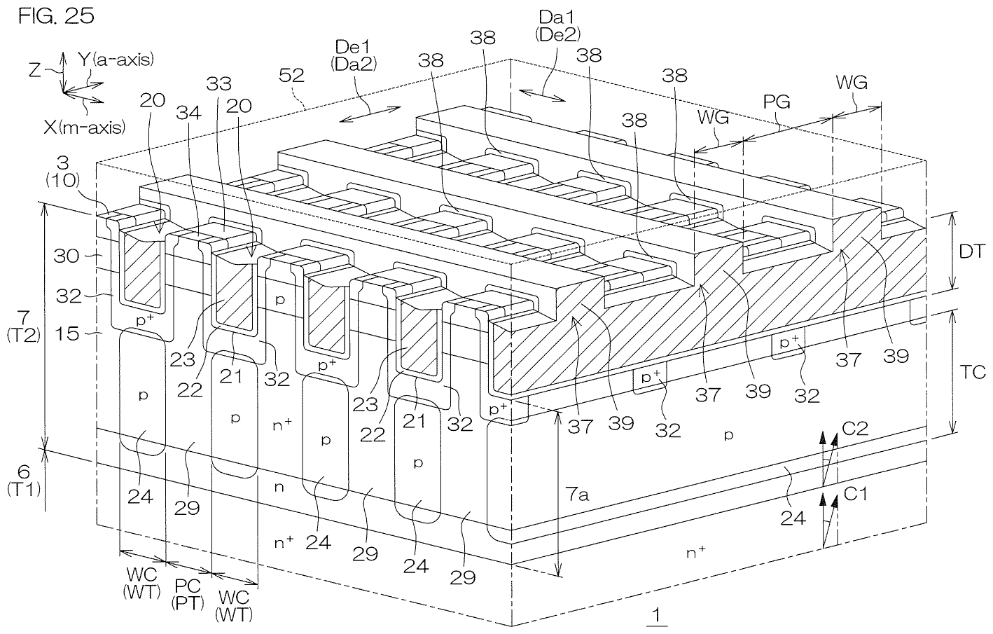

FIG. 25 is a cross-sectional perspective view showing the SiC semiconductor device 1 according to a third modification example. In FIG. 25, illustration of the interlayer insulating film 41 is omitted. With the SiC semiconductor device 1 described above, a potential other than the gate potential is applied to the trench structures 20. However, with the SiC semiconductor device 1 according to the third modification example, the trench structures 20 are formed as trench gate structures and the gate potential is applied to the trench structures 20.

That is, the gate structures 37 are made equipotential to the trench structures 20. The gate electrodes 39 may be formed integral to the embedded electrodes 23 or may be separated physically from the embedded electrodes 23 by interposing the gate insulating films 38 therebetween. An example where the gate electrodes 39 are formed integral to the embedded electrodes 23 is shown in FIG. 25.

The gate pad 50 (the plurality of gate wirings 51) described above is electrically connected to the plurality of trench structures 20 and the plurality of gate structures 37. The plurality of gate wirings 51 penetrate through the interlayer insulating film 41 via the plurality of contact openings 44 and are connected to either or both of the plurality of embedded electrodes 23 and the plurality of gate electrodes 39. Such an arrangement is realized by adjusting the layout of the plurality of contact openings 44 described above.

On the other hand, the source pad 52 is electrically connected to the plurality of body regions 30, the plurality of intermediate regions 32, the plurality of source regions 33, and the plurality of contact regions 34 via the plurality of contact openings 44 and face the plurality of trench structures 20 and the plurality of gate structures 37 with the interlayer insulating film 41 interposed therebetween. That is, the source pad 52 is electrically separated from the plurality of trench structures 20 and the plurality of gate structures 37. Such an arrangement is realized by adjusting the layout of the plurality of contact openings 44 described above.

With the SiC semiconductor device 1 according to the third modification example, the channels Ch that are oriented along the side walls of the trench structures 20 are further formed in regions, among the body regions 30, that are positioned between the source regions 33 and the drift regions 29.

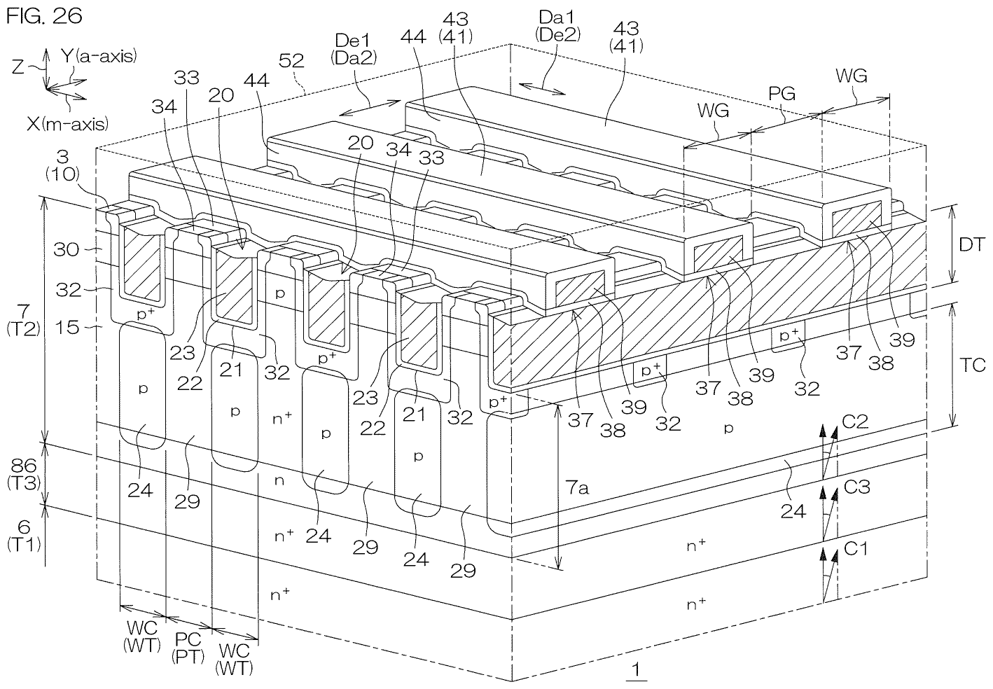

FIG. 26 is a cross-sectional perspective view showing the SiC semiconductor device 1 according to a fourth modification example. The SiC semiconductor device 1 according to the fourth modification example further includes a buffer layer 86 of the n-type made of the SiC monocrystal laminated on the base layer 6. The buffer layer 86 is also a component of the chip 2. The buffer layer 86 may be referred to as a “buffer SiC layer,” a “buffer region,” etc.

The buffer layer 86 extends in a layered shape in the horizontal directions and forms an intermediate portion of the chip 2 and portions of the first to fourth side surfaces 5A to 5D. The buffer layer 86 is constituted of an epitaxial layer (that is, an SiC epitaxial layer) formed by crystal growth with the base layer 6 as a starting point.

The buffer layer 86 has a lower end and an upper end. The lower end of the buffer layer 86 is a crystal growth starting point and the upper end of the buffer layer 86 is a crystal growth end point. The buffer layer 86 is formed by continuous crystal growth from the base layer 6 and therefore, the lower end of the buffer layer 86 is matched with an upper end of the base layer 6. A boundary portion between the base layer 6 and the buffer layer 86 is not necessarily visually recognizable and can be evaluated and/or determined indirectly from other arrangements and elements. The buffer layer 86 has the off direction Do and the off angle θo that are substantially matched with the off direction Do and the off angle θo of the base layer 6.

The buffer layer 86 has a third axis channel C3 oriented along the lamination direction. The third axis channel C3 is constituted of regions (channels) that are of comparatively wide interatomic distance (atomic interval) in the SiC monocrystal constituting the buffer layer 86 and are surrounded by atomic rows constituting a crystal axis extending in the lamination direction (crystal growth direction).

That is, the third axis channel C3 is constituted of regions that are sparse in atomic rows and extend in the lamination direction and are regions in which atomic rows (interatomic distance/atomic density) in the horizontal directions are sparse in plan view. The third axis channel C3 is preferably constituted of regions surrounded by atomic rows oriented along a low index crystal axis among the crystal axes.

In this embodiment, the third axis channel C3 is constituted of regions surrounded by atomic rows oriented along the c-axis of the SiC monocrystal. That is, the third axis channel C3 extends along the c-axis and has the off direction Do and the off angle θo. In other words, the third axis channel C3 is inclined by just the off angle θo toward the off direction Do from the vertical axis.

An n-type impurity concentration of the buffer layer 86 is preferably less than the n-type impurity concentration of the base layer 6. The buffer layer 86 may have an n-type impurity concentration of not less than 1×10¹⁵ cm⁻³ and not more than 1×10¹⁸ cm⁻³ as a peak value. The n-type impurity concentration of the buffer layer 86 may be substantially fixed in a thickness direction. As a matter of course, the n-type impurity concentration of the buffer layer 86 may have a concentration gradient that increases gradually and/or decreases gradually in the lamination direction (crystal growth direction).

The buffer layer 86 may has an n-type impurity concentration that is adjusted by at least one type of pentavalent element. For example, the n-type impurity concentration of the buffer layer 86 may be adjusted by at least one type among nitrogen, phosphorus, arsenic, antimony, and bismuth. The buffer layer 86 preferably contains a pentavalent element other than phosphorus.

The n-type impurity concentration of the buffer layer 86 is preferably adjusted by at least nitrogen. When the buffer layer 86 contains two or more types of pentavalent elements, the buffer layer 86 preferably contains nitrogen and a pentavalent element other than nitrogen. In this case, the buffer layer 86 preferably contains either or both of arsenic and antimony as a pentavalent element other than phosphorus and nitrogen.

The buffer layer 86 has a third thickness T3. The third thickness T3 is preferably less than the first thickness T1 of the base layer 6. The third thickness T3 is preferably not less than 1 μm. The third thickness T3 is preferably not more than 5 μm. The third thickness T3 may have a value falling within any one of ranges of not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor layer 7 is laminated on the buffer layer 86. The semiconductor layer 7 is constituted of an epitaxial layer (that is, an SiC epitaxial layer) formed by crystal growth with the buffer layer 86 as a starting point. The semiconductor layer 7 thus has the off direction Do and the off angle θo that are substantially matched with the off direction Do and the off angle θo of the buffer layer 86. Also, the second axis channel C2 is substantially matched with the third axis channel C3.

The second thickness T2 of the semiconductor layer 7 is preferably greater than the third thickness T3. As a matter of course, the second thickness T2 may be less than the third thickness T3. Also, the second thickness T2 may be substantially equal to the third thickness T3.

The embodiments described above can be implemented in yet other modes. For example, with each of the embodiments described above, the base layer 6, the semiconductor layer 7, and the buffer layer 86 that each include the SiC monocrystal are adopted. However, at least one or all of the base layer 6, the semiconductor layer 7, and the buffer layer 86 may include a monocrystal of a wide bandgap semiconductor other than the SiC monocrystal.

The wide bandgap semiconductor is a semiconductor having a bandgap greater than a bandgap of silicon. As examples of a monocrystal of a wide bandgap semiconductor, silicon carbide (SiC), gallium nitride (GaN), diamond (C), gallium oxide (Ga₂O₃), etc., can be cited. The base layer 6, the semiconductor layer 7, and the buffer layer 86 may be constituted of monocrystals of the same type or may be constituted of monocrystals of different types.

The above-described channeling implantation step (the step of implanting an impurity into regions where atomic rows are sparse) is also applicable to a monocrystal that constitutes a cubic crystal. The monocrystal of the wide bandgap semiconductor may thus be a cubic crystal or a hexagonal crystal. When a monocrystal that is a cubic crystal is applied to at least one or all of the base layer 6, the semiconductor layer 7, and the buffer layer 86, the axis channels thereof are formed by regions surrounded by atomic rows that are oriented along a low index crystal axis among the crystal axes of the cubic crystal.

A low index crystal axis of a cubic crystal is, in terms of Miller indices (h, k, and l), a crystal axis expressed by absolute values of “h,” “k,” and “l” all being not more than 2 (preferably not more than 1). As a matter of course, at least one or all of the base layer 6, the semiconductor layer 7, and the buffer layer 86 may include silicon monocrystal.

With each of the embodiments described above, a base layer 6 of the n-type was illustrated. However, a base layer 6 of the p-type may be adopted instead. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The base layer 6 of the p-type may be a p-type region that contains a trivalent element introduced into a surface layer portion of the second main surface 4 of the chip 2 by an ion implantation method.

Hereinafter, examples of features extracted from this Description and the attached drawings shall be indicated. Hereinafter, the alphanumeric characters, etc., in parentheses represent the corresponding components, etc., in the embodiments described above, but are not intended to limit the scope of each clause to the embodiments described above. The “semiconductor device” in the following clauses may be replaced with an “SiC semiconductor device,” a “wide bandgap semiconductor device,” “a semiconductor switching device,” a “MISFET device,” an “IGBT device,” etc., as needed.

[A1] A semiconductor device (1) comprising: a semiconductor layer (7) that includes a main surface (3); a trench structure (20) that is formed in the main surface (3) and extends in a first extension direction (De1) in plan view; and a gate structure (37) of a planar electrode type that is arranged on the main surface (3) and extends in a second extension direction (De2) other than the first extension direction (De1) in plan view.

[A2] The semiconductor device (1) according to A1, wherein the gate structure (37) intersects the trench structure (20) and is electrically insulated from the trench structure (20) at an intersection portion with the trench structure (20).

[A3] The semiconductor device (1) according to A1 or A2, wherein a potential other than a gate potential is applied to the trench structure (20), and the gate potential is applied to the gate structure (37).

[A4] The semiconductor device (1) according to any one of A1 to A3, wherein the first extension direction (De1) is an a-axis direction of the semiconductor layer (7), and the second extension direction (De2) is a direction other than the a-axis direction.

[A5] The semiconductor device (1) according to any one of A1 to A4, further comprising: the semiconductor layer (7) of a first conductivity type (an n-type); a lower region (7a) that is demarcated in a region between a bottom portion of the semiconductor layer (7) and the trench structure (20); and a column region (24) of a second conductivity type that is formed in the lower region (7a).

[A6] The semiconductor device (1) according to A5, wherein the column region (24) extends in the first extension direction (De1) in plan view, and the gate structure (37) intersects the column region (24) in plan view.

[A7] The semiconductor device (1) according to A5 or A6, wherein the semiconductor layer (7) has an axis channel (C2) oriented along a lamination direction, and the column region (24) extends along the axis channel (C2).

[A8] The semiconductor device (1) according to A7, wherein the column region (24) crosses a thickness range intermediate portion of the lower region (7a) along the axis channel (C2).

[A9] The semiconductor device (1) according to A7 or A8, wherein the semiconductor layer (7) has an off angle (θo) inclined toward an off direction (Do) on a basis of a vertical axis (Z), and the axis channel (C2) has the off angle (θo) inclined toward the off direction (Do) on the basis of the vertical axis (Z).

[A10] The semiconductor device (1) according to any one of A5 to A9, wherein, in regard to a thickness direction of the semiconductor layer (7), the column region (24) has a thickness (TC) greater than a depth (DT) of the trench structure (20).

[A11] The semiconductor device (1) according to any one of A5 to A10, wherein the column region (24) has an upper end portion at the trench structure (20) side and a lower end portion at the bottom portion side of the semiconductor layer (7) and has a concentration gradient that decreases gradually from the upper end portion toward the lower end portion.

[A12] The semiconductor device (1) according to A11, wherein the concentration gradient includes a peak value (P2) at the upper end portion side and a gentle gradient portion (27) where an impurity concentration decreases gradually at a slow decrease rate in a region further to the lower end portion side than the peak value (P2).

[A13] The semiconductor device (1) according to A12, wherein the gentle gradient portion (27) occupies a thickness range of not less than ¼ of the column region (24).

[A14] The semiconductor device (1) according to any one of A5 to A13, wherein the column region (24) is formed at an interval to the bottom portion side of the semiconductor layer (7) from the trench structure (20).

[A15] The semiconductor device (1) according to A14, further comprising: an intermediate region (32) of the second conductivity type that is formed in a region between the trench structure (20) and the column region (24).

[A16] The semiconductor device (1) according to A15, further comprising: a body region (30) of the second conductivity type (p-type) that is formed in a surface layer portion of the main surface (3); and wherein the trench structure (20) penetrates through the body region (30), the intermediate region (32) is electrically connected to the body region (30), and the column region (24), and the gate structure (37) covers the body region (30).

[A17] The semiconductor device (1) according to A16, further comprising: a source region (33) of the first conductivity type (n-type) that is formed at a side of the trench structure (20) in a surface layer portion of the body region (30); and wherein the gate structure (37) covers the source region (33).

[A18] The semiconductor device (1) according to any one of A5 to A17, further comprising: a high concentration region (15) of the first conductivity type (n-type) that has a higher impurity concentration than an impurity concentration of the semiconductor layer (7) and is formed in a surface layer portion of the main surface (3); and wherein the trench structure (20) is formed at an interval to the main surface (3) side from a bottom portion of the high concentration region (15), the lower region (7a) includes a portion of the high concentration region (15), and the column region (24) has a portion that is positioned inside the high concentration region (15).

[A19] The semiconductor device (1) according to A18, wherein the column region (24) crosses the bottom portion of the high concentration region (15).

[A20] A semiconductor device (1) comprising: a semiconductor layer (7) of a first conductivity type (an n-type) that includes a main surface (3) and has an axis channel (C2) oriented along a lamination direction; a trench structure (20) that is formed in the main surface (3) and demarcates, together with a bottom portion of the semiconductor layer (7), a lower region (7a); a column region (24) of a second conductivity type (p-type) that is formed in the lower region (7a) and extends along the axis channel (C2); and a gate structure (37) of a planar electrode type that is arranged on the main surface (3) and overlaps with the trench structure (20) and the column region (24) in the lamination direction.

[A21] The semiconductor device (1) according to any one of A1 to A20, wherein the semiconductor layer (7) is an SiC layer (7) that includes an SiC monocrystal.

While specific embodiments have been described in detail above, these are merely specific examples used to clarify the technical contents. The various technical ideas extracted from this Description can be combined as appropriate with each other without being limited by the order of description, the order of configuration examples, the order of modification examples, etc., in this Description.

What is claimed is:

1. An SiC semiconductor device comprising:
an SiC layer that includes a main surface;
a trench structure that is formed in the main surface and extends in a first extension direction in plan view; and
a gate structure of a planar electrode type that is arranged on the main surface and extends in a second extension direction other than the first extension direction in plan view.

2. The SiC semiconductor device according to claim 1,
wherein the gate structure intersects the trench structure and is electrically insulated from the trench structure at an intersection portion with the trench structure.

3. The SiC semiconductor device according to claim 1,
wherein a potential other than a gate potential is applied to the trench structure, and
the gate potential is applied to the gate structure.

4. The SiC semiconductor device according to claim 1,
wherein the first extension direction is an a-axis direction of the SiC layer, and
the second extension direction is a direction other than the a-axis direction.

5. The SiC semiconductor device according to claim 1, further comprising:
the SiC layer of a first conductivity type;
a lower region that is demarcated in a region between a bottom portion of the SiC layer and the trench structure; and
a column region of a second conductivity type that is formed in the lower region.

6. The SiC semiconductor device according to claim 5,
wherein the column region extends in the first extension direction in plan view, and
the gate structure intersects the column region in plan view.

7. The SiC semiconductor device according to claim 5,
wherein the SiC layer has an axis channel oriented along a lamination direction, and
the column region extends along the axis channel.

8. The SiC semiconductor device according to claim 7,
wherein the column region crosses a thickness range intermediate portion of the lower region along the axis channel.

9. The SiC semiconductor device according to claim 7,
wherein the SiC layer has an off angle inclined toward an off direction on a basis of a vertical axis, and
the axis channel has the off angle inclined toward the off direction on the basis of the vertical axis.

10. The SiC semiconductor device according to claim 5,
wherein, in regard to a thickness direction of the SiC layer, the column region has a thickness greater than a depth of the trench structure.

11. The SiC semiconductor device according to claim 5,
wherein the column region has an upper end portion at the trench structure side and a lower end portion at the bottom portion side of the SiC layer and has a concentration gradient that decreases gradually from the upper end portion toward the lower end portion.

12. The SiC semiconductor device according to claim 11,
wherein the concentration gradient includes a peak value at the upper end portion side and a gentle gradient portion where an impurity concentration decreases gradually at a slow decrease rate in a region further to the lower end portion side than the peak value.

13. The SiC semiconductor device according to claim 12,
wherein the gentle gradient portion occupies a thickness range of not less than ¼ of the column region.

14. The SiC semiconductor device according to claim 5,
wherein the column region is formed at an interval to the bottom portion side of the SiC layer from the trench structure.

15. The SiC semiconductor device according to claim 14, further comprising:
an intermediate region of the second conductivity type that is formed in a region between the trench structure and the column region.

16. The SiC semiconductor device according to claim 15, further comprising:
a body region of the second conductivity type that is formed in a surface layer portion of the main surface; and
wherein the trench structure penetrates through the body region,
the intermediate region is electrically connected to the body region and the column region, and
the gate structure covers the body region.

17. The SiC semiconductor device according to claim 16, further comprising:
a source region of the first conductivity type that is formed at a side of the trench structure in a surface layer portion of the body region; and
wherein the gate structure covers the source region.

18. The SiC semiconductor device according to claim 5, further comprising:
a high concentration region of the first conductivity type that has a higher impurity concentration than an impurity concentration of the SiC layer and is formed in a surface layer portion of the main surface; and
wherein the trench structure is formed at an interval to the main surface side from a bottom portion of the high concentration region,
the lower region includes a portion of the high concentration region, and
the column region has a portion that is positioned inside the high concentration region.

19. The SiC semiconductor device according to claim 18,
wherein the column region crosses the bottom portion of the high concentration region.

20. An SiC semiconductor device comprising:
an SiC layer of a first conductivity type that includes a main surface and has an axis channel oriented along a lamination direction;
a trench structure that is formed in the main surface and demarcates a lower region together with a bottom portion of the SiC layer;
a column region of a second conductivity type that is formed in the lower region and extends along the axis channel; and
a gate structure of a planar electrode type that is arranged on the main surface and overlaps with the trench structure and the column region in the lamination direction.
